(19) United States
(12) Patent Application Publication
(10) Pub. No.: US 2026/0255789 A1
(43) Pub. Date: Aug. 27, 2026

(54) DISPLAY APPARATUS, DISPLAY MODULE, AND ELECTRONIC DEVICE

(71) Applicant: SEMICONDUCTOR ENERGY LABORATORY CO., LTD., Atsugi-shi, Kanagawa-ken (JP)

(72) Inventors: Takuya ISHIMOTO, Isehara, Kanagawa (JP); Takeyoshi WATABE, Atsugi, Kanagawa (JP); Nobuharu OHSAWA, Zama, Kanagawa (JP)

(21) Appl. No.: 18/860,046

(22) PCT Filed: Apr. 17, 2023
(86) PCT No.: PCT/IB2023/053889

§ 371 Date: Oct. 25, 2024

(30) Foreign Application Priority Data
Apr. 28, 2022 (JP) 2022-074553

(51) Int. Cl. H10K 50/856; H10K 50/19; H10K 50/818; H10K 102/00

(52) U.S. Cl. CPC H10K 50/856; H10K 50/19; H10K 50/818; H10K 2102/351

(57) ABSTRACT

A novel display apparatus that is highly convenient, useful, or reliable is provided. The display apparatus includes a first light-emitting device, a first layer, a first reflective film, a second light-emitting device, a second layer, and a second reflective film. The first light-emitting device includes a third layer, a first electrode, and a first unit. The first unit is interposed between the first electrode and the third layer. The first unit includes a first light-emitting material. The first light-emitting material has an emission spectrum having a peak at a first wavelength. The third layer has a light-transmitting property and includes a second electrode. The first layer is interposed between the third layer and the first reflective film. The first layer has a light-transmitting property and an ordinary refractive index lower than that of the third layer at the first wavelength. The second light-emitting device includes a fourth layer, a third electrode, and a second unit. The second unit is interposed between the third electrode and the fourth layer. A space is provided between the fourth layer and the third layer. The second layer is interposed between the fourth layer and the second reflective film.

### TECHNICAL FIELD

One embodiment of the present invention relates to a light-emitting device, a display apparatus, a display module, an electronic device, or a semiconductor device.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Thus, more specifically, examples of the technical field of one embodiment of the present invention disclosed in this specification include a semiconductor device, a display apparatus, a light-emitting apparatus, a power storage device, a memory device, a driving method thereof, and a manufacturing method thereof.

### BACKGROUND ART

For example, a structure of an organic EL apparatus is known as an electro-optical apparatus including a first pixel (Patent Document 1). The first pixel includes a light-emitting pixel R, a light-emitting pixel G, and a light-emitting pixel B. The light-emitting pixel R, the light-emitting pixel G, and the light-emitting pixel B each include a reflective layer, a counter electrode, an optical length adjustment layer, and a functional layer. The counter electrode functions as a transflective layer, and the optical length adjustment layer and the functional layer of each light-emitting pixel are provided between the reflective layer and the counter electrode. The optical length adjustment layer of the light-emitting pixel R includes a third insulating layer and a fourth insulating layer. The optical length adjustment layer of the light-emitting pixel G includes the fourth insulating layer as a luminance adjustment layer. The optical length adjustment layer of the light-emitting pixel B does not include the third insulating layer.

### REFERENCE

### Patent Document

[Patent Document 1] Japanese Published Patent Application No. 2019-135724

### SUMMARY OF THE INVENTION

### Problems to be Solved by the Invention

An object of one embodiment of the present invention is to provide a novel light-emitting device that is highly convenient, useful, or reliable. Another object is to provide a novel display apparatus that is highly convenient, useful, or reliable. Another object is to provide a novel display module that is highly convenient, useful, or reliable. Another object is to provide a novel electronic device that is highly convenient, useful, or reliable. Another object is to provide a novel light-emitting device, a novel display apparatus, a novel display module, a novel electronic device, or a novel semiconductor device.

Note that the description of these objects does not preclude the existence of other objects. One embodiment of the present invention does not need to achieve all of these objects. Note that other objects will be apparent from the description of the specification, the drawings, the claims, and the like, and other objects can be derived from the description of the specification, the drawings, the claims, and the like.

### Means for Solving the Problems

(1) One embodiment of the present invention is a display apparatus including a first light-emitting device, a first layer, a first reflective film, a second light-emitting device, a second layer, and a second reflective film.

The first light-emitting device includes a third layer, a first electrode, and a first unit. The first unit is interposed between the first electrode and the third layer. The first unit includes a first light-emitting material. The first light-emitting material has an emission spectrum having a peak at a first wavelength.

The third layer has a light-transmitting property and includes a second electrode. The first layer is interposed between the third layer and the first reflective film.

The first layer has a light-transmitting property and an ordinary refractive index lower than that of the third layer at the first wavelength.

The second light-emitting device includes a fourth layer, a third electrode, and a second unit. The second unit is interposed between the third electrode and the fourth layer. The second unit includes a second light-emitting material. The second light-emitting material has an emission spectrum having a peak at a second wavelength.

The fourth layer has a light-transmitting property and includes a fourth electrode. A space is positioned between the fourth layer and the third layer.

The second layer is interposed between the fourth layer and the second reflective film and has an ordinary refractive index lower than that of the fourth layer at the second wavelength and a light-transmitting property.
(2) One embodiment of the present invention is a display apparatus including a first light-emitting device, a first layer, a first reflective film, a second light-emitting device, a second layer, and a second reflective film.

The first light-emitting device includes a third layer, a first electrode, and a first unit. The first unit is interposed between the first electrode and the third layer. The first unit includes a first light-emitting material.

The third layer has a light-transmitting property, includes a second electrode, and contains an element with an atomic number of 21 to 83 at 5 atomic % or higher.

The first layer is interposed between the third layer and the first reflective film, has a light-transmitting property, and contains an element with an atomic number of 1 to 20 at 95 atomic % or higher.

The second light-emitting device includes a fourth layer, a third electrode, and a second unit. The second unit is interposed between the third electrode and the fourth layer. The second unit includes a second light-emitting material.

The fourth layer has a light-transmitting property, includes a fourth electrode, and contains an element with an atomic number of 21 to 83 at 5 atomic % or higher. A space is positioned between the fourth layer and the third layer.

The second layer is interposed between the fourth layer and the second reflective film, has a light-transmitting property, and contains an element with an atomic number of 1 to 20 at 95 atomic % or higher.
(3) One embodiment of the present invention is the above-described display apparatus in which the third layer and the fourth layer each contain a metal oxide, and the metal oxide contains indium, tin, zinc, gallium, or titanium.
(4) One embodiment of the present invention is the above-described display apparatus in which the first layer and the second layer each contain silicon oxide or aluminum oxide.
(5) One embodiment of the present invention is the above-described display apparatus in which a difference in ordinary refractive index at the first wavelength between the third layer and the first layer is greater than or equal to 0.2 and less than or equal to 1.4.
(6) One embodiment of the present invention is the above-described display apparatus in which the first layer has an ordinary refractive index higher than or equal to 1.2 and lower than or equal to 1.7 at the first wavelength and an insulating property.

Accordingly, light emitted from the first unit toward the first reflective film goes from the region having a high ordinary refractive index into the region having a low ordinary refractive index. Part of the light emitted from the first unit can be reflected at an interface between the third layer and the first layer. The light reflected at the interface and light emitted from the first unit toward the first electrode can intensify each other. Light reflected by the first reflective film can also intensify the light emitted from the first unit toward the first electrode each other. As a result, a novel display apparatus that is highly convenient, useful, or reliable can be provided.
(7) One embodiment of the present invention is the above-described display apparatus in which the first layer has a thickness tLX and an ordinary refractive index nLX at the first wavelength. The thickness tLX and the ordinary refractive index nLX have a relation satisfying the following formula.

$$\begin{matrix}[ Formula 1 ] & \\ 0 < \frac{tLX \times nLX}{λ X} < 0.375 & ( 1 )\end{matrix}$$

Thus, part of the light emitted from the first unit toward the first reflective film can be reflected at the interface between the third layer and the first layer. Another part of the light can be reflected by the first reflective film. Furthermore, with the use of the light reflected at the interface between the third layer and the first layer, the light reflected by the first reflective film can be intensified. Furthermore, the efficiency of extracting light from the light-emitting device can be increased. Moreover, the width of the emission spectrum can be narrowed. Furthermore, the saturation of an emission color can be increased. As a result, a novel display apparatus that is highly convenient, useful, or reliable can be provided.
(8) One embodiment of the present invention is the above-described display apparatus in which the second layer contains the same material as the first layer and has the same thickness as the first layer.

Thus, the first layer and the second layer can be formed in the same step. In addition, the manufacturing process can be simplified. Part of the light emitted from the first unit toward the first reflective film can be reflected at the interface between the third layer and the first layer. Another part of the light can be reflected by the first reflective film. Furthermore, with the use of the light reflected at the interface between the third layer and the first layer, the light reflected by the first reflective film can be intensified. Part of light emitted from the second unit toward the second reflective film can be reflected at an interface between the fourth layer and the second layer. Another part of the light can be reflected by the second reflective film. Furthermore, with the use of light reflected at the interface between the fourth layer and the second layer, the light reflected by the second reflective film can be intensified. As a result, a novel display apparatus that is highly convenient, useful, or reliable can be provided.
(9) One embodiment of the present invention is the above-described display apparatus in which the first light-emitting device includes a first intermediate layer and a third unit.

The third unit is interposed between the first electrode and the first intermediate layer and includes a third light-emitting material. The first intermediate layer is interposed between the third unit and the first unit.

The second light-emitting device includes a second intermediate layer and a fourth unit. The fourth unit is interposed between the third electrode and the second intermediate layer and includes a fourth light-emitting material. The second intermediate layer is interposed between the fourth unit and the second unit.

Thus, emission intensity at the same current density can be increased. Moreover, the current efficiency in light emission can be increased. Furthermore, energy efficiency in light emission can be increased. As a result, a novel display apparatus that is highly convenient, useful, or reliable can be provided.
(10) One embodiment of the present invention is the above-described display apparatus in which the second light-emitting material is different from the first light-emitting material.
(11) One embodiment of the present invention is the above-described display apparatus including a first insulating film, a conductive film, and a second insulating film.

The first reflective film is interposed between the first insulating film and the first layer. The second reflective film is interposed between the first insulating film and the second layer.

The conductive film overlaps with the first insulating film and includes the first electrode and the third electrode.

The second insulating film is interposed between the conductive film and the first insulating film, fills the space, and has an insulating property.

The second insulating film includes a first opening portion and a second opening portion. The first opening portion overlaps with the second electrode. The second opening portion overlaps with the fourth electrode.

Thus, the space can be filled with the second insulating film. Moreover, a step due to the space can be reduced so as to be close to a flat plane. A phenomenon in which a cut or a split due to the step is generated in a conductive film 552 can be inhibited. As a result, a novel display apparatus that is highly convenient, useful, or reliable can be provided.
(12) One embodiment of the present invention is the above-described display apparatus in which the first reflective film is electrically connected to the second electrode, and the second reflective film is electrically connected to the fourth electrode.

Thus, a wiring can be used as the first reflective film, for example. Furthermore, the structure of a display apparatus can be simplified. As a result, a novel display apparatus that is highly convenient, useful, or reliable can be provided.
(13) One embodiment of the present invention is a display module including the above-described display apparatus and at least one of a connector and an integrated circuit.
(14) One embodiment of the present invention is an electronic device including the above-described display apparatus and at least one of a battery, a camera, a speaker, and a microphone.

Although a block diagram in which components are classified by their functions and shown as independent blocks is shown in the drawing attached to this specification, it is difficult to completely separate actual components according to their functions and one component can relate to a plurality of functions.

Note that the light-emitting apparatus in this specification includes, in its category, an image display device that uses a light-emitting device. The light-emitting apparatus may also include a module in which a light-emitting device is provided with a connector such as an anisotropic conductive film or a TCP (Tape Carrier Package), a module in which a printed wiring board is provided at the end of a TCP, and a module in which an integrated circuit (IC) is directly mounted on a light-emitting device by a COG (Chip On Glass) method. Furthermore, a lighting device or the like may include the light-emitting apparatus.

### Effect of the Invention

According to one embodiment of the present invention, a novel light-emitting device that is highly convenient, useful, or reliable can be provided. According to one embodiment of the present invention, a novel display apparatus that is highly convenient, useful, or reliable can be provided. According to one embodiment of the present invention, a novel display module that is highly convenient, useful, or reliable can be provided. According to one embodiment of the present invention, a novel electronic device that is highly convenient, useful, or reliable can be provided. According to one embodiment of the present invention, a novel light-emitting device can be provided. According to one embodiment of the present invention, a novel display apparatus can be provided. According to one embodiment of the present invention, a novel display module can be provided. According to one embodiment of the present invention, a novel electronic device can be provided.

Note that the description of these effects does not preclude the existence of other effects. Note that one embodiment of the present invention does not need to have all the effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A to FIG. 1C are diagrams illustrating a structure of a display apparatus of an embodiment.

FIG. 2A to FIG. 2C are diagrams illustrating a structure of a light-emitting device of an embodiment.

FIG. 3 is a diagram illustrating a structure of a display apparatus of an embodiment.

FIG. 4A and FIG. 4B are diagrams illustrating a structure of a light-emitting device of an embodiment.

FIG. 5A and FIG. 5B are diagrams illustrating structures of light-emitting devices of an embodiment.

FIG. 6A to FIG. 6C are diagrams illustrating a structure of a display apparatus of an embodiment.

FIG. 7 is a diagram illustrating a structure of a display apparatus of an embodiment.

FIG. 8 is a diagram illustrating a structure of a display module of an embodiment.

FIG. 9A and FIG. 9B are diagrams illustrating structures of display apparatuses of an embodiment.

FIG. 10 is a diagram illustrating a structure of a display apparatus of an embodiment.

FIG. 11 is a diagram illustrating a structure of a display apparatus of an embodiment.

FIG. 12 is a diagram illustrating a structure of a display apparatus of an embodiment.

FIG. 13 is a diagram illustrating a structure of a display apparatus of an embodiment.

FIG. 14 is a diagram illustrating a structure of a display apparatus of an embodiment.

FIG. 15 is a diagram illustrating a structure of a display module of an embodiment.

FIG. 16A to FIG. 16C are diagrams illustrating structures of a display apparatus of an embodiment.

FIG. 17 is a diagram illustrating a structure of a display apparatus of an embodiment.

FIG. 18 is a diagram illustrating a structure of a display apparatus of an embodiment.

FIG. 19A to FIG. 19D are diagrams illustrating examples of electronic devices of an embodiment.

FIG. 20A to FIG. 20F are diagrams illustrating examples of electronic apparatuses of an embodiment.

FIG. 21A to FIG. 21G are diagrams illustrating examples of electronic apparatuses of an embodiment.

FIG. 22 is a diagram illustrating a structure of a display apparatus of Example.

FIG. 23 is a diagram illustrating a structure of a comparative apparatus of Example.

FIG. 24 is a diagram showing emission spectra of light-emitting materials of Example.

FIG. 25 is a diagram showing wavelength dependence of a refractive index n and an extinction coefficient k of a material of Example.

FIG. 26 is a diagram showing wavelength dependence of a refractive index n and an extinction coefficient k of a material of Example.

FIG. 27 is a diagram showing wavelength dependence of a refractive index n and an extinction coefficient k of a material of Example.

FIG. 28 is a diagram showing wavelength dependence of a refractive index n and an extinction coefficient k of a material of Example.

FIG. 29 is a diagram showing wavelength dependence of a refractive index n and an extinction coefficient k of a material of Example.

### MODE FOR CARRYING OUT THE INVENTION

The display apparatus of one embodiment of the present invention includes the first light-emitting device, the first layer, the first reflective film, the second light-emitting device, the second layer, and the second reflective film. The first light-emitting device includes the third layer, the first electrode, and the first unit, and the first unit is interposed between the first electrode and the third layer. The first unit includes the first light-emitting material. The first light-emitting material has the emission spectrum having the peak at the first wavelength. The third layer has a light-transmitting property and includes the second electrode. The first layer is interposed between the third layer and the first reflective film. The first layer has a light-transmitting property and the ordinary refractive index lower than that of the third layer at the first wavelength. The second light-emitting device includes the fourth layer, the third electrode, and the second unit, and the second unit is interposed between the third electrode and the fourth layer. The second unit includes the second light-emitting material. The second light-emitting material has the emission spectrum having the peak at the second wavelength. The fourth layer has a light-transmitting property and includes the fourth electrode. The space is positioned between the fourth layer and the third layer. The second layer is interposed between the fourth layer and the second reflective film and has the ordinary refractive index lower than that of the fourth layer at the second wavelength and a light-transmitting property.

Accordingly, light emitted from the first unit toward the first reflective film goes from the region having a high ordinary refractive index into the region having a low ordinary refractive index. Part of the light emitted from the first unit can be reflected at the interface between the third layer and the first layer. The light reflected at the interface and light emitted from the first unit toward the first electrode can intensify each other. Light reflected by the first reflective film can also intensify the light emitted from the first unit toward the first electrode each other. As a result, a novel display apparatus that is highly convenient, useful, or reliable can be provided.

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

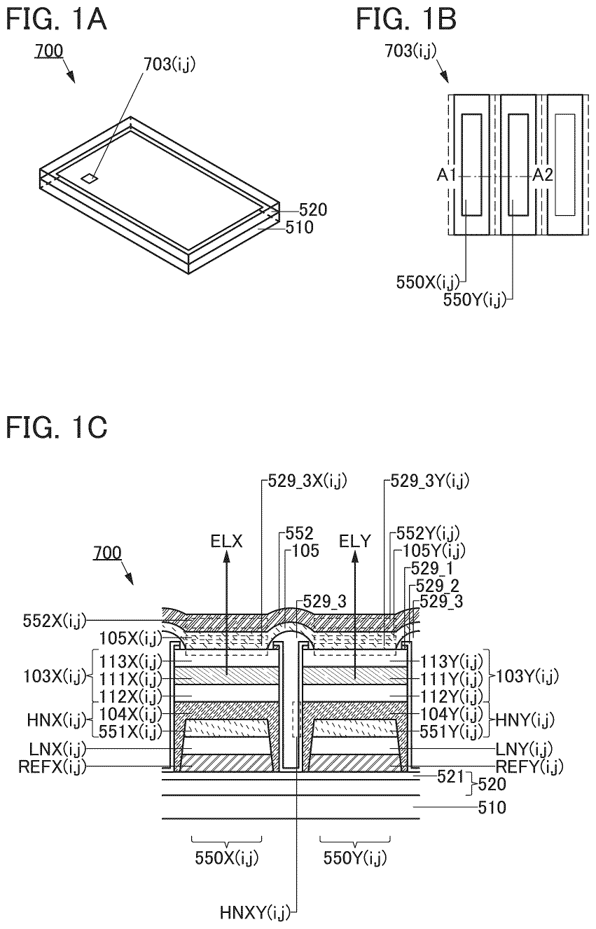

In this embodiment, a structure of a display apparatus 700 of one embodiment of the present invention will be described with reference to FIG. 1 to FIG. 3.

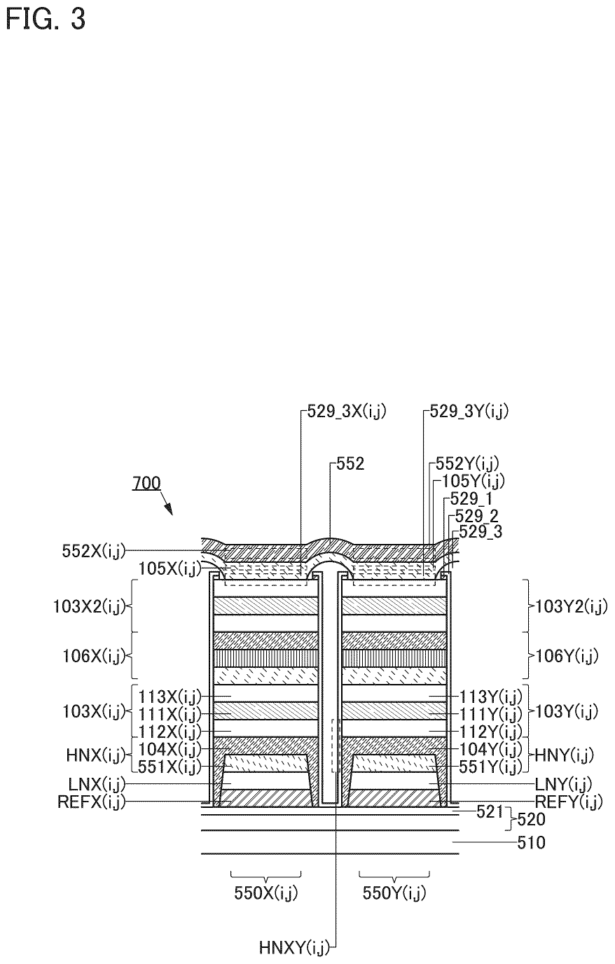

FIG. 1A is a perspective view illustrating a structure of the display apparatus 700 of one embodiment of the present invention. FIG. 1B is a top view illustrating part of the display apparatus 700. FIG. 1C is a cross-sectional view taken along the cutting line A1-A2 in FIG. 1B and illustrating part of the display apparatus 700. FIG. 3 is a cross-sectional view illustrating the structure of the display apparatus 700 of one embodiment of the present invention.

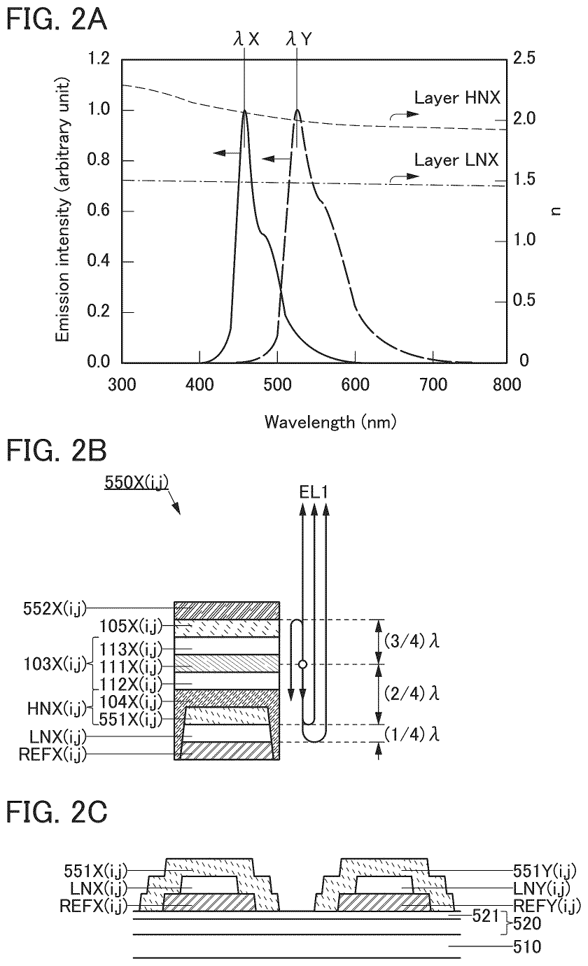

FIG. 2A shows a light emission spectrum illustrating the structure of the display apparatus 700 of one embodiment of the present invention, and FIG. 2B is a diagram illustrating an effect of the structure of the display apparatus 700. FIG. 2C is a diagram illustrating part of the structure of the display apparatus 700.

### Structure Example 1 of Display Apparatus 700

The display apparatus 700 described in this embodiment includes a substrate 510 and a functional layer 520 (see FIG. 1A). The display apparatus 700 includes a pixel set 703(i,j), and the pixel set 703(i,j) includes a light-emitting device 550X(i,j) and a light-emitting device 550Y(i,j)(see FIG. 1A and FIG. 1B).

The functional layer 520 includes an insulating film 521, and the light-emitting device 550X(i,j) and the light-emitting device 550Y(i,j) are formed over the insulating film 521 (see FIG. 1C). The functional layer 520 is interposed between the substrate 510 and the light-emitting device 550X(i,j).

The display apparatus 700 includes the light-emitting device 550X(i,j), a layer LNX(i,j), and a reflective film REFX(i,j)(see FIG. 1C). The display apparatus 700 includes the light-emitting device 550Y(i,j), a layer LNY(i,j), and a reflective film REFY(i,j).

### <<Structure Example 1 of Light-Emitting Device 550X(i,j)>>

The light-emitting device 550X(i,j) includes a layer HNX(i,j), an electrode 552X(i,j), and a unit 103X(i,j). The unit 103X(i,j) is interposed between the electrode 552X(i,j) and a layer HNX(i,j).

The unit 103X(i,j) contains a light-emitting material EMX, and the light-emitting material EMX has an emission spectrum having a peak at a wavelength λX (see FIG. 2A).

For example, a layer selected from functional layers such as a light-emitting layer, a hole-transport layer, an electron-transport layer, and a carrier-blocking layer can be used in the unit 103X(i,j). Moreover, a layer selected from functional layers such as a hole-injection layer, an electron-injection layer, an exciton-blocking layer, and a charge-generation layer can be used in the unit 103X(i,j).

### <<Structure Example 1 of Unit 103X(i,j)>>

For example, the unit 103X(i,j) includes a layer 111X(i,j), a layer 112X(i,j), and a layer 113X(i,j)(see FIG. 1C). The layer 111X(i,j) is interposed between the layer 113X(i,j) and the layer HNX(i,j), and contains the light-emitting material EMX.

Note that the details of a structure example applicable to the unit 103X(i,j) will be described in Embodiment 2.

### <<Structure Example 1 of Layer HNX(i,j)>>

The layer HNX(i,j) has a light-transmitting property, and the layer HNX(i,j) includes an electrode 551X(i,j).

The difference in ordinary refractive index at the wavelength 2X between the layer HNX(i,j) and the layer LNX(i,j) is greater than or equal to 0.2 and less than or equal to 1.4.

For example, a film containing an inorganic compound, a film containing an organic compound, or a stacked film of an inorganic compound and an organic compound can be used as the layer HNX(i,j).

Note that an element having a larger principal quantum number tends to have larger polarizability. Furthermore, an element in which an electron travels an orbital more distant from its atomic nucleus tends to have larger polarizability. Moreover, the refractive index increases depending on the polarizability. Thus, the refractive index of the layer HNX(i,j) can be increased when an element with a larger atomic number or an element in the later period is used for the layer HNX(i,j). For example, a material containing an element with an atomic number of 21 to 83 at 5 atomic % or higher can be used for the layer HNX(i,j).

Specifically, an oxide containing indium, tin, zinc, gallium, or titanium can be used for the layer HNX(i,j), for example.

A material having both a light-transmitting property and conductivity can be used for the electrode 551X(i,j). Note that a structure example that can be employed for the electrode 551X(i,j) is described in detail in Embodiment 3.

### <<Structure Example 1 of Layer LNX(i,j)>>

The layer LNX(i,j) is interposed between the layer HNX(i,j) and the reflective film REFX(i,j). The layer LNX(i,j) has a lower ordinary refractive index than the layer HNX(i,j) at the wavelength λX and a light-transmitting property.

The layer LNX(i,j) has an ordinary refractive index higher than or equal to 1.2 and lower than or equal to 1.7 at the wavelength 2X. The layer LNX(i,j) has an insulating property.

For example, a film containing an inorganic compound, a film containing an organic compound, or a stacked film of an inorganic compound and an organic compound can be used as the layer LNX(i,j).

For example, a material containing an element with an atomic number of 1 to 20 at 95 atomic % or higher can be used for the layer LNX(i,j).

Specifically, silicon oxide, aluminum oxide, lithium fluoride, sodium fluoride, potassium fluoride, magnesium fluoride, calcium fluoride, or the like can be used for the layer LNX(i,j).

### <<Structure Example 1 of Light-Emitting Device 550Y(i,j)>>

The light-emitting device 550Y(i,j) is adjacent to the light-emitting device 550X(i,j). The light-emitting device 550Y(i,j) includes a layer HNY(i,j), an electrode 552Y(i,j), and a unit 103Y(i,j). The unit 103Y(i,j) is interposed between the electrode 552Y(i,j) and the layer HNY(i,j).

The unit 103Y(i,j) contains a light-emitting material EMY, and the light-emitting material EMY has an emission spectrum having a peak at the wavelength λY (see FIG. 2A).

### <<Structure Example 1 of Unit 103Y(i,j)>>

The unit 103Y(i,j) includes a layer 111Y(i,j), a layer 112Y(i,j), and a layer 113Y(i,j)(see FIG. 1C). The layer 111Y(i,j) is interposed between the layer 113Y(i,j) and the layer HNY(i,j), and contains the light-emitting material EMY.

For example, the structure usable for the unit 103X(i,j) can be employed for the unit 103Y(i,j).

### <<Structure Example 1 of Layer HNY(i,j)>>

The layer HNY(i,j) has a light-transmitting property, and the layer HNY(i,j) includes an electrode 551Y(i,j).

A space HNXY(i,j) is provided between the layer HNY(i,j) and the layer HNX(i,j). For example, a space is provided between the electrode 551Y(i,j) and the electrode 551X(i,j). Thus, a potential different from a potential supplied to the electrode 551X(i,j) can be supplied to the electrode 551Y(i,j). The space HNXY(i,j) separates not only the electrode 551Y(i,j) but also the layer HNY(i,j) from the layer HNX(i,j).

For example, the structure that can be used for the layer HNX(i,j) can be used for the layer HNY(i,j).

### <<Structure Example 1 of Layer LNY(i,j)>>

The layer LNY(i,j) is interposed between the layer HNY(i,j) and the reflective film REFY(i,j). The layer LNY(i,j) has a light-transmitting property, and the layer LNY(i,j) has an ordinary refractive index lower than that of the layer HNY(i,j) at the wavelength λY.

For example, the structure that can be used for the layer LNX(i,j) can be used for the layer LNY(i,j).

Thus, light emitted from the unit 103X(i,j) toward the reflective film REFX(i,j) goes from the region having a high ordinary refractive index into the region having a low ordinary refractive index. Part of the light emitted from the unit 103X(i,j) can be reflected at the interface between the layer HNX(i,j) and the layer LNX(i,j). Furthermore, the light reflected at the interface and the light emitted from the unit 103X(i,j) toward the electrode 552X(i,j) can intensify each other. Furthermore, light reflected by the reflective film REFX(i,j) can also intensify the light emitted from the unit 103X(i,j) toward the electrode 552X(i,j) each other. As a result, a novel display apparatus that is highly convenient, useful, or reliable can be provided.

### <<Structure Example 2 of Layer LNX(i,j)>>

The layer LNX(i,j) has a thickness tLX, and the layer LNX(i,j) has an ordinary refractive index nLX at the wavelength λX. Note that the thickness tLX is preferably greater than 0 and less than or equal to 110 nm, for example. The thickness tLX and the ordinary refractive index nLX satisfy the following formula.

$$\begin{matrix}[ Formula 2 ] & \\ 0 < \frac{tLX \times nLX}{λ X} < 0.375 & ( 1 )\end{matrix}$$

Thus, part of the light emitted from the unit 103X(i,j) toward the reflective film REFX(i,j) can be reflected at the interface between the layer HNX(i,j) and the layer LNX(i,j)(see FIG. 2B). Another part of the light can be reflected by the reflective film REFX(i,j). Furthermore, with the use of the light reflected at the interface between the layer HNX(i,j) and the layer LNX(i,j), the light reflected by the reflective film REFX(i,j) can be intensified. Alternatively, the efficiency of extracting light from the light-emitting device can be increased. Moreover, the width of emission spectra can be narrowed. Alternatively, the saturation of an emission color can be increased. As a result, a novel display apparatus that is highly convenient, useful, or reliable can be provided.

By adjusting the distance from the interface between the layer HNX(i,j) and the layer LNX(i,j) to the layer 111X(i,j), light emitted from the layer 111X(i,j) toward the electrode 552X(i,j) can be intensified with the use of the light reflected at the interface between the layer HNX(i,j) and the layer LNX(i,j)(see FIG. 2B). For example, the distance from the interface between the layer HNX(i,j) and the layer LNX(i,j) to the central plane of the layer 111X(i,j) is set to approximately half of the value obtained by dividing the wavelength λX by the refractive index of the layer HNX(i,j).

By adjusting the distance from the layer 111X(i,j) to the electrode 552X(i,j), light emitted from the layer 111X(i,j) toward the electrode 551X(i,j) can be intensified with the use of light reflected by the electrode 552X(i,j)(see FIG. 2B). For example, the distance from the center plane of the layer 111X(i,j) to the electrode 552X(i,j) is set to approximately ¾ of the value obtained by dividing the wavelength λX by the refractive index of the layer HNX(i,j).

### <<Structure Example 2 of Layer LNY(i,j)>>

The layer LNY(i,j) contains the same material as the layer LNX(i,j), and the layer LNY(i,j) has the same thickness as the layer LNX(i,j).

Thus, the layer LNX(i,j) and the layer LNY(i,j) can be formed in the same step. In addition, the manufacturing process can be simplified. Part of the light emitted from the unit 103X(i,j) toward the reflective film REFX(i,j) can be reflected at the interface between the layer HNX(i,j) and the layer LNX(i,j). Another part of the light can be reflected by the reflective film REFX(i,j). Furthermore, with the use of the light reflected at the interface between the layer HNX(i,j) and the layer LNX(i,j), the light reflected by the reflective film REFX(i,j) can be intensified. Part of light emitted from the unit 103Y(i,j) toward the reflective film REFY(i,j) can be reflected at the interface between the layer HNY(i,j) and the layer LNY(i,j). Another part of the light can be reflected by the reflective film REFY(i,j). Furthermore, with the use of the light reflected at the interface between the layer HNY(i,j) and the layer LNY(i,j), the light reflected by the reflective film REFY(i,j) can be intensified. As a result, a novel display apparatus that is highly convenient, useful, or reliable can be provided.

### <<Structure Example 2 of Light-Emitting Device 550X(i,j)>>

The light-emitting device 550X(i,j) includes an intermediate layer 106X(i,j) and a unit 103X2(i,j)(see FIG. 3).

The unit 103X2(i,j) is interposed between the electrode 552X(i,j) and the intermediate layer 106X(i,j), and contains a light-emitting material EMX2.

The intermediate layer 106X(i,j) is interposed between the unit 103X2(i,j) and the unit 103X(i,j).

In other words, the light-emitting device 550X(i,j) includes the stacked units between the electrode 551X(i,j) and the electrode 552X(i,j). Note that the number of stacked units is not limited to two, and three or more units can be stacked. A structure including the stacked units interposed between the electrode 551X(i,j) and the electrode 552X(i,j) and the intermediate layer 106X(i,j) interposed between the units is referred to as a stacked light-emitting device or a tandem light-emitting device in some cases.

Note that a structure example that can be used for the intermediate layer 106X(i,j) and a structure example that can be used for the unit 103X2(i,j) will be described in detail in Embodiment 5.

### <<Structure Example 2 of Light-Emitting Device 550Y(i,j)>>

The light-emitting device 550Y(i,j) includes an intermediate layer 106Y(i,j) and a unit 103Y2(i,j).

The unit 103Y2(i,j) is interposed between the electrode 552Y(i,j) and the intermediate layer 106Y(i,j), and contains a light-emitting material EMY2.

The intermediate layer 106Y(i,j) is interposed between the unit 103Y2 (i,j) and the unit 103Y(i,j).

Thus, emission intensity at the same current density can be increased. Moreover, the current efficiency in light emission can be increased. Furthermore, energy efficiency in light emission can be increased. As a result, a novel display apparatus that is highly convenient, useful, or reliable can be provided.

### <<Structure Example 3 of Light-Emitting Device 550Y(i,j)>>

Moreover, a structure emitting light whose hue is the same as that of light emitted from the light-emitting device 550X(i,j) can be used for the light-emitting device 550Y(i,j).

For example, both the light-emitting device 550X(i,j) and the light-emitting device 550Y(i,j) may emit white light. A coloring layer is provided to overlap with the light-emitting device 550X(i,j), whereby light of a predetermined hue can be extracted from white light. Another coloring layer is provided to overlap with the light-emitting device 550Y(i,j), whereby light of another predetermined hue can be extracted from white light.

For example, both the light-emitting device 550X(i,j) and the light-emitting device 550Y(i,j) may emit blue light. Note that a color conversion layer is provided to overlap with the light-emitting device 550X(i,j), whereby blue light can be converted into light of a predetermined hue. Another color conversion layer is provided to overlap with the light-emitting device 550Y(i,j), whereby blue light can be converted into light of another predetermined hue. Blue light can be converted into green light or red light, for example.

### <<Structure Example 4 of Light-Emitting Device 550Y(i,j)>>

Moreover, a structure emitting light whose hue is different from that of light emitted from the light-emitting device 550X(i,j) can be used for the light-emitting device 550Y(i,j). For example, the hue of light ELY emitted from the unit 103Y(i,j) can be different from that of light ELX.

### <<Structure Example 1 of Light-Emitting Material EMY>>

A material different from the light-emitting material EMX can be used as the light-emitting material EMY. For example, a material that emits light with a hue different from that of light emitted from the light-emitting material EMX can be used as the light-emitting material EMY. Specifically, when the light-emitting material EMX emits light with one hue selected from blue, green, red, and white, a material that emits light with another hue can be used as the light-emitting material EMY.

### <Structure Example 2 of Display Apparatus 700>

The display apparatus 700 of one embodiment of the present invention includes the insulating film 521, the conductive film 552, and a film 529_3 (see FIG. 1C). The display apparatus 700 further includes a layer 105, a film 529_1, and a film 529_2.

The reflective film REFX(i,j) is interposed between the insulating film 521 and the layer LNX(i,j), and the reflective film REFY(i,j) is interposed between the insulating film 521 and the layer LNY(i,j).

### <<Structure Example of Conductive Film 552>>

The conductive film 552 overlaps with the insulating film 521 and includes the electrode 552X(i,j) and the electrode 552Y(i,j).

A material having both a light-transmitting property and conductivity can be used for the conductive film 552. Note that a structure example that can be employed for the conductive film 552 is described in detail in Embodiment 4.

### <<Structure Example of Layer 105>>

The layer 105 includes a layer 105X(i,j) and a layer 105Y(i,j). A material that facilitates carrier injection from the electrode 552X(i,j) can be used for the layer 105X(i,j). A material having an electron-injection property can be used for the layer 105X(i,j), for example. Note that a structure example that can be employed for the layer 105X(i,j) is described in detail in Embodiment 4.

In this specification and the like, a device manufactured using a metal mask or an FMM (fine metal mask, high-resolution metal mask) may be referred to as a device having an MM (metal mask) structure. In this specification and the like, a device manufactured without using a metal mask or an FMM may be referred to as a device having an MML (metal maskless) structure.

### <<Structure Example of Film 529_1>>

The film 529_1 has opening portions; one opening portion overlaps with the electrode 551X(i,j) and the other opening portion overlaps with the electrode 551Y(i,j). The film 529_1 includes an opening portion overlapping with the space HNXY(i,j). For example, a film containing a metal, a metal oxide, an organic material, or an inorganic insulating material can be used as the film 529_1. Specifically, a light-blocking metal film can be used. Accordingly, the structure of the light-emitting device can be protected from light emitted in the processing step.

### <<Structure Example of Film 529_2>>

The film 529_2 has opening portions; one opening portion overlaps with the electrode 551X(i,j) and the other opening portion overlaps with the electrode 551Y(i,j). The film 529_2 overlaps with the space HNXY(i,j).

The film 529_2 includes a region in contact with the layer HNX(i,j) and the unit 103X(i,j).

The film 529_2 includes a region in contact with the layer HNY(i,j) and the unit 103Y(i,j).

The film 529_2 includes a region in contact with the insulating film 521. The film 529_2 can be formed by an atomic layer deposition (ALD) method, for example. Thus, a film with favorable coverage can be formed. Specifically, a metal oxide film or the like can be used as the film 529_2. Aluminum oxide can be used, for example.

### <<Structure Example of Film 529 3>>

The film 529_3 is interposed between the conductive film 552 and the insulating film 521 and fills the space HNXY(i,j). The film 529_3 has an insulating property.

The film 529_3 includes an opening portion 529_3X(i,j) and an opening portion 529_3Y(i,j), the opening portion 529_3X(i,j) overlaps with the electrode 551X(i,j), and the opening portion 529_3Y(i,j) overlaps with the electrode 551Y(i,j).

The film 529_3 can be formed using a photosensitive resin, for example. Specifically, an acrylic resin or the like can be used.

Accordingly, the layer HNX(i,j) can be electrically isolated from the layer HNY(i,j), for example. Moreover, current flowing between the layer HNX(i,j) and the layer HNY(i,j) can be reduced. Furthermore, a phenomenon in which the light-emitting device 550Y(i,j) that is adjacent to the light-emitting device 550X(i,j) unintentionally emits light in accordance with the operation of the light-emitting device 550X(i,j) can be inhibited. The size of a step generated between the top surface of the unit 103X(i,j) and the top surface of the unit 103Y(i,j) can be reduced. Occurrence of a phenomenon in which a split portion or a portion with a small film thickness due to the step is formed between the electrode 552X(i,j) and the electrode 552Y(i,j) can be inhibited. One conductive film can be used for the electrode 552X(i,j) and the electrode 552Y(i,j). As a result, a novel display apparatus that is highly convenient, useful, or reliable can be provided.

Note that part or the whole of the structure that can be employed for the light-emitting device 550Y(i,j) can be removed from the space HNXY(i,j) by using a photolithography method, for example.

Specifically, in a first step, a first film to be the unit 103Y(i,j) later is formed over the space HNXY(i,j).

In a second step, a second film to be the film 529_1 later is formed over a film to be the unit 103Y(i,j) later.

In a third step, an opening portion overlapping with the space HNXY(i,j) is formed in the second film by a photolithography method.

In a fourth step, part of the first film is removed using the second film as a resist. For example, part of the first film is removed from the space HNXY(i,j) by a dry etching method. Specifically, part of the first film can be removed from the space HNXY(i,j) using an oxygen-containing gas. Thus, a groove is formed in the first film.

In a fifth step, a third film to be the film 529_2 later is formed over the second film by an ALD method, for example.

In a sixth step, the film 529_3 is formed with the use of a photosensitive polymer, for example. Thus, the film 529_3 fills the space HNXY(i,j). The opening portion 529_3X(i,j) and the opening portion 529_3Y(i,j) are formed in the film 529 3.

In a seventh step, an opening portion overlapping with the electrode 551Y(i,j) is formed by a photolithography method in the third film and the second film to form the film 529_2 and the film 529_1.

In an eighth step, the layer 105Y(i,j) is formed over the unit 103Y(i,j), and the electrode 552Y(i,j) is formed over the layer 105Y(i,j).

### <<Structure Example of Reflective Film REFX(i,j)>>

The reflective film REFX(i,j) is electrically connected to the electrode 551X(i,j), and the reflective film REFY(i,j) is electrically connected to the electrode 551Y(i,j)(see FIG. 2C).

For example, a film that efficiently reflects light can be used for the reflective film REFX(i,j). Specifically, an alloy containing silver, copper, and the like, an alloy containing silver, palladium, and the like, or a metal film of aluminum or the like can be used for the reflective film REFX(i,j).

Thus, a wiring can be used as the reflective film REFX(i,j), for example. In addition, the structure of a display apparatus can be simplified. As a result, a novel display apparatus that is highly convenient, useful, or reliable can be provided.

Note that this embodiment can be combined with any of the other embodiments described in this specification as appropriate.

### Embodiment 2

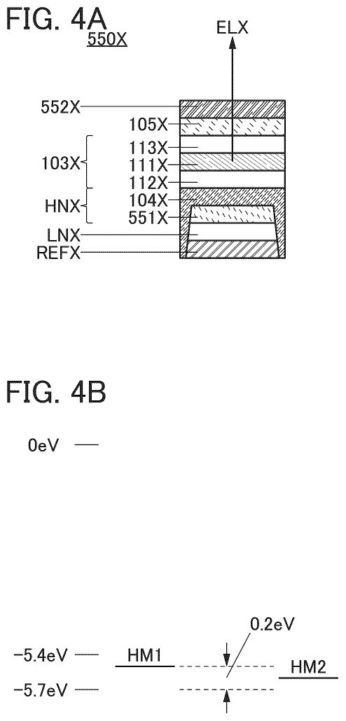

In this embodiment, a structure of a light-emitting device that can be used in a display apparatus of one embodiment of the present invention will be described with reference to FIG. 4A and FIG. 4B.

FIG. 4A is a cross-sectional view illustrating a structure of a light-emitting device that can be used in a display apparatus of one embodiment of the present invention, and FIG. 4B is a diagram illustrating energy levels of a material used for the light-emitting device.

Structures of the light-emitting device 550X described in this embodiment can be employed for the display apparatus of one embodiment of the present invention. Note that the description of the structure of the light-emitting device 550X can be applied to the light-emitting device 550X(i,j). Specifically, the reference numerals used in the description of the light-emitting device 550X can be used for the description of the light-emitting device 550X(i,j) by replacing “X” with “X(i,j)”. Similarly, the structure of the light-emitting device 550X can be employed for the light-emitting device 550Y(i,j) by replacing “X” with “Y(i,j).

### <Structure Example of Light-Emitting Device 550X>

The light-emitting device 550X described in this embodiment includes the layer HNX, the electrode 552X, and the unit 103X, and the electrode 552X overlaps with the layer HNX (see FIG. 4A). The unit 103X is interposed between the electrode 552X and the layer HNX.

### <Structure Example of Unit 103X>

The unit 103X has a single-layer structure or a stacked-layer structure. For example, the unit 103X includes a layer 111X, the layer 112X, and a layer 113X (see FIG. 4A). Note that the unit 103X has a function of emitting the light ELX.

The layer 111X is interposed between the layer 113X and the layer 112X, the layer 113X is interposed between the electrode 552X and the layer 111X, and the layer 112X is interposed between the layer 111X and the layer HNX.

For example, a layer selected from functional layers such as a light-emitting layer, a hole-transport layer, an electron-transport layer, and a carrier-blocking layer can be used in the unit 103X. Moreover, the layer selected from functional layers such as a hole-injection layer, an electron-injection layer, an exciton-blocking layer, and a charge-generation layer can be used in the unit 103X.

### <<Structure Example of Layer 112X>>

For example, a material having a hole-transport property can be used for the layer 112X. The layer 112X can be referred to as a hole-transport layer. A material having a wider band gap than the light-emitting material contained in the layer 111X is preferably used for the layer 112X. In that case, energy transfer from excitons generated in the layer 111X to the layer 112X can be inhibited.

### [Material Having Hole-Transport Property]

A material having a hole mobility higher than or equal to 1×10⁻⁶ cm²/Vs can be suitably used as the material having a hole-transport property.

As the material having a hole-transport property, an amine compound or an organic compound having a π-electron rich heteroaromatic ring skeleton can be used, for example. Specifically, a compound having an aromatic amine skeleton, a compound having a carbazole skeleton, a compound having a thiophene skeleton, a compound having a furan skeleton, or the like can be used. The compound having an aromatic amine skeleton and the compound having a carbazole skeleton are particularly preferable because these compounds are highly reliable and have high hole-transport properties to contribute to a reduction in driving voltage.

As the compound having an aromatic amine skeleton, for example, 4,4′-bis[N-(1-naphthyl)-N-phenylamino]biphenyl (abbreviation: NPB), N,N′-diphenyl-N,N-bis(3-methylphenyl)-4,4′-diaminobiphenyl (abbreviation: TPD), N,N′-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine 4-phenyl-4′-(9-phenyl-9H-carbazol-3-yl)triphenylamine (abbreviation: mBPAFLP), (abbreviation: PCBA1BP), 4,4′-diphenyl-4′-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), or the like can be used.

As the compound having a carbazole skeleton, for example, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole)(abbreviation: PCCP), or the like can be used.

As the compound having a thiophene skeleton, for example, 4,4′,4″-(benzene-1,3,5-triyl)tri (dibenzothiophene)(abbreviation: DBT3P-II), 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), or the like can be used.

As the compound having a furan skeleton, for example, 4,4′,4″-(benzene-1,3,5-triyl)tri (dibenzofuran)(abbreviation: DBF3P-II), 4-{3-[3-(9-phenyl-9H-fluoren-9-yl)phenyl]phenyl}dibenzofuran (abbreviation: mmDBFFLBi-II), or the like can be used.

### <<Structure Example of Layer 113X>>

A material having an electron-transport property, a material having an anthracene skeleton, or a mixed material can be used for the layer 113X, for example. The layer 113X can be referred to as an electron-transport layer. Note that a material having a wider band gap than the light-emitting material contained in the layer 111X is preferably used for the layer 113X. In that case, energy transfer from excitons generated in the layer 111X to the layer 113X can be inhibited.

### [Material Having Electron-Transport Property]

A material having an electron mobility higher than or equal to 1×10⁻⁷ cm²/Vs and lower than or equal to 5×10⁻⁵ cm²/Vs in a condition where the square root of the electric field strength [V/cm] is 600 can be suitably used as the material having an electron-transport property. Thus, the electron-transport property in the electron-transport layer can be inhibited. Alternatively, the amount of electrons injected into the light-emitting layer can be controlled. Alternatively, the light-emitting layer can be prevented from having excess electrons.

For example, a metal complex or an organic compound having a π-electron deficient heteroaromatic ring skeleton can be used as the material having an electron-transport property.

As the metal complex, for example, bis(10-hydroxybenzo[h]quinolinato) beryllium (II) (abbreviation: BeBq₂), bis(2-methyl-8-quinolinolato)(4-phenylphenolato)aluminum (III) (abbreviation: BAlq), bis(8-quinolinolato) zinc (II)(abbreviation: Znq), bis[2-(2-benzoxazolyl) phenolato]zinc (II)(abbreviation: ZnPBO), bis[2-(2-benzothiazolyl) phenolato]zinc (II)(abbreviation: ZnBTZ), or the like can be used.

As the organic compound having a π-electron deficient heteroaromatic ring skeleton, for example, a heterocyclic compound having a polyazole skeleton, a heterocyclic compound having a diazine skeleton, a heterocyclic compound having a pyridine skeleton, a heterocyclic compound having a triazine skeleton, or the like can be used. In particular, the heterocyclic compound having a diazine skeleton or the heterocyclic compound having a pyridine skeleton has favorable reliability and thus is preferable. In addition, the heterocyclic compound having a diazine (pyrimidine or pyrazine) skeleton has a high electron-transport property to contribute to a reduction in driving voltage.

As the heterocyclic compound having a polyazole skeleton, for example, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole)(abbreviation: TPBI), 2-[3-(dibenzothiophen-4-yl)phenyl]-1-phenyl-1H-benzimidazole (abbreviation: mDBTBIm-II), or the like can be used.

As the heterocyclic compound having a diazine skeleton, for example, 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,8-bis[3-(dibenzothiophen-4-yl)phenyl]benzo[h]quinazoline (abbreviation: 4,8mDBtP2Bqn), or the like can be used.

As the heterocyclic compound having a pyridine skeleton, for example, 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), or the like can be used.

As the heterocyclic compound having a triazine skeleton, for example, 2-[3′-(9,9-dimethyl-9H-fluoren-2-yl)biphenyl-3-yl]-4,6-diphenyl-1,3,5-triazine (abbreviation: mFBPTzn), 2-[(1,1′-biphenyl)-4-yl]-4-phenyl-6-[9,9′-spirobi (9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), or the like can be used.

### [Material Having Anthracene Skeleton]

An organic compound having an anthracene skeleton can be used for the layer 113X. In particular, an organic compound having both an anthracene skeleton and a heterocyclic skeleton can be suitably used.

For example, an organic compound having both an anthracene skeleton and a nitrogen-containing five-membered ring skeleton can be used for the layer 113X. Alternatively, an organic compound having both an anthracene skeleton and a nitrogen-containing five-membered ring skeleton where two heteroatoms are included in a ring can be used for the layer 113X. Specifically, a pyrazole ring, an imidazole ring, an oxazole ring, a thiazole ring, or the like can be suitably used as the heterocyclic skeleton.

For example, an organic compound having both an anthracene skeleton and a nitrogen-containing six-membered ring skeleton can be used for the layer 113X. Alternatively, an organic compound having both an anthracene skeleton and a nitrogen-containing six-membered ring skeleton where two heteroatoms are included in a ring can be used for the layer 113X. Specifically, a pyrazine ring, a pyrimidine ring, a pyridazine ring, or the like can be suitably used as the heterocyclic skeleton.

### [Structure Example of Mixed Material]

A material in which a plurality of kinds of substances are mixed can be used for the layer 113X. Specifically, a mixed material that contains a substance having an electron-transport property and any of an alkali metal, an alkali metal compound, and an alkali metal complex can be used for the layer 113X. Note that it is further preferable that the HOMO level of the material having an electron-transport property be higher than or equal to −6.0 eV.

The mixed material can be suitably used for the layer 113X in combination with a structure using a composite material, which is described later, for a layer 104X. For example, a composite material of a substance having an electron-accepting property and a material having a hole-transport property can be used for the layer 104X. Specifically, a composite material of a substance having an electron-accepting property and a substance having a relatively deep HOMO level HM1, which is higher than or equal to −5.7 eV and lower than or equal to −5.4 eV, can be used for the layer 104X (see FIG. 4B). Using the mixed material for the layer 113X in combination with the structure using such a composite material for the layer 104X, whereby the reliability of the light-emitting device can be improved.

Furthermore, a structure using a material having a hole-transport property for the layer 112X is preferably combined with the structure using the mixed material for the layer 113X and the composite material for the layer 104X. For example, a substance having a HOMO level HM2, which is within the range of −0.2 eV to 0 eV from the relatively deep HOMO level HM1, can be used for the layer 112X (see FIG. 4B). As a result, the reliability of the light-emitting device can be increased. Note that in this specification and the like, the structure of the above light-emitting device is referred to as a Recombination-Site Tailoring Injection structure (ReSTI structure) in some cases.

The concentration of the alkali metal, the alkali metal compound, or the alkali metal complex preferably differs in the thickness direction of the layer 113X (including the case where the concentration is 0).

For example, a metal complex having an 8-hydroxyquinolinato structure can be used. A methyl-substituted product of the metal complex having an 8-hydroxyquinolinato structure (e.g., a 2-methyl-substituted product or a 5-methyl-substituted product) or the like can also be used. As the metal complex having an 8-hydroxyquinolinato structure, 8-hydroxyquinolinato-lithium (abbreviation: Liq), 8-hydroxyquinolinato-sodium (abbreviation: Naq), or the like can be used. In particular, a complex of a monovalent metal ion, especially a complex of lithium is preferable, and Liq is further preferable.

### <<Structure Example 1 of Layer 111X>>

A light-emitting material or a light-emitting material and a host material can be used for the layer 111X, for example. The layer 111X can be referred to as a light-emitting layer. The layer 111X is preferably provided in a region where holes and electrons are recombined. In that case, energy generated by recombination of carriers can be efficiently converted into light and emitted.

Furthermore, the layer 111X is preferably provided apart from a metal used for the electrode or the like. In that case, a quenching phenomenon caused by the metal used for the electrode or the like can be inhibited.

It is preferable that a distance from an electrode or the like having a reflective property to the layer 111X be adjusted and the layer 111X be provided in an appropriate position in accordance with an emission wavelength. Thus, the amplitude can be increased by utilizing an interference phenomenon between light reflected by the electrode or the like and light emitted from the layer 111X. Light of a predetermined wavelength can be intensified and the spectrum of the light can be narrowed. In addition, bright light emission colors with high intensity can be obtained. In other words, the layer 111X is provided in an appropriate position, for example, between electrodes and the like, and thus a microcavity structure (microcavity) can be formed.

For example, a fluorescent substance, a phosphorescent substance, or a substance exhibiting thermally activated delayed fluorescence (TADF)(also referred to as a TADF material) can be used as the light-emitting material. Thus, energy generated by recombination of carriers can be released as the light ELX from the light-emitting material (see FIG. 4A).

### [Fluorescent Substance]

A fluorescent substance can be used for the layer 111X. For example, any of the following fluorescent substances can be used for the layer 111X. Note that without being limited to the following ones, any of a variety of known fluorescent substances can be used for the layer 111X.

Specifically, it is possible to use, for example, 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N′-bis[4-(9-phenyl-9H-fluoren-9-yl)phenyl]pyrene-1,6-diamine (abbreviation: 1,6FLPAPrn), N,N-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl) perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine](abbreviation: DPABPA), N,9-diphenyl-N-[4-(9,10-diphenyl-2-anthryl)phenyl]-9H-carbazol-3-amine (abbreviation: 2PCAPPA), N,N′-(pyrene-1,6-diyl)bis[(6,N-diphenylbenzo[b]naphtho[1,2-d]furan)-8-amine] (abbreviation: 1,6BnfAPrn-03), 3,10-bis[N-(9-phenyl-9H-carbazol-2-yl)-N-phenylamino]naphtho[2,3-b; 6,7-b′]bisbenzofuran (abbreviation: 3,10PCA2Nbf (IV)-02), or 3,10-bis[N-(dibenzofuran-3-yl)-N-phenylamino]naphtho[2,3-b; 6,7-b′]bisbenzofuran (abbreviation: 3,10FrA2Nbf (IV)-02).

Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

In addition, it is possible to use, for example, N-[4-(9,10-diphenyl-2-anthryl)phenyl]-N,N′,N′-triphenyl-1,4-phenylenediamine (abbreviation: 2DPAPPA), N,N,N,N,N″,N″,N″,N′″-octaphenyldibenzo[g,p]chrysene-2,7,10,15-tetraamine (abbreviation: DBC1), coumarin 30, 9,10-diphenyl-2-[N-phenyl-N-(9-phenyl-carbazol-3-yl)-amino]-anthracene (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracene-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, or 5,12-bis(1,1′-biphenyl-4-yl)-6,11-diphenyltetracene (abbreviation: BPT).

Furthermore, it is possible to use, for example, 2-(2-{2-[4-(dimethylamino)phenyl]ethenyl}-6-methyl-4H-pyran-4-ylidene) propanedinitrile (abbreviation: DCM1), 2-{2-methyl-6-[2-(2,3,6,7-tetrahydro-1H,5H-benzo[ij]quinolizin-9-yl) ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl) acenaphtho[1,2-α]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl) ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl) ethenyl]-4H-pyran-4-ylidene}propanedinitrile (abbreviation: DCJTB), 2-(2,6-bis {2-[4-(dimethylamino)phenyl]ethenyl}-4H-pyran-4-ylidene) propanedinitrile (abbreviation: BisDCM), or 2-{2,6-bis[2-(8-methoxy-1,1,7,7-tetramethyl-2,3,6,7-tetrahydro-1H,5H-benzo[ij]quinolizin-9-yl) ethenyl]-4H-pyran-4-ylidene}propanedinitrile (abbreviation: BisDCJTM).

### [Phosphorescent Substance]

A phosphorescent substance can be used for the layer 111X. For example, any of the following phosphorescent substances can be used for the layer 111X. Note that without being limited to the following ones, any of a variety of known phosphorescent substances can be used for the layer 111X.

For the layer 111X, it is possible to use, for example, an organometallic iridium complex having a 4H-triazole skeleton, an organometallic iridium complex having a 1H-triazole skeleton, an organometallic iridium complex having an imidazole skeleton, an organometallic iridium complex having a phenylpyridine derivative with an electron-withdrawing group as a ligand, an organometallic iridium complex having a pyrimidine skeleton, an organometallic iridium complex having a pyrazine skeleton, an organometallic iridium complex having a pyridine skeleton, a rare earth metal complex, or a platinum complex.

### [Phosphorescent Substance (Blue)]

As the organometallic iridium complex having a 4H-triazole skeleton or the like, for example, tris {2-[5-(2-methylphenyl)-4-(2,6-dimethylphenyl)-4H-1,2,4-triazol-3-yl-κN2]phenyl-KC}iridium(III)(abbreviation: [Ir(mpptz-dmp)₃]), tris(5-methyl-3,4-diphenyl-4H-1,2,4-triazolato)iridium(III)(abbreviation: [Ir(Mptz)₃]), tris[4-(3-biphenyl)-5-isopropyl-3-phenyl-4H-1,2,4-triazolato]iridium(III)(abbreviation: [Ir(iPrptz-3b)₃]), or the like can be used.

As the organometallic iridium complex having a 1H-triazole skeleton or the like, for example, tris[3-methyl-1-(2-methylphenyl)-5-phenyl-1H-1,2,4-triazolato]iridium(III) (abbreviation: [Ir(Mptz1-mp)₃]), tris(1-methyl-5-phenyl-3-propyl-1H-1,2,4-triazolato]iridium(III) (abbreviation: [Ir(Prptz1-Me)₃]), or the like can be used.

As the organometallic iridium complex having an imidazole skeleton or the like, for example, fac-tris[1-(2,6-diisopropylphenyl)-2-phenyl-1H-imidazole]iridium(III)(abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), or the like can be used.

As the organometallic iridium complex having a phenylpyridine derivative with an electron-withdrawing group as a ligand, or the like, for example, bis[2-(4′,6′-difluorophenyl)pyridinato-N,C^{2′}]iridium(III) tetrakis(1-pyrazolyl) borate (abbreviation: FIr6), bis[2-(4′,6′-difluorophenyl)pyridinato-N,C^{2′}]iridium(III) picolinate (abbreviation: FIrpic), bis {2-[3′,5′-bis(trifluoromethyl)phenyl]pyridinato-N,C^{2′}}iridium(III) picolinate (abbreviation: [Ir(CF₃ppy)₂(pic)]), bis[2-(4′,6′-difluorophenyl)pyridinato-N,C^{2′}]iridium(III) acetylacetonate (abbreviation: FIracac), or the like can be used.

Note that these are compounds exhibiting blue phosphorescence and are compounds having an emission wavelength peak at 440 nm to 520 nm.

### [Phosphorescent Substance (Green)]

As the organometallic iridium complex having a pyrimidine skeleton or the like, it is possible to use, for example, tris(4-methyl-6-phenylpyrimidinato)iridium(III)(abbreviation: [Ir(mppm)₃]), tris(4-t-butyl-6-phenylpyrimidinato)iridium(III)(abbreviation: [Ir(tBuppm)₃]), (acetylacetonato)bis(6-methyl-4-phenylpyrimidinato)iridium(III)(abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III)(abbreviation: [Ir(nbppm)₂(acac)]), (acetylacetonato)bis[5-methyl-6-(2-methylphenyl)-4-phenylpyrimidinato]iridium(III)(abbreviation: [Ir(mpmppm)₂(acac)]), (acetylacetonato)bis(4,6-diphenylpyrimidinato)iridium(III)(abbreviation: [Ir(dppm)₂(acac)]), or the like.

As the organometallic iridium complex having a pyrazine skeleton or the like, for example, (acetylacetonato)bis(3,5-dimethyl-2-phenylpyrazinato)iridium(III)(abbreviation: [Ir(mppr-Me)₂(acac)]), (acetylacetonato)bis(5-isopropyl-3-methyl-2-phenylpyrazinato)iridium(III)(abbreviation: [Ir(mppr-iPr)₂(acac)]), or the like can be used.

As the organometallic iridium complex having a pyridine skeleton or the like, it is possible to use, for example, tris(2-phenylpyridinato-N,C^{2′})iridium(III)(abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III)(abbreviation: [Ir(bzq)₃]), tris(2-phenylquinolinato-[Ir(pq)₃]), bis(2-phenylquinolinato-N,C^{2′})iridium(III) N,C²)iridium(III)(abbreviation: acetylacetonate (abbreviation: [Ir(pq)₂(acac)]), [2-d₃-methyl-8-(2-pyridinyl-κN)benzofuro[2,3-b]pyridine-KC]bis[2-(5-d₃-methyl-2-pyridinyl-κN²)phenyl-κC]iridium(III)(abbreviation: [Ir(5mppy-d₃)₂(mbfpypy-d₃)]), [2-d₃-methyl-(2-pyridinyl-κN)benzofuro[2,3-b]pyridine-κC]bis[2-(2-pyridinyl-κN)phenyl-κC]iridium(III)(abbreviation: [Ir(ppy)₂(mbfpypy-d₃)]), or the like.

An example of the rare earth metal complex is tris(acetylacetonato) (monophenanthroline) terbium (III)(abbreviation: [Tb(acac)₃(Phen)]).

Note that these are compounds mainly exhibiting green phosphorescence and have an emission wavelength peak at 500 nm to 600 nm. An organometallic iridium complex having a pyrimidine skeleton excels particularly in reliability or emission efficiency.

### [Phosphorescent Substance (Red)]

As the organometallic iridium complex having a pyrimidine skeleton or the like, for example, (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), bis[4,6-di(naphthalen-1-yl)pyrimidinato](dipivaloylmethanato)iridium(III)(abbreviation: [Ir(dlnpm)₂(dpm)]), or the like can be used.

As the organometallic iridium complex having a pyrazine skeleton or the like, for example, (acetylacetonato)bis(2,3,5-triphenylpyrazinato)iridium(III)(abbreviation: [Ir(tppr)₂(acac)]), bis(2,3,5-triphenylpyrazinato)(dipivaloylmethanato)iridium(III)(abbreviation: [Ir(tppr)₂(dpm)]), (acetylacetonato)bis[2,3-bis(4-fluorophenyl) quinoxalinato]iridium(III) (abbreviation: [Ir(Fdpq)₂(acac)]), or the like can be used.

As the organometallic iridium complex having a pyridine skeleton or the like, for example, tris(1-phenylisoquinolinato-N,C²)iridium(III)(abbreviation: [Ir(piq)₃]), bis(1-phenylisoquinolinato-N,C²)iridium(III) acetylacetonate (abbreviation: [Ir(piq)₂(acac)]), or the like can be used.

As the rare earth metal complex or the like, for example, tris(1,3-diphenyl-1,3-propanedionato)(monophenanthroline) europium (III)(abbreviation: [Eu(DBM)₃(Phen)]), tris[1-(2-thenoyl)-3,3,3-trifluoroacetonato](monophenanthroline) europium (III)(abbreviation: [Eu(TTA)₃(Phen)]), or the like can be used.

As the platinum complex or the like, 2,3,7,8,12,13,17,18-octaethyl-21H,23H-porphyrin platinum (II)(abbreviation: PtOEP) or the like can be used.

Note that these are compounds exhibiting red phosphorescence and have an emission peak at 600 nm to 700 nm. Furthermore, from the organometallic iridium complex having a pyrazine skeleton, red light emission with chromaticity favorably used for display apparatuses can be obtained.

### [Substance Exhibiting Thermally Activated Delayed Fluorescence (TADF)]

A TADF material can be used for the layer 111X. When a TADF material is used as a light-emitting substance, the S1 level of the host material is preferably higher than that of the TADF material. In addition, the T1 level of the host material is preferably higher than that of the TADF material.

For example, any of the TADF materials given below can be used as the light-emitting material. Note that without being limited thereto, any of a variety of known TADF materials can be used.

In the TADF material, the difference between the S1 level and the T1 level is small, and reverse intersystem crossing (upconversion) from the triplet excited state into the singlet excited state can be achieved by a little thermal energy. Thus, the singlet excited state can be efficiently generated from the triplet excited state. In addition, the triplet excitation energy can be converted into light.

An exciplex whose excited state is formed of two kinds of substances has an extremely small difference between the S1 level and the T1 level and functions as a TADF material capable of converting triplet excitation energy into singlet excitation energy.

A phosphorescence spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

Examples of the TADF material include a fullerene, a derivative thereof, an acridine, a derivative thereof, and an eosin derivative. Furthermore, porphyrin containing a metal such as magnesium (Mg), zinc (Zn), cadmium (Cd), tin (Sn), platinum (Pt), indium (In), or palladium (Pd) can be also used for the TADF material.

Specifically, any of the following materials whose structural formulae are shown below can be used: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), and the like.

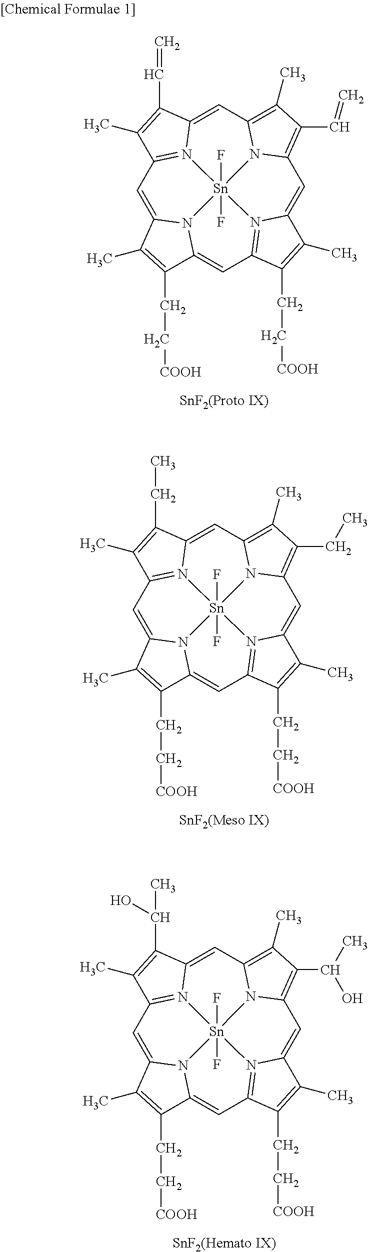

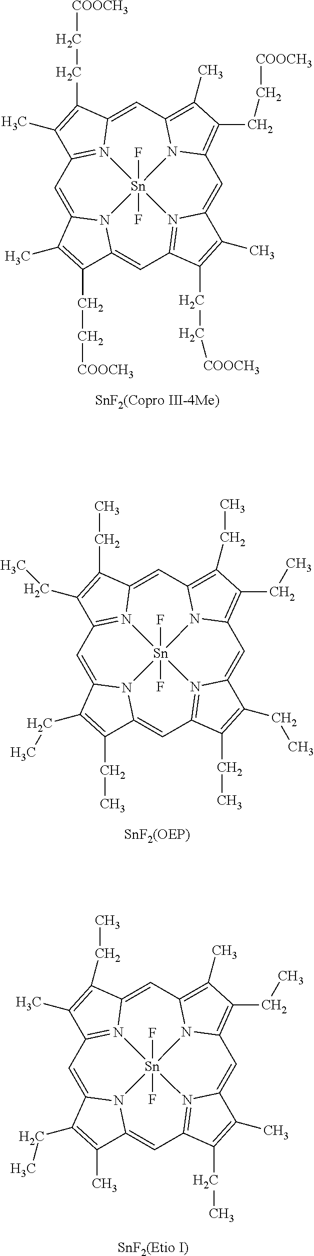

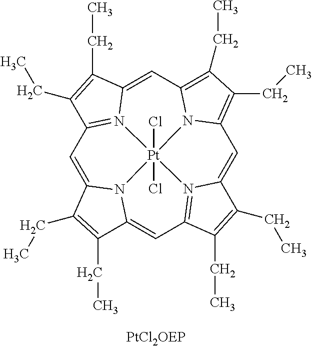

Furthermore, a heterocyclic compound including one or both of a π-electron rich heteroaromatic ring and a π-electron deficient heteroaromatic ring can be used for the TADF material, for example.

Specifically, any of the following materials whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), and the like.

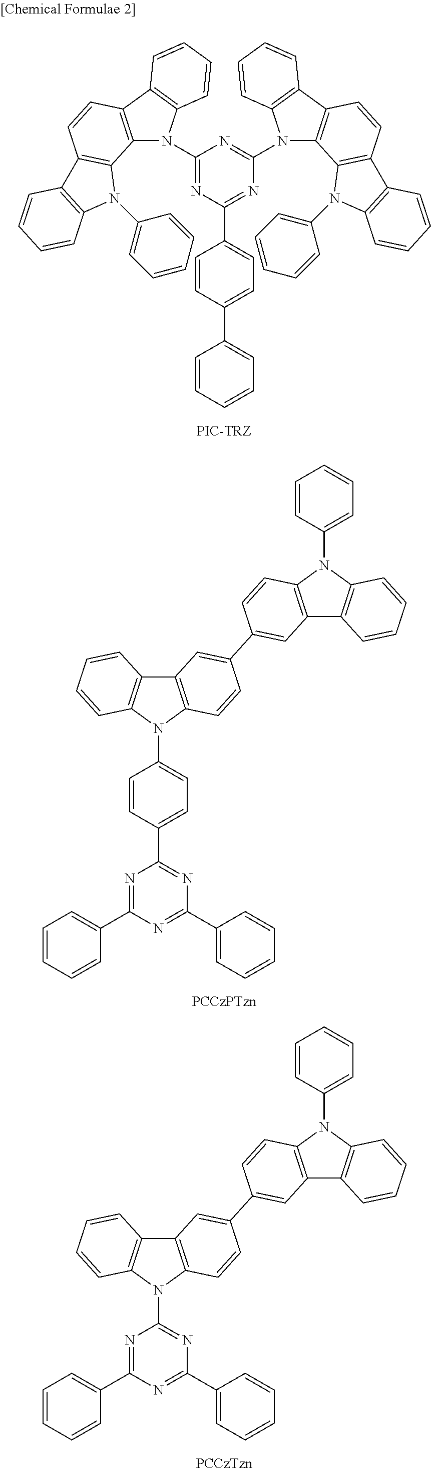 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

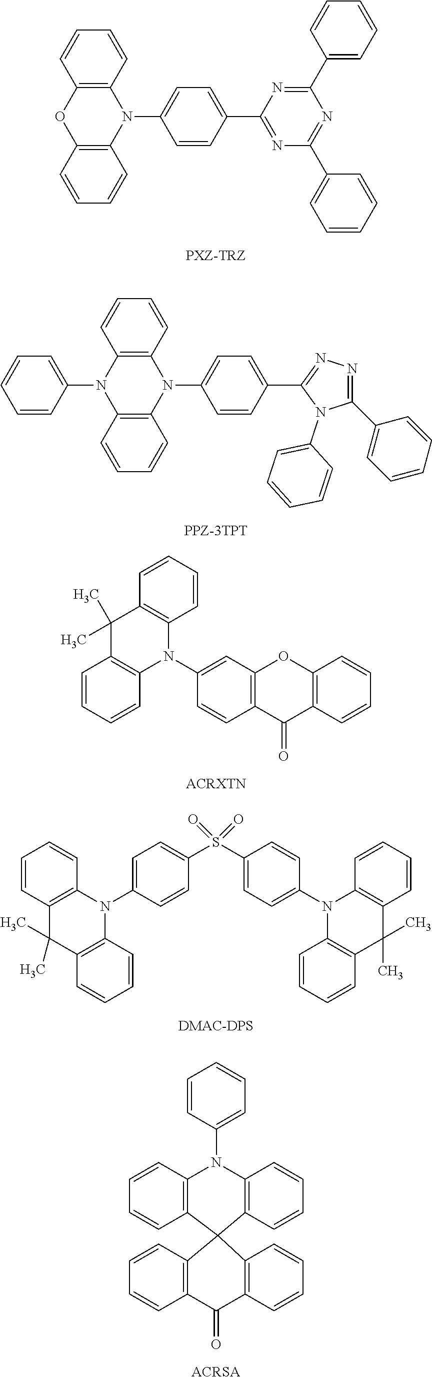 [SMILES: c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Such a heterocyclic compound is preferable because of having a high electron-transport property and a high hole-transport property owing to a π-electron rich heteroaromatic ring and a π-electron deficient heteroaromatic ring. Among skeletons having the π-electron deficient heteroaromatic ring, in particular, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high electron-accepting properties and reliability.

Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a nitrile group or a cyano group such as benzonitrile or cyanobenzene, a carbonyl skeleton such as benzophenone, a phosphine oxide skeleton, a sulfone skeleton, or the like can be used.

As described above, π-electron deficient skeleton and a π-electron rich skeleton can be used instead of at least one of the π-electron deficient heteroaromatic ring and the π-electron rich heteroaromatic ring.

### <<Structure Example 2 of Layer 111X>>

A material having a carrier-transport property can be used as the host material. For example, a material having a hole-transport property, a material having an electron-transport property, a substance exhibiting thermally activated delayed fluorescence (TADF), a material having an anthracene skeleton, or a mixed material can be used as the host material. A material having a wider band gap than the light-emitting material contained in the layer 111X is preferably used as the host material. In that case, energy transfer from excitons generated in the layer 111X to the host material can be inhibited.

### [Material Having Hole-Transport Property]

A material having a hole mobility higher than or equal to 1×10⁻⁶ cm²/Vs can be suitably used as the material having a hole-transport property. For example, the material having a hole-transport property that can be used for the layer 112X can be used for the layer 111X.

### [Material Having Electron-Transport Property]

A metal complex or an organic compound having a π-electron deficient heteroaromatic ring skeleton can be used as the material having an electron-transport property. For example, the material having an electron-transport property that can be used for the layer 113X can be used for the layer 111X.

### [Material Having Anthracene Skeleton]

An organic compound having an anthracene skeleton can be used as the host material. In particular, when a fluorescent substance is used as the light-emitting substance, an organic compound having an anthracene skeleton is suitable. In that case, a light-emitting device with high emission efficiency and high durability can be obtained.

As the organic compound having an anthracene skeleton, an organic compound having a diphenylanthracene skeleton, in particular, a 9,10-diphenylanthracene skeleton is chemically stable and thus is preferable. The host material preferably has a carbazole skeleton, in which case the hole-injection and hole-transport properties are improved. In particular, the host material preferably has a dibenzocarbazole skeleton, in which case the HOMO level thereof is shallower than that of carbazole by approximately 0.1 eV, so that holes enter the host material easily, the hole-transport property is improved, and the heat resistance is increased. Note that in terms of the hole-injection and hole-transport properties, a benzofluorene skeleton or a dibenzofluorene skeleton may be used instead of a carbazole skeleton.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferable as the host material.

For example, it is possible to use 6-[3-(9,10-diphenyl-2-anthryl)phenyl]-benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-βNP Anth), 9-phenyl-3-[4-(10-phenyl-9-anthryl)phenyl]-9H-carbazole (abbreviation: PCzPA), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), or 3-[4-(1-naphthyl)-phenyl]-9-phenyl-9H-carbazole (abbreviation: PCPN).

In particular, CzPA, cgDBCzPA, 2mBnfPPA, and PCzPA have excellent characteristics.

### [Substance Exhibiting Thermally Activated Delayed Fluorescence (TADF)]

A TADF material can be used as the host material. When the TADF material is used as the host material, triplet excitation energy generated in the TADF material can be converted into singlet excitation energy by reverse intersystem crossing. Moreover, excitation energy can be transferred to the light-emitting substance. In other words, the TADF material functions as an energy donor, and the light-emitting substance functions as an energy acceptor. Thus, the emission efficiency of the light-emitting device can be increased.

This is very effective in the case where the light-emitting substance is a fluorescent substance. In that case, the S1 level of the TADF material is preferably higher than that of the fluorescent substance in order that high emission efficiency can be achieved. Furthermore, the T1 level of the TADF material is preferably higher than the S1 level of the fluorescent substance. Therefore, the T1 level of the TADF material is preferably higher than that of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no π bond are poor in carrier-transport performance, whereby the TADF material and the luminophore of the fluorescent substance can be made away from each other with little influence on carrier transport or carrier recombination.

Here, the luminophore refers to an atomic group (skeleton) that causes light emission in a fluorescent substance. The luminophore is preferably a skeleton having a π bond, further preferably includes an aromatic ring, still further preferably includes a condensed aromatic ring or a condensed heteroaromatic ring.

Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

For example, the TADF material that can be used as the light-emitting material can be used as the host material.

### Structure Example 1 of Mixed Material

A material in which a plurality of kinds of substances are mixed can be used as the host material. For example, a material having an electron-transport property and a material having a hole-transport property can be used as the mixed material. The weight ratio between the material having a hole-transport property and the material having an electron-transport property contained in the mixed material may be (the material having a hole-transport property/the material having an electron-transport property)=(1/19) or more and (19/1) or less. Accordingly, the carrier-transport property of the layer 111X can be easily adjusted. In addition, a recombination region can be controlled easily.

### Structure Example 2 of Mixed Material

A material mixed with a phosphorescent substance can be used as the host material. When a fluorescent substance is used as the light-emitting substance, a phosphorescent substance can be used as an energy donor for supplying excitation energy to the fluorescent substance.

### Structure Example 3 of Mixed Material

A mixed material containing a material to form an exciplex can be used as the host material. For example, a material forming an exciplex whose emission spectrum overlaps with the wavelength of the absorption band on the lowest energy side of the light-emitting substance can be used as the host material. This enables smooth energy transfer and improves emission efficiency. Alternatively, the driving voltage can be reduced. With such a structure, light emission can be efficiently obtained by ExTET (Exciplex-Triplet Energy Transfer), which is energy transfer from the exciplex to the light-emitting substance (phosphorescent material).

A phosphorescent substance can be used as at least one of the materials forming an exciplex. Accordingly, reverse intersystem crossing can be used. Alternatively, triplet excitation energy can be efficiently converted into singlet excitation energy.

A combination of materials forming an exciplex is preferably such that the HOMO level of a material having a hole-transport property is higher than or equal to the HOMO level of a material having an electron-transport property. Alternatively, the LUMO level of the material having a hole-transport property is preferably higher than or equal to the LUMO level of the material having an electron-transport property. In that case, an exciplex can be efficiently formed. Note that the LUMO levels and the HOMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of a mixed film in which the material having a hole-transport property and the material having an electron-transport property are mixed is shifted to a longer wavelength than the emission spectrum of each of the materials (or has another peak on the longer wavelength side) observed in comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed in comparison of the transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed in comparison of the transient EL of the material having a hole-transport property, the transient EL of the material having an electron-transport property, and the transient EL of the mixed film of these materials.

Note that this embodiment can be combined with any of the other embodiments described in this specification as appropriate.

### Embodiment 3

In this embodiment, a structure of a light-emitting device that can be used for the display apparatus of one embodiment of the present invention will be described with reference to FIG. 4A.

Structures of the light-emitting device 550X described in this embodiment can be employed for the display apparatus of one embodiment of the present invention. Note that the description of the structure of the light-emitting device 550X can be applied to the light-emitting device 550X(i,j). Specifically, the reference numerals used in the description of the light-emitting device 550X can be used for the description of the light-emitting device 550X(i,j) by replacing “X” with “X(i,j)”. Similarly, the structure of the light-emitting device 550X can be employed for the light-emitting device 550Y(i,j) by replacing “X” with “Y(i,j).

### <Structure Example of Light-Emitting Device 550X>

The light-emitting device 550X described in this embodiment includes the layer HNX, the electrode 552X, and the unit 103X, and the electrode 552X overlaps with the layer HNX (see FIG. 4A). The unit 103X is interposed between the electrode 552X and the layer HNX. For example, the structure described in Embodiment 2 can be employed for the unit 103X.

### <Structure Example 1 of Layer HNX>

A material that has a light-transmitting property and contains an element with an atomic number of 21 to 83 at 5 atomic % or higher can be used for the layer HNX, for example. Specifically, a metal oxide containing indium, tin, zinc, gallium, or titanium can be used for the layer HNX.

### <Structure Example 2 of Layer HNX>

The layer HNX includes the electrode 551X and the layer 104X, and the layer 104X is interposed between the electrode 551X and the unit 103X.

### <Structure Example of Electrode 551X>

For example, a conductive material can be used for the electrode 551X. Specifically, a film having a property of transmitting visible light can be used for the electrode 551X. For example, a single layer or a stacked layer of a metal film, an alloy film, a conductive oxide film, or the like that is thin enough to transmit light can be used for the electrode 551X.

In particular, a material having a work function higher than or equal to 4.0 eV can be suitably used for the electrode 551X.

For example, a conductive oxide containing indium can be used. Specifically, indium oxide, indium oxide-tin oxide (abbreviation: ITO), indium oxide-tin oxide containing silicon or silicon oxide (abbreviation: ITSO), indium oxide-zinc oxide, indium oxide containing tungsten oxide and zinc oxide (abbreviation: IWZO), or the like can be used.

Furthermore, for example, a conductive oxide containing zinc can be used. Specifically, zinc oxide, zinc oxide to which gallium is added, zinc oxide to which aluminum is added, or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), a nitride of a metal material (e.g., titanium nitride), or the like can be used. Alternatively, graphene can be used.

### <<Structure Example 1 of Layer 104X>>

For example, a material having a hole-injection property can be used for the layer 104X. The layer 104X can be referred to as a hole-injection layer.

For example, a material having a hole mobility lower than or equal to 1×10⁻³ cm²/Vs when the square root of the electric field strength [V/cm] is 600 can be used for the layer 104X. A film having an electrical resistivity greater than or equal to 1×10⁴ [Ω·cm] and less than or equal to 1×10⁷ [Ω·cm] can be used as the layer 104X. The electrical resistivity of the layer 104X is preferably greater than or equal to 5×10⁴ [Ω·cm] and less than or equal to 1×10⁷ [Ω·cm], further preferably greater than or equal to 1×10⁵ [Ω·cm] and less than or equal to 1×10⁷ [Ω·cm].

### <<Structure Example 2 of Layer 104X>>

Specifically, a substance having an electron-accepting property can be used for the layer 104X. A composite material containing a plurality of kinds of substances can be used for the layer 104X. This can facilitate injection of holes from the electrode 551X, for example. Alternatively, the driving voltage of the light-emitting device 550X can be lowered.

### [Substance Having Electron-Accepting Property]

An organic compound and an inorganic compound can be used as the substance having an electron-accepting property. The substance having an electron-accepting property can extract electrons from an adjacent hole-transport layer or an adjacent material having a hole-transport property by the application of an electric field.

For example, a compound having an electron-withdrawing group (a halogen group or a cyano group) can be used as the substance having an electron-accepting property. Note that an organic compound having an electron-accepting property is easily evaporated and deposited. As a result, the productivity of the light-emitting device 550X can be increased.

Specifically, it is possible to use, for example, 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene) malononitrile.

A compound in which electron-withdrawing groups are bonded to a condensed aromatic ring having a plurality of heteroatoms, such as HAT-CN, is particularly preferable because it is thermally stable.

Alternatively, a [3]radialene derivative having an electron-withdrawing group (in particular, a cyano group or a halogen group such as a fluoro group) is preferable because it has a very high electron-accepting property.

Specifically, it is possible to use, for example, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], or α,α′,α″-1,2,3-cyclopropanetriylidenetris[2,3,4,5,6-pentafluorobenzeneacetonitrile].

As the substance having an electron-accepting property, a transition metal oxide such as molybdenum oxide, vanadium oxide, ruthenium oxide, tungsten oxide, or manganese oxide can be used.

It is possible to use any of the following materials: phthalocyanine-based compounds such as phthalocyanine (abbreviation: H₂Pc); phthalocyanine-based complex compounds such as copper phthalocyanine (CuPc); and compounds each having an aromatic amine skeleton such as 4,4′-bis[N-(4-diphenylaminophenyl)-N-phenylamino]biphenyl (abbreviation: DPAB) and N,N′-bis[4-bis(3-methylphenyl)aminophenyl]-N,N′-diphenyl-4,4′-diaminobiphenyl (abbreviation: DNTPD).

Furthermore, a high molecular compound such as poly(3,4-ethylenedioxythiophene)/poly(styrenesulfonic acid)(PEDOT/PSS) can be used.

### Structure Example of Composite Material

For example, a composite material containing a substance having an electron-accepting property and a material having a hole-transport property can be used for the layer 104X. Thus, not only a material having a high work function, but also a material having a low work function can be used for the electrode 551X. Alternatively, a material used for the electrode 551X can be selected from a wide range of materials regardless of its work function.

As the material having a hole-transport property in the composite material, for example, a compound having an aromatic amine skeleton, a carbazole derivative, an aromatic hydrocarbon, an aromatic hydrocarbon having a vinyl group, a high molecular compound (such as an oligomer, a dendrimer, or a polymer), or the like can be used. A material having a hole mobility higher than or equal to 1×10⁻⁶ cm²/Vs can be suitably used as the material having a hole-transport property in the composite material. For example, a material having a hole-transport property that can be used for the layer 112X can be used as the composite material.

A substance having a relatively deep HOMO level can be suitably used as the material having a hole-transport property in the composite material. Specifically, the HOMO level is preferably higher than or equal to −5.7 eV and lower than or equal to −5.4 eV. In that case, hole injection to the unit 103X can be facilitated. Alternatively, hole injection to the layer 112X can be facilitated. Alternatively, the reliability of the light-emitting device 550X can be increased.

As the compound having an aromatic amine skeleton, it is possible to use, for example, N,N-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis[4-bis(3-methylphenyl)aminophenyl]-N,N′-diphenyl-4,4′-diaminobiphenyl (abbreviation: DNTPD), or 1,3,5-tris[N-(4-diphenylaminophenyl)-N-phenylamino]benzene (abbreviation: DPA3B).

As the carbazole derivative, it is possible to use, for example, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), or 1,4-bis[4-(N-carbazolyl)phenyl]-2,3,5,6-tetraphenylbenzene.

As the aromatic hydrocarbon, it is possible to use, for example, 2-tert-butyl-9,10-di(2-naphthyl) anthracene (abbreviation: t-BuDNA), 2-tert-butyl-9,10-di(1-naphthyl) anthracene, 9,10-bis(3,5-diphenylphenyl) anthracene (abbreviation: DPPA), 2-tert-butyl-9,10-bis(4-phenylphenyl) anthracene (abbreviation: t-BuDBA), 9,10-di(2-naphthyl) anthracene (abbreviation: DNA), 9,10-diphenylanthracene (abbreviation: DPAnth), 2-tert-butylanthracene (abbreviation: t-BuAnth), 9,10-bis(4-methyl-1-naphthyl) anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl) anthracene, 2,3,6,7-tetramethyl-9,10-di(2-naphthyl) anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl) perylene, pentacene, or coronene.

As the aromatic hydrocarbon having a vinyl group, it is possible to use, for example, 4,4′-bis(2,2-diphenylvinyl)biphenyl (abbreviation: DPVBi) or 9,10-bis[4-(2,2-diphenylvinyl)phenyl]anthracene (abbreviation: DPVPA).

As the high molecular compound, it is possible to use, for example, poly(N-vinylcarbazole)(abbreviation: PVK), poly(4-vinyltriphenylamine)(abbreviation: PVTPA), poly[N-(4-{N′-[4-(4-diphenylamino)phenyl]phenyl-N′-phenylamino}phenyl) methacrylamide] (abbreviation: PTPDMA), or poly[N,N′-bis(4-butylphenyl)-N,N′-bis(phenyl)benzidine] (abbreviation: Poly-TPD).

As another example, a substance having any of a carbazole skeleton, a dibenzofuran skeleton, a dibenzothiophene skeleton, and an anthracene skeleton can be suitably used as the material having a hole-transport property in the composite material. Moreover, as the material having a hole-transport property in the composite material, it is possible to use a substance including any of an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group. With the use of a substance having an N,N-bis(4-biphenyl)amino group, the reliability of the light-emitting device 550X can be increased.

As these materials, it is possible to use, for example, N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBABNB), 4-[4-(2-naphthyl)phenyl]-4′,4″-diphenyltriphenylamine (abbreviation: BBAβNBi), 4,4′-diphenyl-4″-(6; 1′-binaphthyl-2-yl)triphenylamine (abbreviation: BBAαNβNB), 4,4′-diphenyl-4″-(7; l′-binaphthyl-2-yltriphenylamine BBAαNβNB-03), 4,4′-diphenyl-4″-(7-phenyl) naphthyl-2-yl)triphenylamine (abbreviation: BBAPβNB-03), 4,4′-diphenyl-4″-(6; 2′-binaphthyl-2-yl)triphenylamine (abbreviation: BBA(βN2)B), 4,4′-diphenyl-4″-(7; 2′-binaphthyl-2-yl)triphenylamine (abbreviation: BBA(βN2)B-03), 4,4′-diphenyl-4″-(4; 2′-binaphthyl-1-yl)triphenylamine (abbreviation: BBAβNαNB), 4,4′-diphenyl-4″-(5; 2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, or N,N-bis(9,9-dimethyl-9H-fluoren-2-yl)-9,9′-spirobi-9H-fluoren-1-amine.

Note that this embodiment can be combined with any of the other embodiments described in this specification as appropriate.

### Embodiment 4

In this embodiment, a structure of the light-emitting device 550X of one embodiment of the present invention will be described with reference to FIG. 4A and FIG. 4B.

Structures of the light-emitting device 550X described in this embodiment can be employed for the display apparatus of one embodiment of the present invention. Note that the description of the structure of the light-emitting device 550X can be applied to the light-emitting device 550X(i,j). Specifically, the reference numerals used in the description of the light-emitting device 550X can be used for the description of the light-emitting device 550X(i,j) by replacing “X” with “X(i,j)”. Similarly, the structure of the light-emitting device 550X can be employed for the light-emitting device 550Y(i,j) by replacing “X” with “Y(i,j).

### <Structure Example of Light-Emitting Device 550X>

The light-emitting device 550X described in this embodiment includes the layer HNX, the electrode 552X, the unit 103X, and the layer 105X. The electrode 552X includes a region overlapping with the layer HNX, and the unit 103X includes a region interposed between the layer HNX and the electrode 552X. The layer 105X includes a region interposed between the unit 103X and the electrode 552X. For example, the structure described in Embodiment 2 can be employed for the unit 103X.

### <Structure Example of Electrode 552X>

A conductive material can be used for the electrode 552X, for example. Specifically, a single layer or a stacked layer of a metal, an alloy, or a material containing a conductive compound can be used for the electrode 552X.

For example, the material that can be used for the electrode 551X described in Embodiment 3 can be used for the electrode 552X. In particular, a material having a lower work function than the electrode 551X can be favorably used for the electrode 552X. Specifically, a material having a work function lower than or equal to 3.8 eV is preferable.

For example, an element belonging to Group 1 of the periodic table, an element belonging to Group 2 of the periodic table, a rare earth metal, or an alloy containing any of these elements can be used for the electrode 552X.

Specifically, lithium (Li), cesium (Cs), or the like; magnesium (Mg), calcium (Ca), strontium (Sr), or the like; europium (Eu), ytterbium (Yb), or the like; or an alloy containing any of these such as an alloy of magnesium and silver or an alloy of aluminum and lithium can be used for the electrode 552X.

### <<Structure Example of the Layer 105X>>

A material having an electron-injection property can be used for the layer 105X, for example. The layer 105X can be referred to as an electron-injection layer.

Specifically, a substance having an electron-donating property can be used for the layer 105X. Alternatively, a material in which a substance having an electron-donating property and a material having an electron-transport property are combined can be used for the layer 105X. Alternatively, electrode can be used for the layer 105X. This can facilitate injection of electrons from the electrode 552X, for example. Alternatively, besides a material having a low work function, a material having a high work function can also be used for the electrode 552X. Alternatively, a material used for the electrode 552X can be selected from a wide range of materials regardless of its work function. Specifically, Al, Ag, ITO, indium oxide-tin oxide containing silicon or silicon oxide, or the like can be used for the electrode 552X. Alternatively, the driving voltage of the light-emitting device 550X can be lowered.

### [Substance Having Electron-Donating Property]

For example, an alkali metal, an alkaline earth metal, a rare earth metal, or a compound thereof (an oxide, a halide, a carbonate, or the like) can be used as the substance having an electron-donating property. Alternatively, an organic compound such as tetrathianaphthacene (abbreviation: TTN), nickelocene, or decamethylnickelocene can be used as the substance having an electron-donating property.

As an alkali metal compound (including an oxide, a halide, and a carbonate), lithium oxide, lithium fluoride (LiF), cesium fluoride (CsF), lithium carbonate, cesium carbonate, 8-hydroxyquinolinato-lithium (abbreviation: Liq), or the like can be used.

As an alkaline earth metal compound (including an oxide, a halide, and a carbonate), calcium fluoride (CaF₂) or the like can be used.

### [Structure Example 1 of Composite Material]

A material in which a plurality of kinds of substances are combined can be used as the material having an electron-injection property. For example, a substance having an electron-donating property and a material having an electron-transport property can be used as the composite material.

### [Material Having Electron-Transport Property]

A material having an electron mobility higher than or equal to 1×10⁻¹ cm²/Vs and lower than or equal to 5×10⁻⁵ cm²/Vs in a condition where the square root of the electric field strength [V/cm] is 600 can be suitably used as the material having an electron-transport property. Accordingly, the amount of electrons injected into the light-emitting layer can be controlled. Alternatively, the light-emitting layer can be prevented from having excess electrons.

A metal complex or an organic compound having a π-electron deficient heteroaromatic ring skeleton can be used as the material having an electron-transport property. For example, the material having an electron-transport property that can be used for the layer 113X can be used for the layer 111X.

### [Structure Example 2 of Composite Material]

A material including a fluoride of an alkali metal in a microcrystalline state and a material having an electron-transport property can be used as the composite material. Alternatively, a material including a fluoride of an alkaline earth metal in a microcrystalline state and a material having an electron-transport property can be used as the composite material. In particular, a composite material including a fluoride of an alkali metal or a fluoride of an alkaline earth metal at higher than or equal to 50 wt % can be suitably used. Alternatively, a composite material including an organic compound having a bipyridine skeleton can be suitably used. In that case, the refractive index of the layer 105X can be reduced. Alternatively, the external quantum efficiency of the light-emitting device 550X can be improved.

### [Structure Example 3 of Composite Material]

For example, a composite material containing a first organic compound having an unshared electron pair and a first metal can be used for the layer 105X. The sum of the number of electrons of the first organic compound and the number of electrons of the first metal is preferably an odd number. The molar ratio of the first metal to 1 mol of the first organic compound is preferably greater than or equal to 0.1 and less than or equal to 10, further preferably greater than or equal to 0.2 and less than or equal to 2, still further preferably greater than or equal to 0.2 and less than or equal to 0.8.

Accordingly, the first organic compound having an unshared electron pair interacts with the first metal and thus can form a singly occupied molecular orbital (SOMO). Furthermore, in the case where electrons are injected from the electrode 552X into the layer 105X, a barrier therebetween can be lowered.

For the layer 105X, a composite material that allows the spin density measured by an electron spin resonance method (ESR) to be preferably higher than or equal to 1×10¹⁶ spins/cm³, further preferably higher than or equal to 5×10¹⁶ spins/cm³, still further preferably higher than or equal to 1×10¹⁷ spins/cm³ can be used.

### [Organic Compound Having Unshared Electron Pair]

For example, a material having an electron-transport property can be used as the organic compound having an unshared electron pair. For example, a compound having an electron deficient heteroaromatic ring can be used. Specifically, a compound having at least one of a pyridine ring, a diazine ring (a pyrimidine ring, a pyrazine ring, and a pyridazine ring), and a triazine ring can be used. Accordingly, the driving voltage of the light-emitting device 550X can be lowered.

Note that the lowest unoccupied molecular orbital (LUMO) level of the organic compound having an unshared electron pair is preferably higher than or equal to −3.6 eV and lower than or equal to −2.3 eV. In general, the HOMO level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a: 2′,3′-c]phenazine (abbreviation: HATNA), 2,4,6-tris[3′-(pyridin-3-yl)biphenyl-3-yl]-1,3,5-triazine (abbreviation: TmPPPyTz), 2,2′-(1,3-phenylene)bis(9-phenyl-1,10-phenanthroline)(abbreviation: mPPhen2P), or the like can be used as the organic compound having an unshared electron pair. Note that NBPhen has a higher glass transition temperature (Tg) than BPhen and thus has high heat resistance.

Alternatively, for example, copper phthalocyanine can be used as the organic compound having an unshared electron pair. The number of electrons of the copper phthalocyanine is an odd number.

### [First Metal]

For example, when the number of electrons of the first organic compound having an unshared electron pair is an even number, a composite material of the first metal that belongs to an odd-numbered group in the periodic table and the first organic compound can be used for the layer 105X.

For example, manganese (Mn), which is a metal belonging to Group 7, cobalt (Co), which is a metal belonging to Group 9, copper (Cu), silver (Ag), and gold (Au), which are metals belonging to Group 11, and aluminum (Al) and indium (In), which are metals belonging to Group 13, are odd-numbered groups in the periodic table. Note that elements belonging to Group 11 have a lower melting point than elements belonging to Group 7 or Group 9 and thus are suitable for vacuum evaporation. In particular, Ag is preferable because of its low melting point. By using a metal having a low reactivity with water or oxygen as the first metal, the moisture resistance of the light-emitting device 550X can be improved.

The use of Ag for the electrode 552X and the layer 105X can increase the adhesion between the layer 105X and the electrode 552X.

When the number of electrons of the first organic compound having an unshared electron pair is an odd number, a composite material of the first metal that belongs to an even-numbered group in the periodic table and the first organic compound can be used for the layer 105X. For example, iron (Fe), which is a metal belonging to Group 8, is an element belonging to an even-numbered group in the periodic table.

### [Electride]

For example, a substance obtained by adding electrons at high concentration to an oxide where calcium and aluminum are mixed, or the like can be used as the material having an electron-injection property.

Note that this embodiment can be combined with any of the other embodiments described in this specification as appropriate.

### Embodiment 5

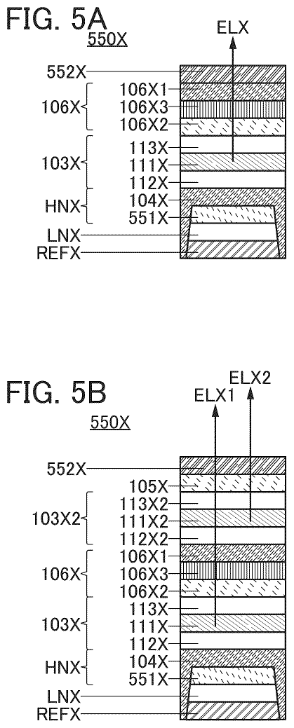

In this embodiment, a structure of a light-emitting device that can be used for the display apparatus of one embodiment of the present invention will be described with reference to FIG. 5A.

FIG. 5A is a cross-sectional view illustrating a structure of a light-emitting device that can be used in the display apparatus of one embodiment of the present invention.

Structures of the light-emitting device 550X described in this embodiment can be employed for the display apparatus of one embodiment of the present invention. Note that the description of the structure of the light-emitting device 550X can be applied to the light-emitting device 550X(i,j). Specifically, the reference numerals used in the description of the light-emitting device 550X can be used for the description of the light-emitting device 550X(i,j) by replacing “X” with “X(i,j)”. Similarly, the structure of the light-emitting device 550X can be employed for the light-emitting device 550Y(i,j) by replacing “X” with “Y(i,j).

### <Structure Example of Light-Emitting Device 550X>

The light-emitting device 550X described in this embodiment includes the layer HNX, the electrode 552X, the unit 103X, and the intermediate layer 106X (see FIG. 5A). The electrode 552X includes a region overlapping with the layer HNX, and the unit 103X includes a region interposed between the layer HNX and the electrode 552X. The intermediate layer 106X includes a region interposed between the electrode 552X and the unit 103X.

### <<Structure Example 1 of Intermediate Layer 106X>>

The intermediate layer 106X has a function of supplying electrons to the anode side and supplying holes to the cathode side by applying voltages. The intermediate layer 106X can be referred to as a charge-generation layer.

For example, a material having a hole-injection property that can be used for the layer 104X described in Embodiment 3 can be used for the intermediate layer 106X. Specifically, a composite material can be used for the intermediate layer 106X.

As another example, a stacked film in which a film containing the composite material and a film containing a material having a hole-transport property are stacked can be used as the intermediate layer 106X. Note that the film containing a material having a hole-transport property is interposed between the film containing the composite material and the cathode.

### <<Structure Example 2 of Intermediate Layer 106X>>

A stacked film in which a layer 106X1 and a layer 106X2 are stacked can be used as the intermediate layer 106X. The layer 106X1 includes a region interposed between the unit 103X and the electrode 552X, and the layer 106X2 includes a region interposed between the unit 103X and the layer 106X1.

### <<Structure Example of Layer 106X1>>

For example, a material having a hole-injection property that can be used for the layer 104X described in Embodiment 3 can be used for the layer 106X1. Specifically, a composite material can be used for the layer 106X1. A film having an electrical resistivity greater than or equal to 1×10⁴ [Ω·cm] and less than or equal to 1×10⁷ [Ω·cm] can be used as the layer 106X1. The layer 106X1 preferably has an electrical resistivity greater than or equal to 5×10⁴ [Ω·cm] and less than or equal to 1×10⁷ [Ω·cm], further preferably greater than or equal to 1×10⁵ [Ω·cm] and less than or equal to 1×10⁷ [Ω·cm].

### <<Structure Example of Layer 106X2>>

For example, a material that can be used for the layer 105X described in Embodiment 4 can be used for the layer 106X2.

### <<Structure Example 3 of Layer 106X>>

A stacked film in which the layer 106X1, the layer 106X2, and a layer 106X3 are stacked can be used as the intermediate layer 106X. The layer 106X3 includes a region interposed between the layer 106X1 and the layer 106X2.

### <<Structure Example of Layer 106X3>>

For example, a material having an electron-transport property can be used for the layer 106X3. The layer 106X3 can be referred to as an electron-relay layer. With the use of the layer 106X3, a layer that is in contact with the anode side of the layer 106X3 can be distanced from a layer that is in contact with the cathode side of the layer 106X3. It is possible to reduce interaction between the layer in contact with the anode side of the layer 106X3 and the layer in contact with the cathode side of the layer 106X3. Electrons can be smoothly supplied to the layer in contact with the anode side of the layer 106X3.

A substance whose LUMO level is positioned between the LUMO level of a substance having an electron acceptor property contained in the layer 106X1 and the LUMO level of a substance contained in the layer 106X2 can be suitably used for the layer 106X3.

For example, a material that has a LUMO level higher than or equal to −5.0 eV, preferably higher than or equal to −5.0 eV and lower than or equal to −3.0 eV can be used for the layer 106X3.

Specifically, a phthalocyanine-based material can be used for the layer 106X3. For example, copper phthalocyanine (abbreviation: CuPc) or a metal complex having a metal-oxygen bond and an aromatic ligand can be used for the layer 106X3.

Note that this embodiment can be combined with any of the other embodiments described in this specification as appropriate.

### Embodiment 6

In this embodiment, a structure of the light-emitting device 550X that can be used in the display apparatus of one embodiment of the present invention will be described with reference to FIG. 5B.

FIG. 5B is a cross-sectional view illustrating a structure of a light-emitting device, which is different from the structure illustrated in FIG. 5A.

### <Structure Example of Light-Emitting Device 550X>

The light-emitting device 550X described in this embodiment includes the layer HNX, the electrode 552X, the unit 103X, the intermediate layer 106X, and a unit 103X2 (see FIG. 5B).

The unit 103X is interposed between the electrode 552X and the layer HNX, and the intermediate layer 106X is interposed between the electrode 552X and the unit 103X.

The unit 103X2 is interposed between the electrode 552X and the intermediate layer 106X. The unit 103X2 has a function of emitting light ELX2.

In other words, the light-emitting device 550X includes the stacked units between the electrode 551X and the electrode 552X. Note that the number of stacked units is not limited to two, and three or more units can be stacked. A structure including the stacked units interposed between the electrode 551X and the electrode 552X and the intermediate layer 106X interposed between the units is referred to as a stacked light-emitting device or a tandem light-emitting device in some cases.

This structure can provide light emission at high luminance while the current density is kept low. Alternatively, reliability can be improved. Alternatively, the driving voltage can be lowered as compared with other structures with the same luminance. Furthermore, power consumption can be reduced.

### <<Structure Example 1 of Unit 103X2>>

The unit 103X2 includes a layer 111X2, a layer 112X2, and a layer 113X2. The layer 111X2 is interposed between the layer 112X2 and the layer 113X2.

The structure that can be employed for the unit 103X can be employed for the unit 103X2. For example, the same structure as the unit 103X can be employed for the unit 103X2.

### <<Structure Example 2 of Unit 103X2>>

The structure different from that of the unit 103X can be employed for the unit 103X2. For example, the unit 103X2 can have a structure emitting light whose hue is different from that of light emitted from the unit 103X.

Specifically, a stack including the unit 103X emitting red light and green light and the unit 103X2 emitting blue light can be employed. Accordingly, a light-emitting device that emits light of a desired color can be provided. For example, a light-emitting device that emits white light can be provided.

### <<Structure Example of Intermediate Layer 106X>>

The intermediate layer 106X has a function of supplying electrons to one of the unit 103X and the unit 103X2 and supplying holes to the other. For example, the intermediate layer 106X described in Embodiment 5 can be used.

### <Method for Manufacturing Light-Emitting Device 550X>

For example, each layer of the layer HNX, the electrode 552X, the unit 103X, the intermediate layer 106X, and the unit 103X2 can be formed by a dry process, a wet process, an evaporation method, a droplet discharge method, a coating method, a printing method, or the like. Different methods can be used to form the components.

Specifically, the light-emitting device 550X can be manufactured with a vacuum evaporation apparatus, an inkjet apparatus, a coating apparatus such as a spin coater, a gravure printing apparatus, an offset printing apparatus, a screen printing apparatus, or the like.

For example, the electrode can be formed by a wet process or a sol-gel method using a paste of a metal material. An indium oxide-zinc oxide film can be formed by a sputtering method using a target obtained by adding, to indium oxide, zinc oxide at higher than or equal to 1 wt % and lower than or equal to 20 wt %. An indium oxide film containing tungsten oxide and zinc oxide (IWZO) can be formed by a sputtering method using a target containing, with respect to indium oxide, tungsten oxide at higher than or equal to 0.5 wt % and lower than or equal to 5 wt % and zinc oxide at higher than or equal to 0.1 wt % and lower than or equal to 1 wt %.

Note that this embodiment can be combined with any of the other embodiments described in this specification as appropriate.

### Embodiment 7

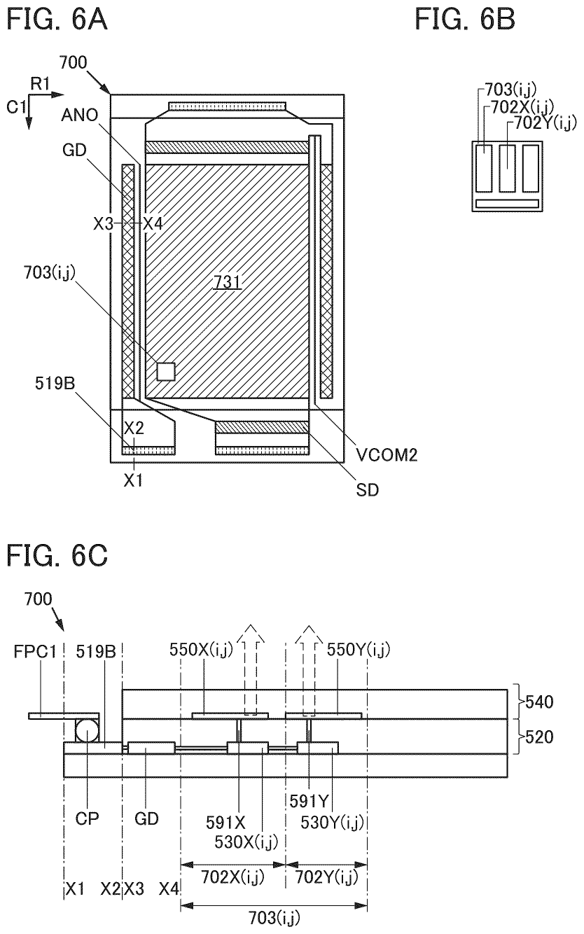

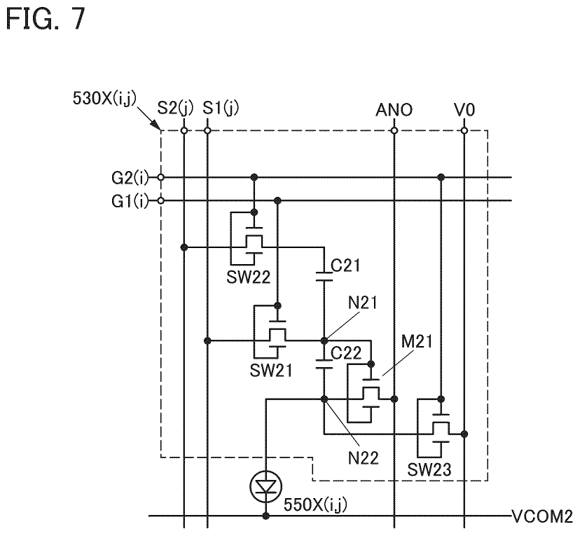

In this embodiment, a structure of the display apparatus of one embodiment of the present invention will be described with reference to FIG. 6 and FIG. 7.

FIG. 6A is a top view of the display apparatus of one embodiment of the present invention, and FIG. 6B is a top view illustrating part of FIG. 6A. FIG. 6C is a cross-sectional view taken along the cutting line X1-X2 and the cutting line X3-X4 in FIG. 6A and a cross-sectional view of the pixel set 703(i,j).

FIG. 7 is a circuit diagram illustrating a structure of an apparatus of one embodiment of the present invention.

Note that in this specification, an integer variable of 1 or more is sometimes used in reference numerals. For example, (p) where p is an integer variable of 1 or more is sometimes used in part of a reference numeral that specifies any of p components at a maximum. As another example, (m, n) where m and n are each an integer variable of 1 or more is sometimes used in part of a reference numeral that specifies any of m×n components at a maximum.

### <Structure Example 1 of Display Apparatus 700>

The display apparatus 700 of one embodiment of the present invention includes a region 231 (see FIG. 6A). The region 231 includes the pixel set 703 (i,j).

<<Structure Example of Pixel Set 703(i,j)>>

The pixel set 703 (i,j) includes a pixel 702X(i,j) and a pixel 702Y(i,j)(see FIG. 6B and FIG. 6C).

The pixel 702X(i,j) includes a pixel circuit 530X(i,j) and the light-emitting device 550X(i,j). The light-emitting device 550X(i,j) is electrically connected to the pixel circuit 530X(i,j).

For example, the light-emitting device described in any of Embodiment 1 to Embodiment 6 can be used as the light-emitting device 550X(i,j) and the pixel 702Y(i,j).

### <Structure Example 2 of Display Apparatus 700>

The display apparatus 700 of one embodiment of the present invention includes a functional layer 540 and the functional layer 520 (see FIG. 6C). The functional layer 540 overlaps with the functional layer 520.

The functional layer 540 includes the light-emitting device 550X(i,j).

The functional layer 520 includes the pixel circuit 530X(i,j) and wirings (see FIG. 6C). The pixel circuit 530X(i,j) is electrically connected to the wiring. For example, a conductive film provided in an opening portion 591X or an opening portion 591Y in the functional layer 520 can be used for the wiring. The wiring electrically connects a terminal 519B to the pixel circuit 530X(i,j). Note that a conductive material CP electrically connects the terminal 519B to a flexible printed circuit FPC1.

### <Structure Example 3 of Display Apparatus 700>

The display apparatus 700 of one embodiment of the present invention includes a driver circuit GD and a driver circuit SD (see FIG. 6A).

### <<Structure Example of Driver Circuit GD>>

The driver circuit GD supplies a first selection signal and a second selection signal.

### <<Structure Example of Driver Circuit SD>>

The driver circuit SD supplies a first control signal and a second control signal.

### <<Structure Example of Wiring>>

As wirings, a conductive film G1(i), a conductive film G2(i), a conductive film S1(j), a conductive film S2(j), a conductive film ANO, a conductive film VCOM2, and a conductive film V0 are included (see FIG. 7).

The conductive film G1(i) is supplied with the first selection signal, and the conductive film G2(i) is supplied with the second selection signal.

The conductive film S1(j) is supplied with the first control signal, and the conductive film S2(j) is supplied with the second control signal.

### <<Structure Example 1 of Pixel Circuit 530X(i,j)>>

The pixel circuit 530X(i,j) is electrically connected to the conductive film G1(i) and the conductive film S1(j). The conductive film G1(i) supplies the first selection signal, and the conductive film S1(j) supplies the first control signal.

The pixel circuit 530X(i,j) drives the light-emitting device 550X(i,j) based on the first selection signal and the first control signal. The light-emitting device 550X(i,j) emits light.

One electrode of the light-emitting device 550X(i,j) is electrically connected to the pixel circuit 530X(i,j), and the other electrode of the light-emitting device 550X(i,j) is electrically connected to the conductive film VCOM2.

### <<Structure Example 2 of Pixel Circuit 530X(i,j)>>

The pixel circuit 530X(i,j) includes a switch SW21, a switch SW22, a transistor M21, a capacitor C21, and a node N21.

The transistor M21 includes a gate electrode electrically connected to the node N21, a first electrode electrically connected to the light-emitting device 550X(i,j), and a second electrode electrically connected to the conductive film ANO.

The switch SW21 includes a first terminal electrically connected to the node N21, a second terminal electrically connected to the conductive film S1(j), and a gate electrode having a function of controlling the conduction state or the non-conduction state based on the potential of the conductive film G1(i).

The switch SW22 includes a first terminal electrically connected to the conductive film S2(j) and a gate electrode having a function of controlling the conduction state or the non-conduction state based on the potential of the conductive film G2(i).

The capacitor C21 includes a conductive film electrically connected to the node N21 and a conductive film electrically connected to a second electrode of the switch SW22.

Thus, an image signal can be stored in the node N21. The potential of the node N21 can be changed using the switch SW22. Alternatively, the intensity of light emitted from the light-emitting device 550X(i,j) can be controlled with the potential of the node N21. As a result, a novel apparatus that is highly convenient, useful, or reliable can be provided.

### <<Structure Example 3 of Pixel Circuit 530X(i,j)>>

The pixel circuit 530X(i,j) includes a switch SW23, a node N22, and a capacitor C22.

The switch SW23 includes a first terminal electrically connected to the conductive film V0, a second terminal electrically connected to the node N22, and a gate electrode having a function of controlling the conduction state or the non-conduction state based on the potential of the conductive film G2(i).

The capacitor C22 includes a conductive film electrically connected to the node N21 and a conductive film electrically connected to the node N22.

Note that the first electrode of the transistor M21 is electrically connected to the node N22.

Note that this embodiment can be combined with any of the other embodiments described in this specification as appropriate.

### Embodiment 8

In this embodiment, a display module of one embodiment of the present invention is described.

### <Display Module>

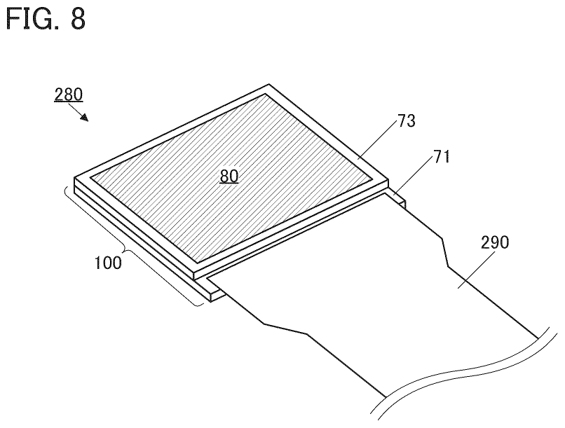

FIG. 8 is a perspective view illustrating a structure of a display module 280.

The display module 280 includes a display apparatus 100, and an FPC 290 or a connector. The FPC 290 is supplied with a data signal, a power supply potential, or the like from the outside and supplies the data signal, the power supply potential, or the like to the display apparatus 100. An IC may be mounted on the FPC 290. Note that a connector is a mechanical component for electrical connection through a conductor, and the conductor can electrically connect the display apparatus 100 to a component to be connected. For example, the FPC 290 can be used as the conductor. The connector can detach the display apparatus 100 from the connected component.

### <<Display Apparatus 100A>>

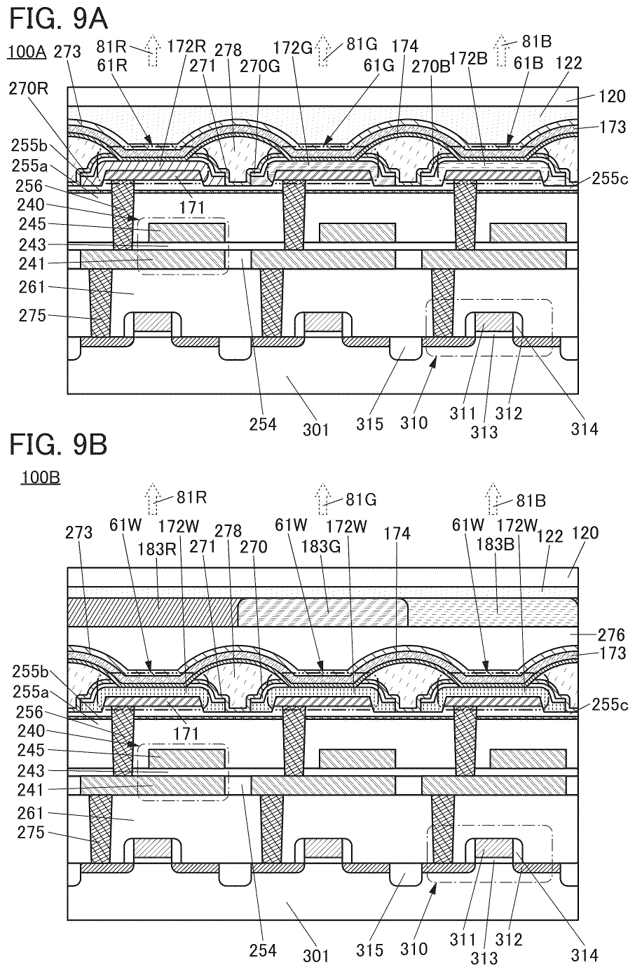

FIG. 9A is a cross-sectional view illustrating a structure of a display apparatus 100A. The display apparatus 100A can be used as the display apparatus 100 of the display module 280, for example. A substrate 301 corresponds to a substrate 71 in FIG. 8.

The display apparatus 100A includes the substrate 301, a transistor 310, an element isolation layer 315, an insulating layer 261, a capacitor 240, an insulating layer 255, a light-emitting device 61R, a light-emitting device 61G, and a light-emitting device 61B. The insulating layer 261 is provided over a substrate 301A, and the transistor 310 is positioned between the substrate 301 and the insulating layer 261. An insulating layer 255a is provided over the insulating layer 261, the capacitor 240 is positioned between the insulating layer 261 and the insulating layer 255a, and the insulating layer 255a is positioned between the light-emitting device 61R and the capacitor 240, between the light-emitting device 61G and the capacitor 240, and the light-emitting device 61B and the capacitor 240.

### [Transistor 310]

The transistor 310 includes a conductive layer 311, a pair of low-resistance regions 312, an insulating layer 313, and an insulating layer 314, and its channel is formed in part of the substrate 301. The conductive layer 311 functions as a gate electrode. The insulating layer 313 is positioned between the substrate 301 and the conductive layer 311 and functions as a gate insulating layer. The substrate 301 includes the pair of low-resistance regions 312 doped with an impurity. Note that the low-resistance regions function as a source and a drain. The side surface of the conductive layer 311 is covered with the insulating layer 314.

The element isolation layer 315 is embedded in the substrate 301, and positioned between two adjacent transistors 310.

### [Capacitor 240]

The capacitor 240 includes a conductive layer 241, a conductive layer 245, and an insulating layer 243, and the insulating layer 243 is positioned between the conductive layer 241 and the conductive layer 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is positioned over the insulating layer 261 and is embedded in an insulating layer 254. The conductive layer 241 is electrically connected to one of the source and the drain of the transistor 310 through a plug 275 embedded in the insulating layer 261. The insulating layer 243 covers the conductive layer 241. The conductive layer 245 overlaps with the conductive layer 241 with the insulating layer 243 therebetween.

### [Insulating Layer 255]

The insulating layer 255 includes the insulating layer 255a, an insulating layer 255b, and an insulating layer 255c, and the insulating layer 255b is positioned between the insulating layer 255a and the insulating layer 255c.

### [Light-Emitting Device 61R, Light-Emitting Device 61G, and Light-Emitting Device 61B]

The light-emitting device 61R, the light-emitting device 61G, and the light-emitting device 61B are provided over the insulating layer 255c. For example, the light-emitting device described in any of Embodiment 1 to Embodiment 6 can be used as any of the light-emitting device 61R, the light-emitting device 61G, and the light-emitting device 61B.

The light-emitting device 61R includes a conductive layer 171 and an EL layer 172R, and the EL layer 172R covers the top surface and the side surface of the conductive layer 171. A sacrificial layer 270R is positioned over the EL layer 172R. The light-emitting device 61G includes the conductive layer 171 and an EL layer 172G, and the EL layer 172G covers the top surface and the side surface of the conductive layer 171. A sacrificial layer 270G is positioned over the EL layer 172G. The light-emitting device 61B includes the conductive layer 171 and an EL layer 172B, and the EL layer 172B covers the top surface and the side surface of the conductive layer 171. A sacrificial layer 270B is positioned over the EL layer 172B.

The conductive layer 171 is electrically connected to one of the source and the drain of the transistor 310 through a plug 256 embedded in the insulating layer 243, the insulating layer 255a, the insulating layer 255b, and the insulating layer 255c, the conductive layer 241 embedded in the insulating layer 254, and the plug 275 embedded in the insulating layer 261. The top surface of the insulating layer 255c and the top surface of the plug 256 are level with or substantially level with each other. Any of a variety of conductive materials can be used for the plugs.

### [Protective Layer 271, Insulating Layer 278, Protective Layer 273, and Bonding Layer 122]

A protective layer 271 and an insulating layer 278 are positioned between adjacent light-emitting devices, e.g., between the light-emitting device 61R and the light-emitting device 61G, and the insulating layer 278 is provided over the protective layer 271. A protective layer 273 is provided over the light-emitting device 61R, the light-emitting device 61G, and the light-emitting device 61B.

A bonding layer 122 attaches the protective layer 273 to a substrate 120.

### [Substrate 120]

The substrate 120 corresponds to a substrate 73 in FIG. 8. A light-blocking layer can be provided for the surface of the substrate 120 on the bonding layer 122 side, for example. A variety of optical members can be provided on the outer side of the substrate 120.

A film can be used as the substrate. In particular, a film with a low water absorption rate can be suitably used. For example, the water absorption rate is preferably lower than or equal to 1%, further preferably lower than or equal to 0.1%. Thus, a change in size of the film can be inhibited. Furthermore, generation of wrinkles or the like can be inhibited. Moreover, a change in shape of the display apparatus can be inhibited.

For example, a polarizing plate, a retardation plate, a light diffusion layer (e.g., a diffusion film), an anti-reflection layer, a light-condensing film, or the like can be used as the optical member.

It is possible that a highly optically isotropic material, in other words, a material with a low birefringence index is used for the substrate and a circular polarizing plate is provided to overlap with the display apparatus. For example, it is possible to use, for the substrate, a material that has an absolute value of a retardation (phase difference) lower than or equal to 30 nm, preferably lower than or equal to 20 nm, further preferably lower than or equal to 10 nm. For example, a triacetyl cellulose (TAC, also referred to as cellulose triacetate) film, a cycloolefin polymer (COP) film, a cycloolefin copolymer (COC) film, an acrylic resin film, or the like can be used as a highly optically isotropic film.

Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, a glass layer, a silica layer (SiOₓ layer), diamond-like carbon (DLC), aluminum oxide (AlOₓ), a polyester-based material, a polycarbonate-based material, or the like can be used for the surface protective layer. Note that a material having a high visible light transmittance can be suitably used for the surface protective layer. In addition, a material having high hardness can be suitably used for the surface protective layer.

### <<Display Apparatus 100B>>

FIG. 9B is a cross-sectional view illustrating a structure of a display apparatus 100B. For example, the display apparatus 100B can be used as the display apparatus 100 of the display module 280 (see FIG. 8).

The display apparatus 100B includes the substrate 301, a light-emitting device 61W, the capacitor 240, and the transistor 310. The light-emitting device 61W can emit white light, for example.

The display apparatus 100B includes a coloring layer 183R, a coloring layer 183G, and a coloring layer 183B. The coloring layer 183R includes a region overlapping with one light-emitting device 61W, the coloring layer 183G includes a region overlapping with another light-emitting device 61W, and the coloring layer 183B includes a region overlapping with another light-emitting device 61W.

For example, the coloring layer 183R can transmit red light, the coloring layer 183G can transmit green light, and the coloring layer 183B can transmit blue light.

### <<Display Apparatus 100C>>

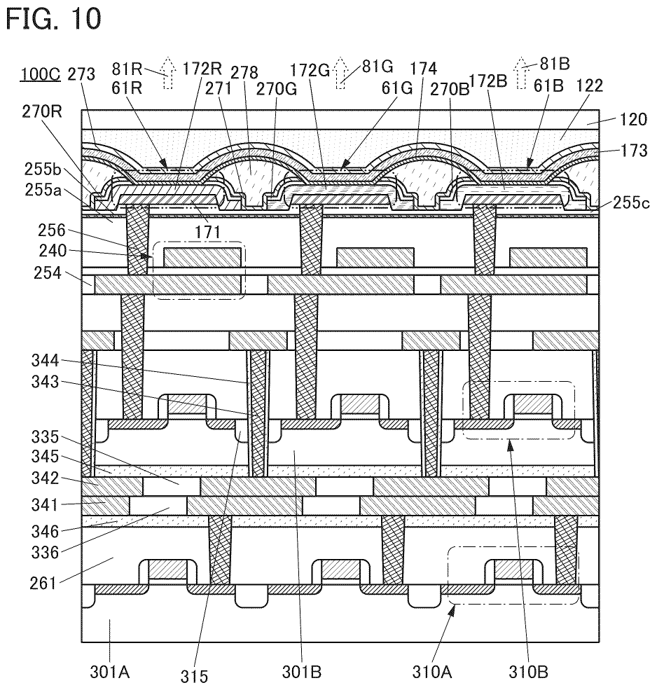

FIG. 10 is a cross-sectional view illustrating a structure of a display apparatus 100C. The display apparatus 100C can be used as the display apparatus 100 of the display module 280, for example (see FIG. 8). Note that in the following description of display apparatuses, the description of portions similar to those of the above-described display apparatuses may be omitted.

The display apparatus 100C includes a substrate 301B and the substrate 301A. The display apparatus 100C includes a transistor 310B, the capacitor 240, the light-emitting device 61, and a transistor 310A. A channel of the transistor 310A is formed in part of the substrate 301A and a channel of the transistor 310B is formed in part of the substrate 301B.

### [Insulating Layer 345 and Insulating Layer 346]

An insulating layer 345 is in contact with the bottom surface of the substrate 301B, and an insulating layer 346 is positioned over the insulating layer 261. For example, the inorganic insulating film that can be used as the protective layer 273 can be used as the insulating layer 345 and the insulating layer 346. The insulating layer 345 and the insulating layer 346 function as protective layers and can inhibit impurities from being diffused into the substrate 301B and the substrate 301A.

### [Plug 343]

A plug 343 penetrates the substrate 301B and the insulating layer 345. An insulating layer 344 covers the side surface of the plug 343. For example, the inorganic insulating film that can be used as the protective layer 273 can be used as the insulating layer 344. The insulating layer 344 functions as a protective layer and can inhibit impurities from being diffused into the substrate 301B.

### [Conductive Layer 342]

A conductive layer 342 is positioned between the insulating layer 345 and the insulating layer 346. The conductive layer 342 is embedded in an insulating layer 335, and a plane formed by the conductive layer 342 and the insulating layer 335 is preferably planarized. Note that the conductive layer 342 is electrically connected to the plug 343.

### [Conductive Layer 341]

A conductive layer 341 is positioned between the insulating layer 346 and the insulating layer 335. It is preferable that the conductive layer 341 be embedded in an insulating layer 336 and a plane formed by the conductive layer 341 and the insulating layer 336 be planarized. The conductive layer 341 is bonded to the conductive layer 342. Thus, the substrate 301A is electrically connected to the substrate 301B.

The conductive layer 341 and the conductive layer 342 are preferably formed using the same conductive material. For example, it is possible to use a metal film containing an element selected from Al, Cr, Cu, Ta, Ti, Mo, and W, or a metal nitride film containing any of the above elements as a component (e.g., a titanium nitride film, a molybdenum nitride film, or a tungsten nitride film). Copper is particularly preferably used for the conductive layer 341 and the conductive layer 342. that case, it is possible to employ Cu-to-Cu (copper-to-copper) direct bonding technique (a technique for achieving electrical continuity by connecting Cu (copper) pads).

### <<Display Apparatus 100D>>

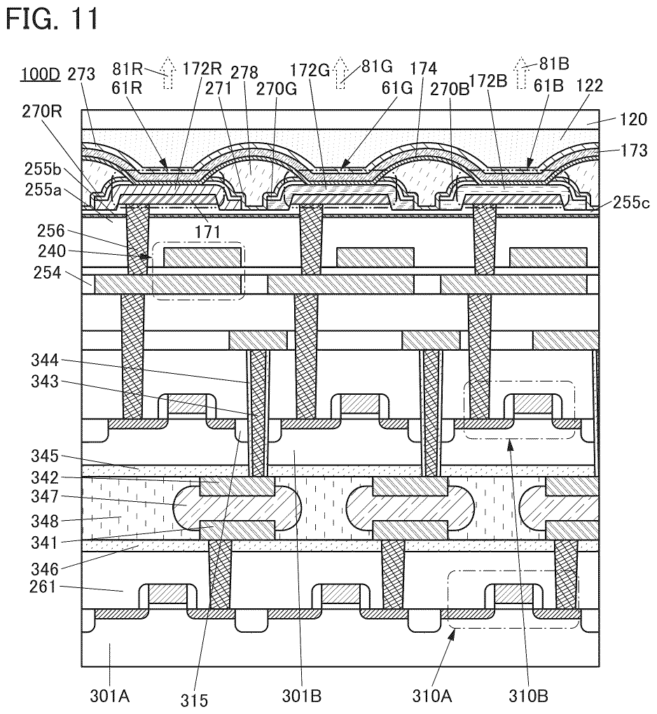

FIG. 11 is a cross-sectional view illustrating a structure of a display apparatus 100D. The display apparatus 100D can be used as the display apparatus 100 of the display module 280, for example (see FIG. 8).

The display apparatus 100D includes a bump 347, and the bump 347 bonds the conductive layer 341 to the conductive layer 342. The bump 347 electrically connects the conductive layer 341 to the conductive layer 342. The bump 347 can be formed using a conductive material containing gold (Au), nickel (Ni), indium (In), tin (Sn), or the like, for example. Solder can be used for the bump 347, for example.

The display apparatus 100D includes a bonding layer 348. The bonding layer 348 attaches the insulating layer 345 to the insulating layer 346.

### <<Display Apparatus 100E>>

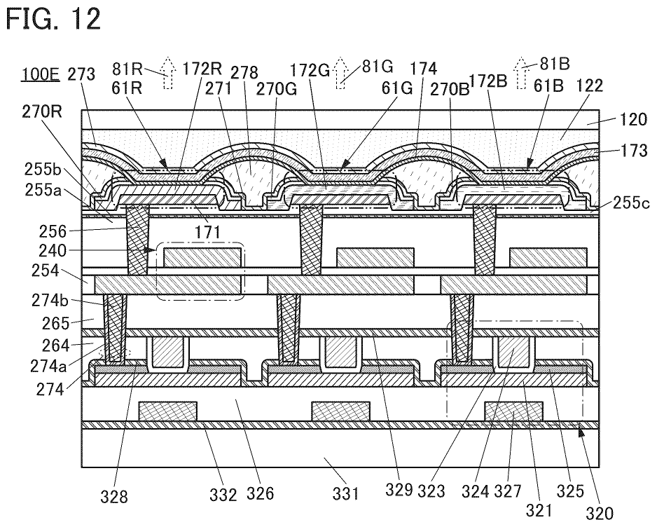

FIG. 12 is a cross-sectional view illustrating a structure of a display apparatus 100E. The display apparatus 100E can be used as the display apparatus 100 of the display module 280, for example (see FIG. 8). A substrate 331 corresponds to the substrate 71 in FIG. 8. An insulating substrate or a semiconductor substrate can be used as the substrate 331. The display apparatus 100E includes a transistor 320. Note that the display apparatus 100E is different from the display apparatus 100A in that the transistor is an OS transistor.

### [Insulating Layer 332]

An insulating layer 332 is provided over the substrate 331. For example, a film in which hydrogen or oxygen is less likely to be diffused than in a silicon oxide film can be used as the insulating layer 332. Specifically, an aluminum oxide film, a hafnium oxide film, a silicon nitride film, or the like can be used as the insulating layer 332. Thus, the insulating layer 332 can prevent impurities such as water and hydrogen from being diffused from the substrate 331 into the transistor 320. Furthermore, oxygen can be prevented from being released from a semiconductor layer 321 to the insulating layer 332 side.

### [Transistor 320]

The transistor 320 includes the semiconductor layer 321, an insulating layer 323, a conductive layer 324, a pair of conductive layers 325, an insulating layer 326, and a conductive layer 327.

The conductive layer 327 is provided over the insulating layer 332 and functions as a first gate electrode of the transistor 320. The insulating layer 326 covers the conductive layer 327. Part of the insulating layer 326 functions as a first gate insulating layer. The insulating layer 326 includes an oxide insulating film at least in a region in contact with the semiconductor layer 321. Specifically, a silicon oxide film or the like is preferably used. The insulating layer 326 has a planarized top surface. The semiconductor layer 321 is provided over the insulating layer 326. A metal oxide film having semiconductor characteristics can be used as the semiconductor layer 321. The pair of conductive layers 325 is provided on and in contact with the semiconductor layer 321, and functions as a source electrode and a drain electrode.

### [Insulating Layer 328 and Insulating Layer 264]

An insulating layer 328 covers the top surfaces and side surfaces of the pair of conductive layers 325, the side surface of the semiconductor layer 321, and the like. An insulating layer 264 is provided over the insulating layer 328 and functions as an interlayer insulating layer. The insulating layer 328 and the insulating layer 264 have an opening portion reaching the semiconductor layer 321. For example, an insulating film similar to the insulating layer 332 can be used as the insulating layer 328. Thus, the insulating layer 328 can prevent impurities such as water and hydrogen from being diffused from the insulating layer 264 into the semiconductor layer 321. Furthermore, oxygen can be prevented from being released from the semiconductor layer 321.

### [Insulating Layer 323]

The insulating layer 323 is in contact with the side surfaces of the insulating layer 264 and the insulating layer 328 and the conductive layer 325 and the top surface of the semiconductor layer 321 inside the opening portion.

### [Conductive Layer 324]

Inside the opening portion, the conductive layer 324 is embedded and in contact with the insulating layer 323. The conductive layer 324 has a top surface subjected to planarization treatment, and is level with or substantially level with the top surface of the insulating layer 323 and the top surface of the insulating layer 264. The conductive layer 324 functions as a second gate electrode, and the insulating layer 323 functions as a second gate insulating layer.

### [Insulating Layer 329 and Insulating Layer 265]

An insulating layer 329 covers the conductive layer 324 and the insulating layer 323 and the insulating layer 264. An insulating layer 265 is provided over the insulating layer 329 and functions as an interlayer insulating layer. For example, an insulating film similar to the insulating layer 328 and the insulating layer 332 can be used as the insulating layer 329. Thus, impurities such as water and hydrogen can be prevented from being diffused from the insulating layer 265 into the transistor 320, for example.

### [Plug 274]

A plug 274 is embedded in the insulating layer 265, the insulating layer 329, the insulating layer 264, and the insulating layer 328 and is electrically connected to one of the pair of conductive layers 325. The plug 274 includes a conductive layer 274a and a conductive layer 274b. The conductive layer 274a is in contact with each of the side surfaces of openings in the insulating layer 265, the insulating layer 329, the insulating layer 264, and the insulating layer 328. In addition, the conductive layer 274a covers part of the top surface of the conductive layer 325. The conductive layer 274b is in contact with the top surface of the conductive layer 274a. For example, a conductive material in which hydrogen and oxygen are less likely to be diffused can be suitably used for the conductive layer 274a.

### <<Display Apparatus 100F>>

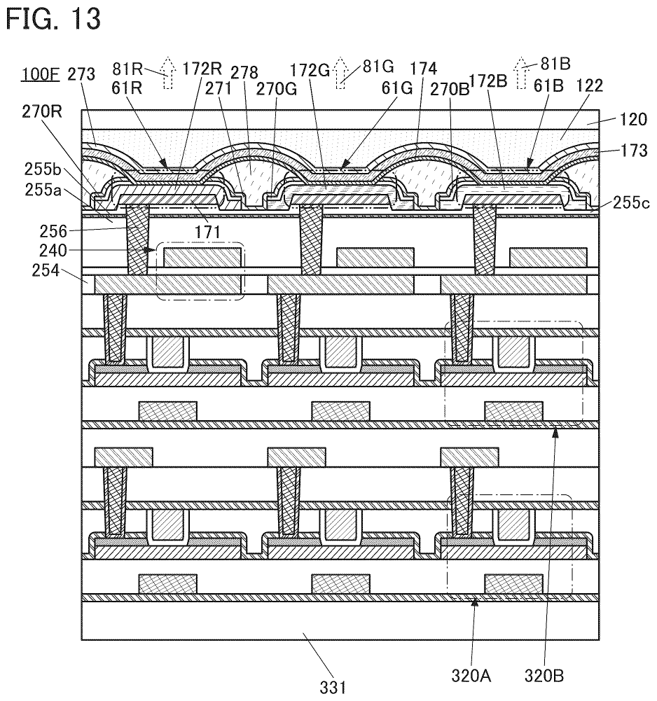

FIG. 13 is a cross-sectional view illustrating a structure of a display apparatus 100F. The display apparatus 100F has a structure in which a transistor 320A and a transistor 320B are stacked. Each of the transistor 320A and the transistor 320B includes an oxide semiconductor and a channel of each transistor is formed in the oxide semiconductor. Note that the structure of the display apparatus 100F is not limited to the structure in which two transistors are stacked, and may be a structure in which three or more transistors are stacked, for example.

The structures of the transistor 320A and the peripheral components are the same as those of the transistor 320 and the peripheral components of the display apparatus 100E. The structures of the transistor 320B and the peripheral components are the same as those of the transistor 320 and the peripheral components of the display apparatus 100E.

### <<Display Apparatus 100G>>

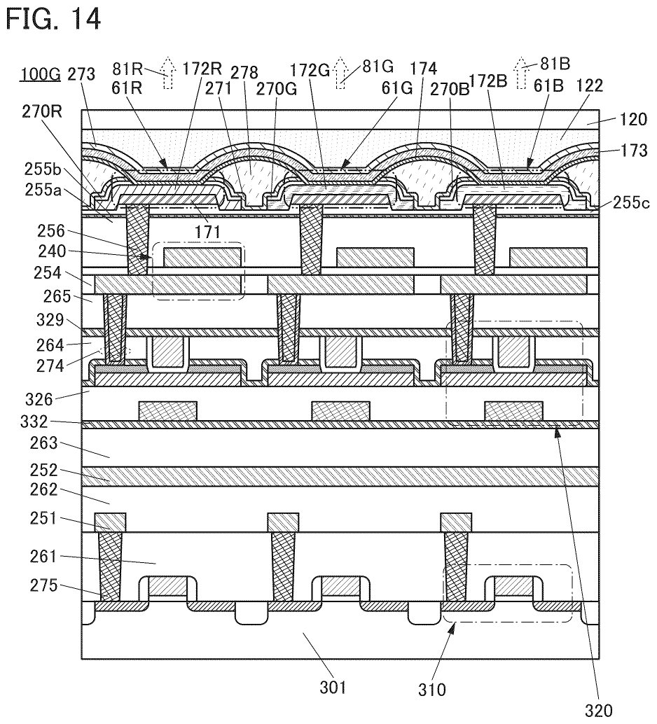

FIG. 14 is a cross-sectional view illustrating a structure of a display apparatus 100G. The display apparatus 100G has a structure in which the transistor 310 and the transistor 320 are stacked. The channel of the transistor 310 is formed in the substrate 301. The transistor 320 includes a metal oxide and its channel is formed in the oxide semiconductor.

The insulating layer 261 covers the transistor 310 and a conductive layer 251 is provided over the insulating layer 261. An insulating layer 262 covers the conductive layer 251 and a conductive layer 252 is provided over the insulating layer 262. An insulating layer 263 and the insulating layer 332 covers the conductive layer 252. The conductive layer 251 and the conductive layer 252 each function as a wiring.

The transistor 320 is provided over the insulating layer 332 and the insulating layer 265 covers the transistor 320. The capacitor 240 is provided over the insulating layer 265 and is electrically connected to the transistor 320 through the plug 274.

For example, the transistor 320 can be used as a transistor included in a pixel circuit. For another example, the transistor 310 can be used as a transistor included in a pixel circuit or for a driver circuit (e.g., a gate driver circuit or a source driver circuit) for driving the pixel circuit. The transistor 310 and the transistor 320 can be used for a variety of circuits such as an arithmetic circuit and a memory circuit. Thus, not only a pixel circuit but also a driver circuit can be provided directly under the light-emitting device, for example. The display apparatus can be downsized as compared to the case where a driver circuit is provided around a display region.

At least part of this embodiment can be implemented in combination with the other embodiments described in this specification as appropriate.

### Embodiment 9

In this embodiment, a display apparatus of one embodiment of the present invention is described

### <Display Module>

FIG. 15 is a perspective view illustrating a structure of a display module.

The display module includes a display apparatus 100H, an IC (integrated circuit), an FPC 177 and a connector. The display apparatus 100H is electrically connected to an IC 176 and the FPC 177. The FPC 177 is supplied with a signal and electric power from the outside and supplies the signal and the electric power to the display apparatus 100H. Note that a connector is a mechanical component for electrical connection through a conductor, and the conductor can electrically connect the display apparatus 100H to a component to be connected. For example, the FPC 177 can be used as the conductor. The connector can detach the display apparatus 100H from the connected component.

The display module includes the IC 176. For example, the IC 176 can be provided for a substrate 14b by a COG (Chip On Glass) method or the like. Alternatively, the IC 176 can be provided for an FPC by a COF (Chip On Film) method or the like, for example. Note that a gate driver circuit, a source driver circuit, or the like can be used as the IC 176.

### <<Display Apparatus 100H>>

The display apparatus 100H includes a display portion 37b, a connection portion 140, a circuit 164, a wiring 165, and the like.

FIG. 16A is a cross-sectional view illustrating a structure of the display apparatus 100H. The display apparatus 100H includes a substrate 16b and the substrate 14b, which are attached to each other. The display apparatus 100H includes one or more connection portions 140. The connection portion(s) 140 can be provided outside the display portion 37b. For example, the connection portion 140 can be provided along one side of the display portion 37b. Alternatively, the connection portion(s) 140 can be provided along a plurality of sides, for example, to surround four sides. In the connection portion 140, a common electrode of a light-emitting device is electrically connected to a conductive layer, which supplies a predetermined potential to the common electrode.

The wiring 165 is supplied with a signal or electric power from the FPC 177 or the IC 176. The wiring 165 supplies a signal and electric power to the display portion 37b and the circuit 164.

For example, a gate driver circuit can be used as the circuit 164.

The display apparatus 100H includes the substrate 14b, the substrate 16b, a transistor 201, a transistor 205, a light-emitting device 63R, a light-emitting device 63G, a light-emitting device 63B, and the like (see FIG. 16A). For example, the light-emitting device 63R emits red light 83R, the light-emitting device 63G emits green light 83G, and the light-emitting device 63B emits blue light 83B. Note that a variety of optical members can be provided on the outer side of the substrate 16b. For example, a polarizing plate, a retardation plate, a light diffusion layer (e.g., a diffusion film), an anti-reflection layer, a light-condensing film, or the like can be provided.

For example, the light-emitting device described in any of Embodiment 1 to Embodiment 6 can be used as each of the light-emitting device 63R, the light-emitting device 63G, and the light-emitting device 63B.

A light-emitting device 63 includes the conductive layer 171, which functions as a pixel electrode. The conductive layer 171 includes a depressed portion, which overlaps with an opening portion provided in an insulating layer 214, an insulating layer 215, and an insulating layer 213. The transistor 205 includes a conductive layer 222b, which is electrically connected to the conductive layer 171.

The display apparatus 100H includes an insulating layer 272. The insulating layer 272 covers an end portion of the conductive layer 171 to fill the depressed portion of the conductive layer 171 (see FIG. 16A).

The display apparatus 100H includes the protective layer 273 and a bonding layer 142. The protective layer 273 covers the light-emitting device 63R, the light-emitting device 63G, and the light-emitting device 63B. The protective layer 273 and the substrate 16b are bonded to each other with the bonding layer 142. The bonding layer 142 fills a space between the substrate 16b and the protective layer 273. Note that the bonding layer 142 may be formed in a frame shape so as not to overlap with the light-emitting devices and a region surrounded by the bonding layer 142, the substrate 16b, and the protective layer 273 may be filled with a resin different from the material of the bonding layer 142. Alternatively, a hollow sealing structure may be employed, in which the region is filled with an inert gas (e.g., nitrogen or argon). For example, the material that can be used for the bonding layer 122 can be used for the bonding layer 142.

The display apparatus 100H includes the connection portion 140, which includes a conductive layer 168. Note that a power supply potential is supplied to the conductive layer 168. The light-emitting device 63 includes a conductive layer 173, and the conductive layer 168 is electrically connected to the conductive layer 173, to which a power supply potential is supplied. Note that the conductive layer 173 functions as a common electrode. For example, the conductive layer 171 and the conductive layer 168 can be formed by processing one conductive film.

The display apparatus 100H has a top-emission structure. The light-emitting device emits light to the substrate 16b side. The conductive layer 171 contains a material reflecting visible light, and the conductive layer 173 transmits visible light.

### [Insulating Layer 211, Insulating Layer 213, the Insulating Layer 215, and the Insulating Layer 214]

An insulating layer 211, the insulating layer 213, the insulating layer 215, and the insulating layer 214 are provided in this order over the substrate 14b. Note that the number of insulating layers is not limited and each insulating layer may be a single layer or a stacked layer of two or more layers.

For example, an inorganic insulating film can be used as each of the insulating layer 211, the insulating layer 213, and the insulating layer 215. A silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

The insulating layer 215 and the insulating layer 214 cover the transistors. The insulating layer 214 functions as a planarization layer. For example, a material in which impurities such as water and hydrogen are less likely to be diffused is preferably used for the insulating layer 215 or the insulating layer 214. This can effectively inhibit impurities from being diffused to the transistors from the outside. Furthermore, the reliability of the display apparatus can be improved.

For example, an organic insulating layer can be favorably used as the insulating layer 214. Specifically, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used for the organic insulating layer. Alternatively, the insulating layer 214 can have a stacked-layer structure of an organic insulating layer and an inorganic insulating layer. Thus, the outermost layer of the insulating layer 214 can be used as an etching protective layer. For example, in the case where a phenomenon of forming a depressed portion in the insulating layer 214 should be avoided in processing the conductive layer 171 into a predetermined shape, the phenomenon can be inhibited.

### [Transistor 201 and Transistor 205]

The transistor 201 and the transistor 205 are formed over the substrate 14b. These transistors can be manufactured using the same materials in the same steps.

Each of the transistor 201 and the transistor 205 includes a conductive layer 221, the insulating layer 211, a conductive layer 222a, the conductive layer 222b, a semiconductor layer 231, the insulating layer 213, and a conductive layer 223. The insulating layer 211 is positioned between the conductive layer 221 and the semiconductor layer 231. The conductive layer 221 functions as a gate and the insulating layer 211 functions as a first gate insulating layer. The conductive layer 222a and the conductive layer 222b function as a source and a drain. The insulating layer 213 is positioned between the conductive layer 223 and the semiconductor layer 231. The conductive layer 223 functions as a gate and the insulating layer 213 functions as a second gate insulating layer. Here, a plurality of layers obtained by processing the same conductive film are shown with the same hatching pattern.

There is no particular limitation on the structure of the transistors included in the display apparatus of this embodiment. For example, a planar transistor, a staggered transistor, an inverted staggered transistor, or the like can be used. A top-gate transistor structure or a bottom-gate transistor structure may be employed. Alternatively, gates may be provided above and below a semiconductor layer where a channel is formed.

The structure in which the semiconductor layer where a channel is formed is provided between two gates is used for the transistor 201 and the transistor 205. The two gates may be connected to each other and supplied with the same signal to operate the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor layer of each of the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case deterioration of the transistor characteristics can be inhibited.

The semiconductor layer of the transistor preferably contains a metal oxide. That is, an OS transistor is preferably used as the transistor included in the display apparatus of this embodiment.

### [Semiconductor Layer]

For example, indium oxide, gallium oxide, and zinc oxide can be used for the semiconductor layer. The metal oxide preferably contains two or three selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin.

It is particularly preferable that an oxide containing indium (In), gallium (Ga), and zinc (Zn)(also referred to as IGZO) be used as the metal oxide used for the semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium (In), aluminum (Al), and zinc (Zn)(also referred to as IAZO). Alternatively, it is preferable to use an oxide containing indium (In), aluminum (Al), gallium (Ga), and zinc (Zn)(also referred to as IAGZO).

In the case where the metal oxide used for the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

Alternatively, the semiconductor layer may include two or more metal oxide layers having different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed. In particular, gallium or aluminum is preferably used as the element M.

Alternatively, a stacked-layer structure of one selected from indium oxide, indium gallium oxide, and IGZO, and one selected from IAZO, IAGZO, and ITZO (registered trademark) may be employed, for example.

As the oxide semiconductor having crystallinity, a CAAC (c-axis aligned crystalline)-OS, an nc (nanocrystalline)-OS, and the like can be given.

Alternatively, a transistor containing silicon in its channel formation region (a Si transistor) may be used. As silicon, single crystal silicon, polycrystalline silicon, amorphous silicon, and the like can be given. In particular, a transistor containing low-temperature polysilicon (LTPS) in a semiconductor layer (such a transistor is referred to as an LTPS transistor) can be used. The LTPS transistor has high field-effect mobility and favorable frequency characteristics.

With the use of a Si transistor such as an LTPS transistor, a circuit required to be driven at a high frequency (e.g., a data driver circuit) can be formed on the same substrate as the display portion. Thus, external circuits mounted on the display apparatus can be simplified, and parts costs and mounting costs can be reduced.

An OS transistor has extremely higher field-effect mobility than a transistor using amorphous silicon. In addition, the OS transistor has extremely low leakage current between a source and a drain in an off state (hereinafter, also referred to as off-state current), and electric charge accumulated in a capacitor that is connected in series to the transistor can be retained for a long period. Furthermore, power consumption of the display apparatus can be reduced with the use of an OS transistor.

In addition, to increase the emission luminance of the light-emitting device included in the pixel circuit, the amount of current flowing through the light-emitting device needs to be increased. For this, it is necessary to increase the source-drain voltage of a driving transistor included in the pixel circuit. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

When a transistor is driven in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be minutely determined by controlling the gate-source voltage. Thus, the amount of current flowing through the light-emitting device can be controlled. Therefore, the number of gray levels in the pixel circuit can be increased.

Regarding saturation characteristics of current flowing when a transistor is driven in a saturation region, even in the case where the source-drain voltage of an OS transistor increases gradually, more stable current (saturation current) can be made flow through an OS transistor than through a Si transistor. Thus, by using an OS transistor as the driving transistor, a stable current can be fed through light-emitting devices even when the current-voltage characteristics of the light-emitting devices vary, for example. In other words, when the OS transistor is driven in the saturation region, the source-drain current hardly changes with an increase in the source-drain voltage. Hence, the emission luminance of the light-emitting device can be stable.

As described above, with the use of an OS transistor as a driving transistor included in the pixel circuit, it is possible to achieve inhibition of black-level degradation, increase in emission luminance, increase in gray level, inhibition of characteristic variation in light-emitting devices, and the like.

The transistors included in the circuit 164 and the transistors included in a display portion 107 may have the same structure or different structures. The same structure or two or more kinds of structures may be employed for a plurality of transistors included in the circuit 164. Similarly, one structure or two or more kinds of structures may be employed for a plurality of transistors included in the display portion 107.

All transistors included in the display portion 107 may be OS transistors, or all transistors included in the display portion 107 may be Si transistors. Alternatively, some of the transistors included in the display portion 107 may be OS transistors and the others may be Si transistors.

For example, when both an LTPS transistor and an OS transistor are used in the display portion 107, the display apparatus can have low power consumption and high driving capability. Note that a structure in which an LTPS transistor and an OS transistor are used in combination is referred to as LTPO in some cases. For example, preferably, an OS transistor is used as a transistor functioning as a switch for controlling conduction and non-conduction between wirings and an LTPS transistor is used as a transistor for controlling current.

For example, one transistor included in the display portion 107 functions as a transistor for controlling current flowing through the light-emitting device and can be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased.

Another transistor included in the display portion 107 functions as a switch for controlling selection or non-selection of a pixel and can be referred to as a selection transistor. A gate of the selection transistor is electrically connected to a gate line, and one of a source and a drain thereof is electrically connected to a signal line. An OS transistor is preferably used as the selection transistor. In that case, the gray level of the pixel can be maintained even with an extremely low frame frequency (e.g., 1 fps or less); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having an MML structure. This structure can significantly reduce leakage current that would flow through a transistor and leakage current that would flow between adjacent light-emitting devices. With the structure, a viewer can notice any one or more of the image crispness, the image sharpness, a high saturation, and a high contrast ratio in an image displayed on the display apparatus. When leakage current that would flow through the transistor and lateral leakage current that would flow between light-emitting devices are extremely low, display with little leakage of light at the time of black display (black-level degradation), for example, can be achieved.

In particular, with the light-emitting device having the MML structure, current flowing between adjacent light-emitting devices can be extremely reduced.

### [Transistor 209 and Transistor 210]

FIG. 16B and FIG. 16C are cross-sectional views each illustrating another example of a cross-sectional structure of a transistor that can be used for the display apparatus 100H.

A transistor 209 and a transistor 210 each include the conductive layer 221, the insulating layer 211, the semiconductor layer 231, the conductive layer 222a, the conductive layer 222b, an insulating layer 225, the conductive layer 223, and the insulating layer 215. The semiconductor layer 231 includes a channel formation region 231i and a pair of low-resistance regions 231n. The insulating layer 211 is positioned between the conductive layer 221 and the channel formation region 231i. The conductive layer 221 functions as a gate and the insulating layer 211 functions as a first gate insulating layer. The insulating layer 225 is positioned at least between the conductive layer 223 and the channel formation region 231i. The conductive layer 223 functions as a gate, and the insulating layer 225 functions as a second gate insulating layer. The conductive layer 222a is electrically connected to one of the pair of low-resistance regions 231n and the conductive layer 222b is electrically connected to the other of the pair of low-resistance regions 231n. The insulating layer 215 covers the conductive layer 223. An insulating layer 218 covers the transistor.

### [Structure Example 1 of Insulating Layer 225]

In the transistor 209, the insulating layer 225 covers the top surface and the side surface of the semiconductor layer 231 (see FIG. 16B). The insulating layer 225 and the insulating layer 215 have opening portions and the conductive layer 222a and the conductive layer 222b are electrically connected to the low-resistance regions 231n through the opening portions. One of the conductive layer 222a and the conductive layer 222b functions as a source, and the other functions as a drain.

### [Structure Example 2 of Insulating Layer 225]

In the transistor 210, the insulating layer 225 overlaps with the channel formation region 231i of the semiconductor layer 231 and does not overlap with the low-resistance regions 231n (see FIG. 16C). For example, the insulating layer 225 can be formed by processing into a predetermined shape with the use of the conductive layer 223 as a mask. The insulating layer 215 covers the insulating layer 225 and the conductive layer 223. The insulating layer 215 has opening portions, and the conductive layer 222a and the conductive layer 222b are electrically connected to the low-resistance regions 231n.

### [Connection Portion 204]

A connection portion 204 is provided for the substrate 14b. The connection portion 204 includes a conductive layer 166, which is electrically connected to the wiring 165. Note that the connection portion 204 does not overlap with the substrate 16b, and the conductive layer 166 is exposed. Note that the conductive layer 166 and the conductive layer 171 can be formed by processing one conductive film. The conductive layer 166 is electrically connected to the FPC 177 through a connection layer 242. As the connection layer 242, for example, an anisotropic conductive film (ACF) or an anisotropic conductive paste (ACP) can be used.

### <<Display Apparatus 100I>>

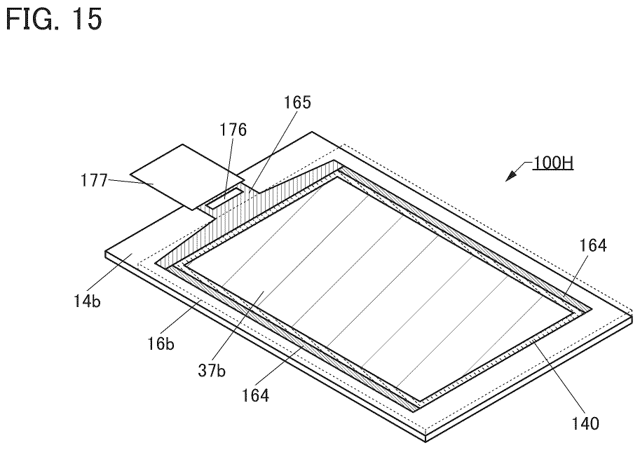

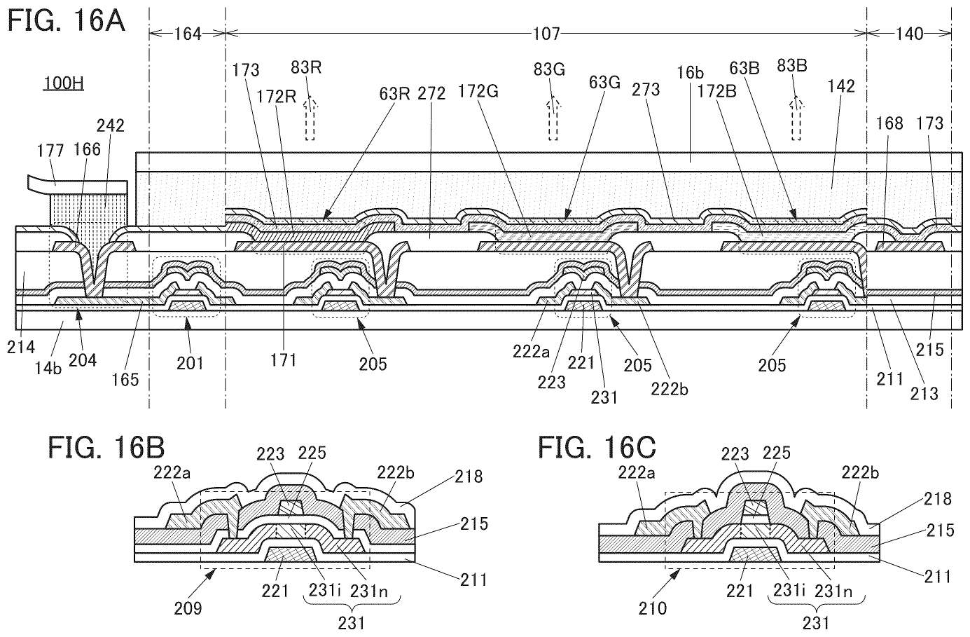

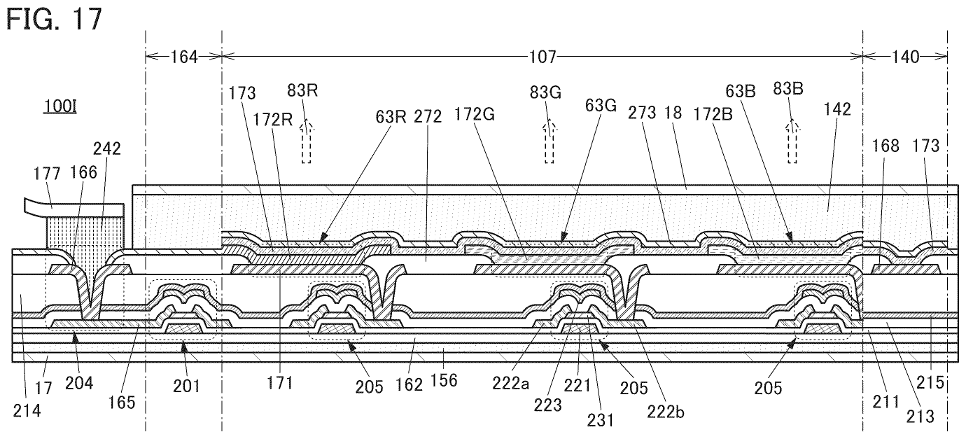

FIG. 17 is a cross-sectional view illustrating a structure of a display apparatus 100I. The display apparatus 100I is different from the display apparatus 100H in having flexibility. In other words, the display apparatus 100I is a flexible display. The display apparatus 100I includes a substrate 17 and a substrate 18 instead of the substrate 14b and the substrate 16b, respectively. The substrate 17 and the substrate 18 both have flexibility.

The display apparatus 100I includes a bonding layer 156 and an insulating layer 162. The insulating layer 162 and the substrate 17 are bonded to each other with the bonding layer 156. For example, the material that can be used for the bonding layer 122 can be used for the bonding layer 156. For example, the material that can be used for the insulating layer 211, the insulating layer 213, or the insulating layer 215 can be used for the insulating layer 162. Note that the transistor 201 and the transistor 205 are provided over the insulating layer 162.

For example, the insulating layer 162 is formed over a formation substrate, and the transistors, the light-emitting devices 63, and the like are formed over the insulating layer 162. Then, the bonding layer 142 is formed over the light-emitting devices 63, and the formation substrate and the substrate 18 are bonded to each other with the bonding layer 142. After that, the formation substrate is separated from the insulating layer 162 and the surface of the insulating layer 162 is exposed. Then, the bonding layer 156 is formed on the exposed surface of the insulating layer 162, and the insulating layer 162 and the substrate 17 are bonded to each other with the bonding layer 156. In this manner, the components formed over the formation substrate can be transferred onto the substrate 17, whereby the display apparatus 100I can be manufactured.

### <<Display Apparatus 100J>>

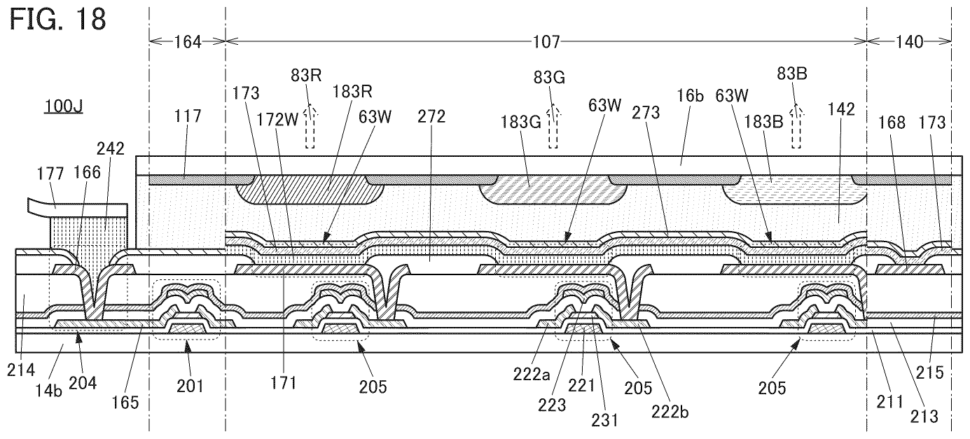

FIG. 18 is a cross-sectional view illustrating a structure of a display apparatus 100J. The display apparatus 100J is different from the display apparatus 100H in including light-emitting devices 63W, instead of the light-emitting device 63R, the light-emitting device 63G and the light-emitting device 63B, and the coloring layer 183R, the coloring layer 183G, and the coloring layer 183B.

The display apparatus 100J includes the coloring layer 183R, the coloring layer 183G, and the coloring layer 183B between the substrate 16b and the substrate 14b. The coloring layer 183R overlaps with one light-emitting device 63W, the coloring layer 183G overlaps with another light-emitting device 63W, and the coloring layer 183B overlaps with another light-emitting device 63W.

The display apparatus 100J includes a light-blocking layer 117. For example, the light-blocking layer 117 is provided between the coloring layer 183R and the coloring layer 183G, between the coloring layer 183G and the coloring layer 183B, and between the coloring layer 183B and the coloring layer 183R. The light-blocking layer 117 includes a region overlapping with the connection portion 140 and a region overlapping with the circuit 164.

The light-emitting device 63W can emit white light, for example. For example, the coloring layer 183R can transmit red light, the coloring layer 183G can transmit green light, and the coloring layer 183B can transmit blue light. In this manner, the display apparatus 100J can emit the red light 83R, the green light 83G, and the blue light 83B, for example, to perform full color display.

At least part of this embodiment can be implemented in combination with the other embodiments described in this specification as appropriate.

### Embodiment 10

In this embodiment, electronic devices of embodiments of the present invention will be described.

Electronic devices of this embodiment each include the display apparatus of one embodiment of the present invention in a display portion. The display apparatus of one embodiment of the present invention is highly reliable and can be easily increased in resolution and definition. Thus, the display apparatus of one embodiment of the present invention can be used for display portions of a variety of electronic devices.

Examples of electronic devices include a digital camera, a digital video camera, a digital photo frame, a mobile phone, a portable game machine, a portable information terminal, and an audio reproducing device, in addition to electronic devices with a relatively large screen, such as a television device, a desktop or laptop personal computer, a monitor of a computer, digital signage, and a large game machine such as a pachinko machine.

In particular, the display apparatus of one embodiment of the present invention can have high resolution, and thus can be suitably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the display apparatus of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With the use of such a display apparatus having one or both of high definition and high resolution, the electronic device can provide higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

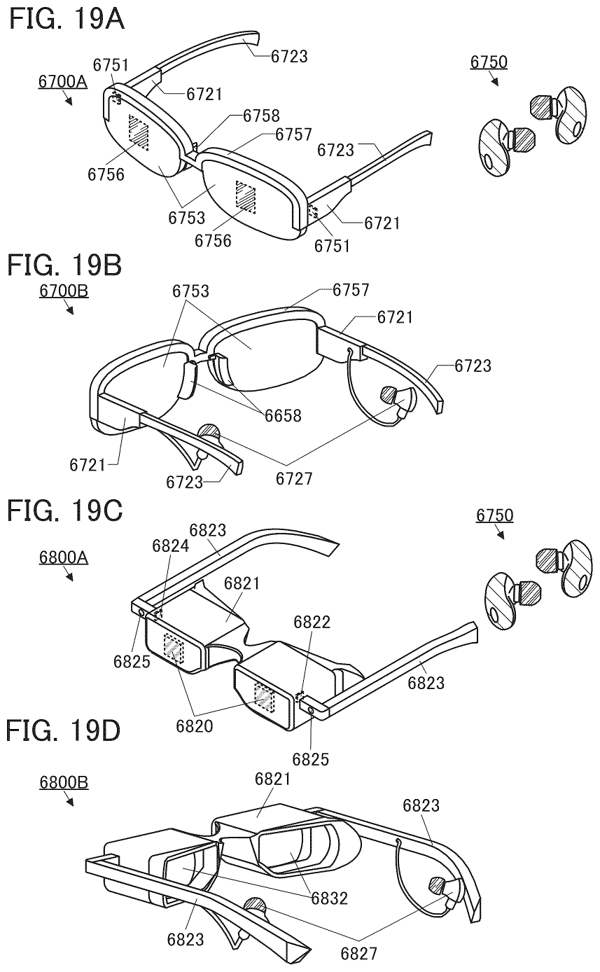

Examples of a wearable device that can be worn on the head are described with reference to FIG. 19A to FIG. 19D. These wearable devices have at least one of a function of displaying AR contents, a function of displaying VR contents, a function of displaying SR contents, and a function of displaying MR contents. The electronic device having a function of displaying a content of at least one of AR, VR, SR, MR, and the like enables the user to reach a higher level of immersion.

An electronic device 6700A illustrated in FIG. 19A and an electronic device 6700B illustrated in FIG. 19B each include a pair of display panels 6751, a pair of housings 6721, a communication portion (not illustrated), a pair of wearing portions 6723, a control portion (not illustrated), an image capturing portion (not illustrated), a pair of optical members 6753, a frame 6757, and a pair of nose pads 6758.

The display apparatus of one embodiment of the present invention can be used for the display panels 6751. Thus, a highly reliable electronic device is obtained.

The electronic device 6700A and the electronic device 6700B can each project images displayed on the display panels 6751 onto display regions 6756 of the optical members 6753. Since the optical members 6753 have a light-transmitting property, a user can see images displayed on the display regions, which are superimposed on transmission images seen through the optical members 6753. Accordingly, the electronic device 6700A and the electronic device 6700B are electronic devices capable of AR display.

In the electronic device 6700A and the electronic device 6700B, a camera capable of capturing images of the front side may be provided as the image capturing portion. Furthermore, when the electronic device 6700A and the electronic device 6700B are provided with an acceleration sensor such as a gyroscope sensor, the orientation of the user's head can be sensed and an image corresponding to the orientation can be displayed on the display regions 6756.

The communication portion includes a wireless communication device, and a video signal, for example, can be supplied by the wireless communication device. Note that instead of the wireless communication device or in addition to the wireless communication device, a connector to which a cable for supplying a video signal and a power supply potential can be connected may be provided.

The electronic device 6700A and the electronic device 6700B are provided with a battery so that they can be charged wirelessly and/or by wire.

A touch sensor module may be provided in the housing 6721. The touch sensor module has a function of detecting a touch on the outer surface of the housing 6721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 6721, whereby the range of the operation can be increased.

A variety of touch sensors can be applied to the touch sensor module. Any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element (also referred to as a photoelectric conversion device) can be used as a light-receiving element. One or both of an inorganic semiconductor and an organic semiconductor can be used for an active layer of the photoelectric conversion element.

An electronic device 6800A illustrated in FIG. 19C and an electronic device 6800B illustrated in FIG. 19D each include a pair of display portions 6820, a housing 6821, a communication portion 6822, a pair of wearing portions 6823, a control portion 6824, a pair of image capturing portions 6825, and a pair of lenses 6832.

The display apparatus of one embodiment of the present invention can be used in the display portions 6820. Thus, a highly reliable electronic device is obtained.

The display portions 6820 are positioned inside the housing 6821 so as to be seen through the lenses 6832. When the pair of display portions 6820 display different images, three-dimensional display using parallax can also be performed.

The electronic device 6800A and the electronic device 6800B can be regarded as electronic devices for VR. The user who wears the electronic device 6800A or the electronic device 6800B can see images displayed on the display portions 6820 through the lenses 6832.

The electronic device 6800A and the electronic device 6800B preferably include a mechanism for adjusting the lateral positions of the lenses 6832 and the display portions 6820 so that the lenses 6832 and the display portions 6820 are positioned optimally in accordance with the positions of the user's eyes. Moreover, the electronic device 6800A and the electronic device 6800B preferably include a mechanism for adjusting focus by changing the distance between the lenses 6832 and the display portions 6820.

The electronic device 6800A or the electronic device 6800B can be mounted on the user's head with the wearing portions 6823. Note that FIG. 19C illustrates an example in which the wearing portion 6823 has a shape like a temple (also referred to as a joint or the like) of glasses, for example; however, one embodiment of the present invention is not limited thereto. The wearing portion 6823 can have any shape with which the user can wear the electronic device, for example, a shape of a helmet or a band.

The image capturing portion 6825 has a function of obtaining information on the external environment. Data obtained by the image capturing portion 6825 can be output to the display portion 6820. An image sensor can be used for the image capturing portion 6825. Moreover, a plurality of cameras may be provided so as to cover a plurality of fields of view, such as a telescope field of view and a wide field of view.

Although an example of including the image capturing portion 6825 is described here, a range sensor (also referred to as a sensing portion) that is capable of measuring a distance from an object may be provided. In other words, the image capturing portion 6825 is one embodiment of the sensing portion. As the sensing portion, an image sensor or a range image sensor such as LIDAR (Light Detection and Ranging) can be used, for example. By using images obtained by the camera and images obtained by the range image sensor, more information can be obtained and a gesture operation with higher accuracy is possible.

The electronic device 6800A may include a vibration mechanism that functions as bone-conduction earphones. For example, a structure including the vibration mechanism can be applied to any one or more of the display portion 6820, the housing 6821, and the wearing portion 6823. Thus, without additionally requiring an audio device such as headphones, earphones, or a speaker, the user can enjoy video and sound only by wearing the electronic device 6800A.

The electronic device 6800A and the electronic device 6800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 6750. The earphones 6750 include a communication portion (not illustrated) and have a wireless communication function. The earphones 6750 can receive information (e.g., audio data) from the electronic device with the wireless communication function. For example, the electronic device 6700A illustrated in FIG. 19A has a function of transmitting information to the earphones 6750 with the wireless communication function. As another example, the electronic device 6800A illustrated in FIG. 19C has a function of transmitting information to the earphones 6750 with the wireless communication function.

The electronic device may include an earphone portion. The electronic device 6700B illustrated in FIG. 19B includes earphone portions 6727. For example, the earphone portion 6727 and the control portion can be connected to each other by wire. Part of a wiring that connects the earphone portion 6727 and the control portion may be positioned inside the housing 6721 or the wearing portion 6723.

Similarly, the electronic device 6800B illustrated in FIG. 19D includes earphone portions 6827. For example, the earphone portion 6827 and the control portion 6824 can be connected to each other by wire. Part of a wiring that connects the earphone portion 6827 and the control portion 6824 may be positioned inside the housing 6821 or the wearing portion 6823. Alternatively, the earphone portions 6827 and the wearing portions 6823 may include magnets. This is preferable because the earphone portions 6827 can be fixed to the wearing portion 6823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 6700A and the electronic device 6700B) and the goggles-type device (e.g., the electronic device 6800A and the electronic device 6800B) are preferable as the electronic device of one embodiment of the present invention.

The electronic device of one embodiment of the present invention can transmit information to earphones by wire or wirelessly.

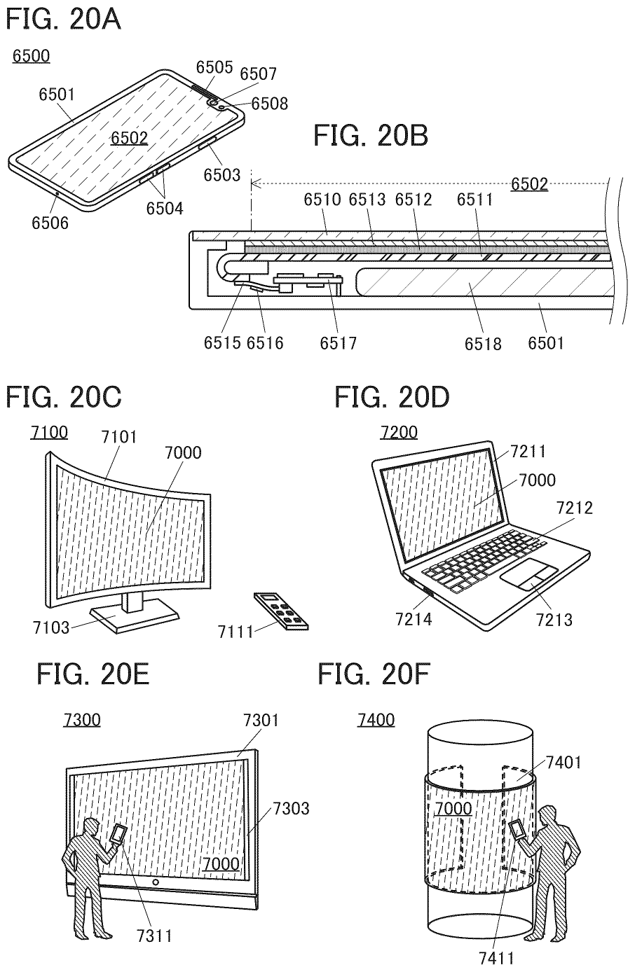

An electronic device 6500 illustrated in FIG. 20A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, a highly reliable electronic device is obtained.

FIG. 20B is a schematic cross-sectional view including the end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the region that is folded back. An IC 6516 is mounted on the FPC 6515. The FPC 6515 is connected to a terminal provided on the printed circuit board 6517.

The display apparatus of one embodiment of the present invention can be used as the display panel 6511. Thus, an extremely lightweight electronic device can be achieved. Since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of a pixel portion, whereby an electronic device with a narrow bezel can be achieved.

FIG. 20C illustrates an example of a television device. In a television device 7100, a display portion 7000 is incorporated in a housing 7101. Here, a structure in which the housing 7101 is supported by a stand 7103 is shown.

The display apparatus of one embodiment of the present invention can be used in the display portion 7000. Thus, a highly reliable electronic device is obtained.

Operation of the television device 7100 illustrated in FIG. 20C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be operated and videos displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) information communication can be performed.

FIG. 20D illustrates an example of a laptop personal computer. The laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used in the display portion 7000. Thus, a highly reliable electronic device is obtained.

FIG. 20E and FIG. 20F illustrate examples of digital signage.

Digital signage 7300 illustrated in FIG. 20E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 20F is digital signage 7400 attached to a cylindrical pillar 7401. The digital signage 7400 includes the display portion 7000 provided along a curved surface of the pillar 7401.

The display apparatus of one embodiment of the present invention can be used in the display portion 7000 illustrated in each of FIG. 20E and FIG. 20F. Thus, a highly reliable electronic device is obtained.

A larger area of the display portion 7000 can increase the amount of information that can be provided at a time. The display portion 7000 having a larger area attracts more attention, so that the effectiveness of the advertisement can be increased, for example.

The touch panel is preferably used in the display portion 7000, in which case in addition to display of still or moving images on the display portion 7000, intuitive operation by a user is possible. Moreover, in the case of an application for providing information such as route information or traffic information, usability can be enhanced by intuitive operation.

As illustrated in FIG. 20E and FIG. 20F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

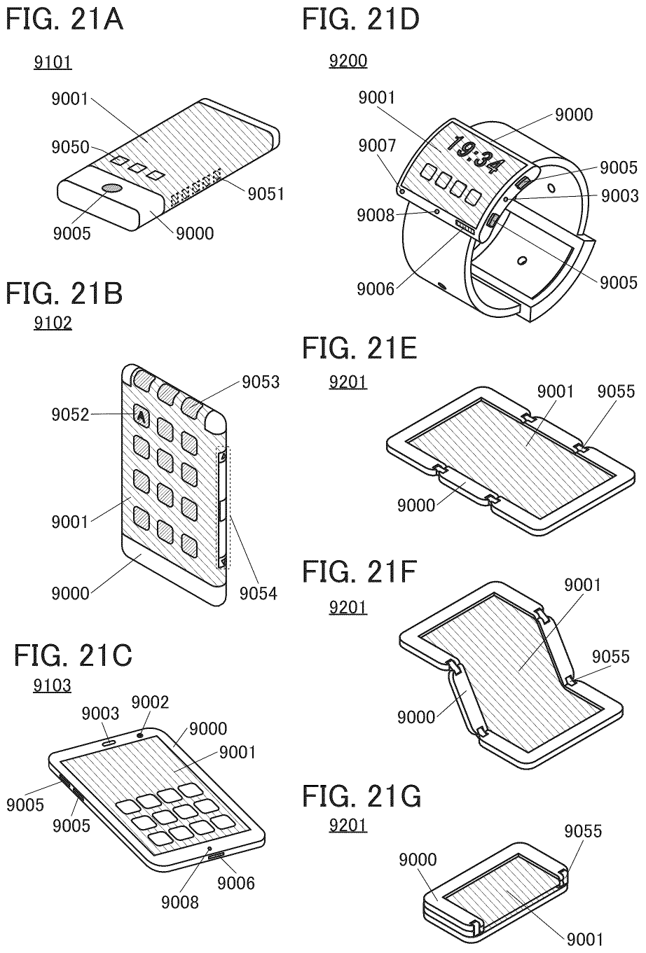

Electronic devices illustrated in FIG. 21A to FIG. 21G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 9008, and the like.

The electronic devices illustrated in FIG. 21A to FIG. 21G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices in FIG. 21A to FIG. 21G are described in detail below.

FIG. 21A is a perspective view illustrating a portable information terminal 9101. For example, the portable information terminal 9101 can be used as a smartphone. Note that the portable information terminal 9101 may include the speaker 9003, the connection terminal 9006, the sensor 9007, or the like. The portable information terminal 9101 can display characters and image information on its plurality of surfaces. FIG. 21A illustrates an example in which three icons 9050 are displayed. Information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, for example, the icon 9050 may be displayed at the position where the information 9051 is displayed.

FIG. 21B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 21C is a perspective view of a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 21D is a perspective view of a watch-type portable information terminal 9200. For example, the portable information terminal 9200 can be used as a Smartwatch (registered trademark). The display surface of the display portion 9001 is curved and provided, and display can be performed along the curved display surface. Mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 21E to FIG. 21G are perspective views illustrating a portable information terminal 9201 that is foldable. FIG. 21E is a perspective view illustrating the portable information terminal 9201 that is opened. FIG. 21G is a perspective view illustrating the portable information terminal 9201 that is folded. FIG. 21F is a perspective view illustrating the portable information terminal 9201 that is shifted from one of the states in FIG. 21E and FIG. 21G to the other. The portable information terminal 9201 is highly portable in the folded state and is highly browsable in the opened state because of a seamless large display region. The display portion 9001 of the portable information terminal 9201 is supported by three housings 9000 joined by hinges 9055. The display portion 9001 can be folded with a radius of curvature of greater than or equal to 0.1 mm and less than or equal to 150 mm, for example.

This embodiment can be combined with the other embodiments as appropriate. In this specification, in the case where a plurality of structure examples are shown in one embodiment, the structure examples can be combined as appropriate.

### Example 1

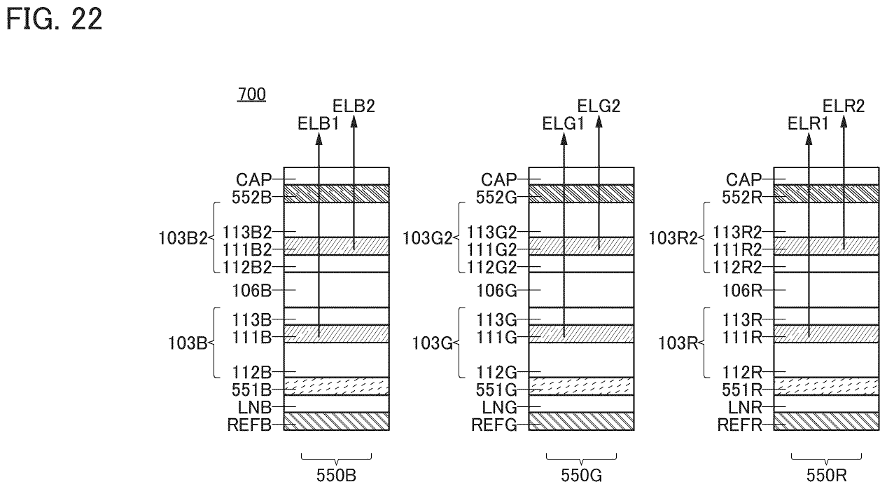

In this example, the display apparatus 700 of one embodiment of the present invention will be described with reference to FIG. 22 to FIG. 29.

FIG. 22 is a diagram illustrating a structure of the display apparatus 700 of one embodiment of the present invention.

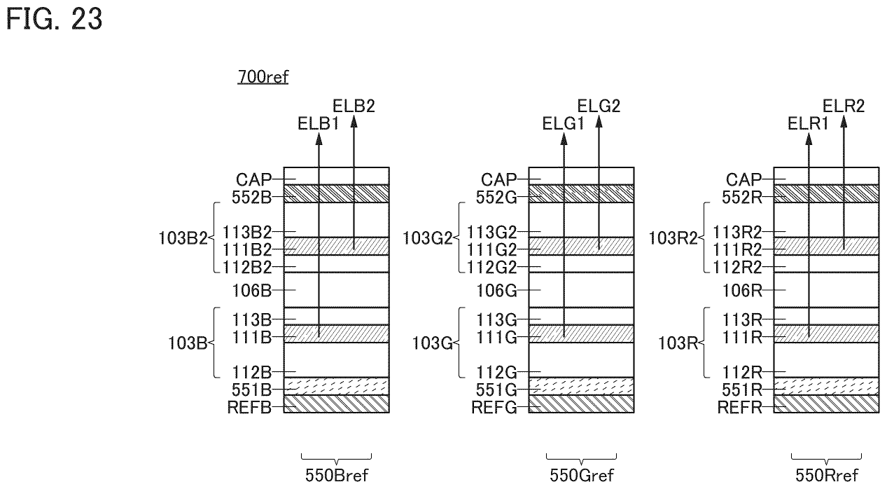

FIG. 23 is diagram illustrating a structure of a comparative apparatus 700ref.

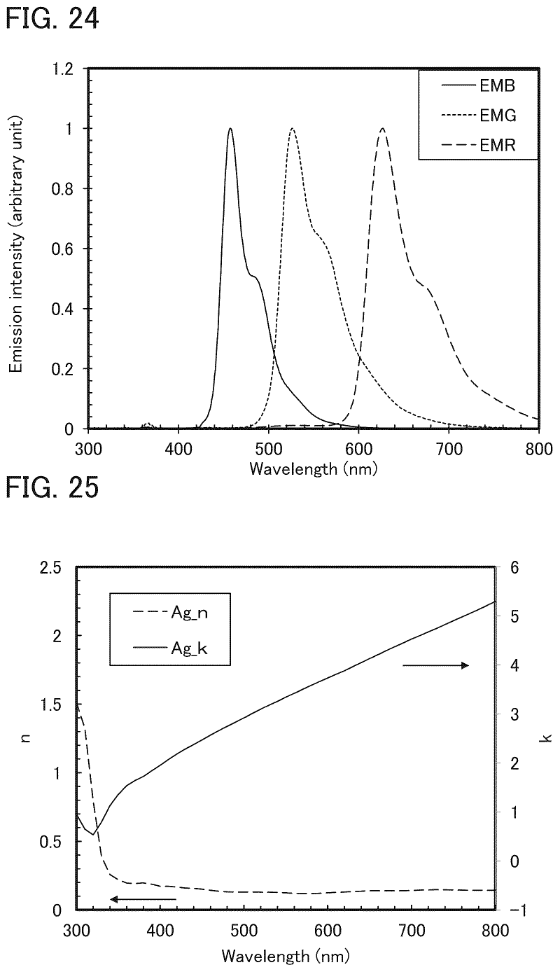

FIG. 24 is a diagram showing emission spectra of a light-emitting material EMB, a light-emitting material EMG, and a light-emitting material EMR.

FIG. 25 is a diagram showing wavelength dependence of the refractive index n and the extinction coefficient k of Ag.

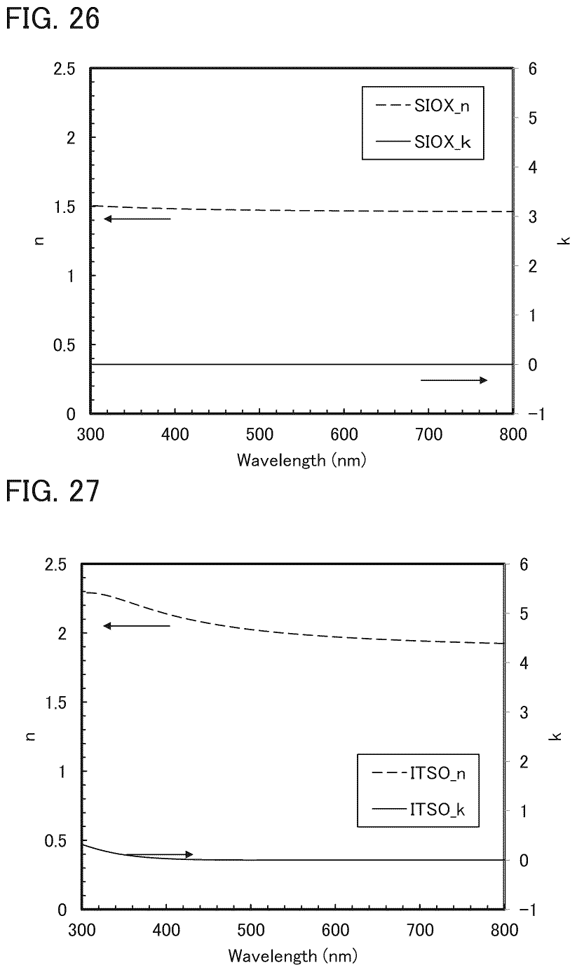

FIG. 26 is a diagram showing wavelength dependence of the refractive index n and the extinction coefficient k of SIOX.

FIG. 27 is a diagram showing wavelength dependence of the refractive index n and the extinction coefficient k of ITSO.

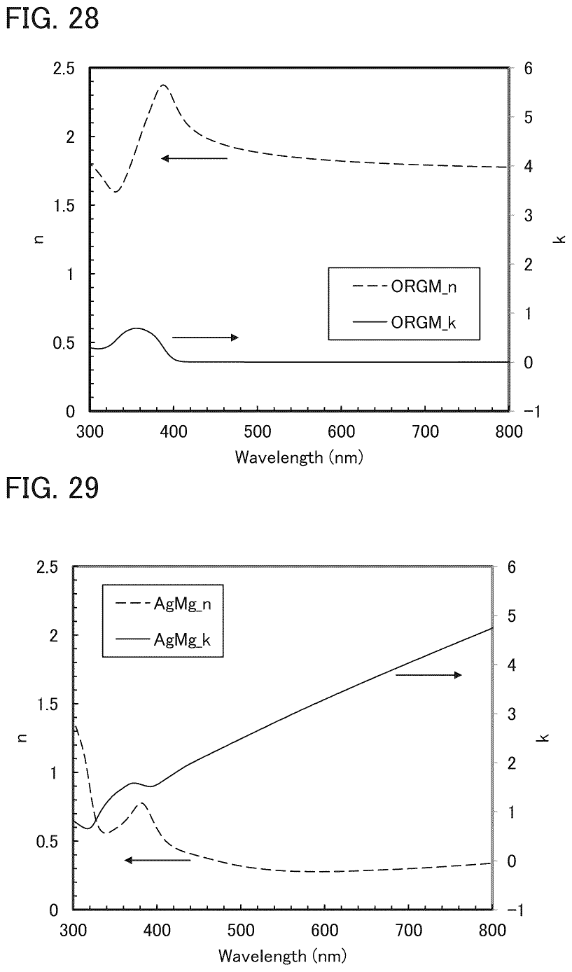

FIG. 28 is a diagram showing wavelength dependence of the refractive index n and the extinction coefficient k of ORGM.

FIG. 29 is a diagram showing wavelength dependence of the refractive index n and the extinction coefficient k of AgMg.

### <Display Apparatus 700>

The display apparatus 700 includes a light-emitting device 550B, a layer LNB, a reflective film REFB, a light-emitting device 550G, a layer LNG, a reflective film REFG, a light-emitting device 550R, a layer LNR, and a reflective film REFR (see FIG. 22).

The light-emitting device 550B includes a layer HNB (the same layer as a layer 551B in the drawing), an electrode 552B, and a unit 103B, and the unit 103B is interposed between the electrode 552B and the layer HNB. The unit 103B contains the light-emitting material EMB, and the light-emitting material EMB has an emission spectrum having a peak at the wavelength λB. The layer HNB has a light-transmitting property and includes an electrode 551B. The layer LNB is interposed between the layer HNB and the reflective film REFB and has a light-transmitting property and an ordinary refractive index lower than that of the layer HNB at the wavelength λB. The light-emitting device 550B includes an intermediate layer 106B and a unit 103B2. The unit 103B2 is interposed between the electrode 552B and the intermediate layer 106B, the unit 103B2 contains the light-emitting material EMB, and the intermediate layer 106B is interposed between the unit 103B2 and the unit 103B.

The light-emitting device 550G includes a layer HNG (the same layer as a layer 551G in the diagram), an electrode 552G, and a unit 103G, and the unit 103G is interposed between the electrode 552G and the layer HNG. The unit 103G contains the light-emitting material EMG, and the light-emitting material EMG has an emission spectrum having a peak at the wavelength λG. The layer HNG has a light-transmitting property and includes an electrode 551G, and a space is provided between the layer HNG and the layer HNB. The layer LNG is interposed between the layer HNG and the reflective film REFG and has a light-transmitting property and an ordinary refractive index lower than that of the layer HNG at the wavelength λG. The light-emitting device 550G includes an intermediate layer 106G and a unit 103G2. The unit 103G2 is interposed between the electrode 552G and the intermediate layer 106G and contains the light-emitting material EMG, and the intermediate layer 106G is interposed between the unit 103G2 and the unit 103G.

The light-emitting device 550R includes a layer HNR (the same layer as a layer 551R in the drawing), an electrode 552R, and a unit 103R, and the unit 103R is interposed between the electrode 552R and the layer HNR. The unit 103R contains the light-emitting material EMR, and the light-emitting material EMR has an emission spectrum having a peak at the wavelength λR. The layer HNR has a light-transmitting property and includes an electrode 551R, and a space is provided between the layer HNR and the layer HNG. The layer LNR is interposed between the layer HNR and the reflective film REFR and has a light-transmitting property and an ordinary refractive index lower than that of the layer HNR at the wavelength λR. The light-emitting device 550R includes an intermediate layer 106R and a unit 103R2. The unit 103R2 is interposed between the electrode 552R and the intermediate layer 106R and contains the light-emitting material EMR, and the intermediate layer 106R is interposed between the unit 103R2 and the unit 103R.

### <<Structure of Light-Emitting Device 1B>>

A light-emitting device 1B, which was subjected to scientific calculation and is described in this example, has a structure similar to that of the light-emitting device 550B (see FIG. 22).

Table 1 shows the structure of the light-emitting device 1B. Note that in the tables in this example, subscript characters and superscript characters are written in ordinary size for convenience. For example, subscript characters in abbreviations and superscript characters in units are written in ordinary size in the tables. Such notations in the tables can be replaced by referring to the description in the specification.

TABLE 1

| | Reference | | Composition | Thickness/ |
|---|---|---|---|---|
| Structure | numeral | Material | ratio | nm |
| Layer | CAP | ITSO | | 70 |
| Electrode | 552B | Ag:Mg | 1:0.1 | 15 |
| Layer | 113B2 | ETM | | 34 |
| Layer | 111B2 | EMB | | 25 |
| Layer | 112B2 | HTM | | |
| Layer | 106B | CGM | | 86 |
| Layer | 113B | ETM | | |
| Layer | 111B | EMB | | 25 |
| Layer | 112B | HTM | | 20 |
| Electrode | 551B | ITSO | | 80 |
| Layer | LNB | SIOX | | 51 |
| Reflective film | REFB | Ag | | 100 |

The reflective film REFB contains silver (Ag) and has a thickness of 100 nm. Note that FIG. 25 shows wavelength dependence of the refractive index n and the extinction coefficient k of Ag.

The layer LNB contains silicon oxide (abbreviation: SIOX) and has a thickness of 51 nm. Note that SIOX has a low refractive index, a low extinction coefficient, and a light-transmitting property. FIG. 26 shows wavelength dependence of the refractive index n and the extinction coefficient k of SIOX.

The electrode 551B contains indium oxide-tin oxide containing silicon or silicon oxide (abbreviation: ITSO) and has a thickness of 80 nm. The electrode 551B can be formed by a sputtering method using a target containing In₂O₃, SnO₂, and SiO₂ at a weight ratio of 85:10:5, for example. Note that ITSO has a high refractive index, a low extinction coefficient, and a light-transmitting property. FIG. 27 shows wavelength dependence of the refractive index n and the extinction coefficient k of ITSO.

A layer 112B contains a material HTM having a hole-transport property and has a thickness of 20 nm. Note that the refractive index n and the extinction coefficient k of the material HTM having a hole-transport property are assumed to have the same wavelength dependence as the refractive index n and the extinction coefficient k of the organic material ORGM. FIG. 28 shows wavelength dependence of the refractive index n and the extinction coefficient k of the organic material ORGM.

A layer 111B contains the light-emitting material EMB and has a thickness of 25 nm. Note that an emission spectrum of the light-emitting material EMB has a peak at a wavelength of 458 nm (see FIG. 24). The refractive index n and the extinction coefficient k of the light-emitting material EMB are assumed to have the same wavelength dependence as the refractive index n and the extinction coefficient k of the organic material ORGM.

A layer 113B contains an electron-transport material ETM, the layer 106B contains a charge-generation material CGM, and a layer 112B2 contains the material HTM having a hole-transport property. The total thickness of the layer 113B, the layer 106B, and the layer 112B2 is 86 nm. The refractive index n and the extinction coefficient k of the electron-transport material ETM are assumed to have the same wavelength dependence as the refractive index n and the extinction coefficient k of the organic material ORGM. The refractive index n and the extinction coefficient k of the charge-generation material CGM are assumed to have the same wavelength dependence as the refractive index n and the extinction coefficient k of the organic material ORGM.

A layer 111B2 contains the light-emitting material EMB and has a thickness of 25 nm.

A layer 113B2 contains the electron-transport material ETM and has a thickness of 34 nm.

The electrode 552B contains silver (Ag) and magnesium (Mg) at Ag:Mg=1:0.1 (volume ratio) and has a thickness of 15 nm. Note that FIG. 29 shows wavelength dependence of the refractive index n and the extinction coefficient k of Ag:Mg.

A layer CAP contains ITSO and has a thickness of 70 nm.

### <<Simulation of Operation Characteristics of Light-Emitting Device 1B>>

Operation characteristics of the light-emitting device 1B were simulated. As software for the calculation, an organic device simulator (a semiconducting emissive thin film optics simulator: setfos, produced by Cybernet Systems Co., Ltd.) was used. Note that the light-emitting device 1B emits light ELB1 from the layer 111B and light ELB2 from the layer 111B2 in accordance with the operation.

Table 2 shows calculated main characteristics of the light-emitting device 1B. Table 2 also shows the characteristics of a comparative device having a structure to be described later in (Reference example). Note that the blue index (BI) is one of the indicators of characteristics of a blue-light-emitting device, and is a value obtained by dividing current efficiency (cd/A) by chromaticity y. In general, blue light with high color purity is useful in expressing a wide color gamut. In addition, blue light with higher color purity tends to have lower chromaticity y. Thus, a value obtained by dividing current efficiency (cd/A) by chromaticity y is the indicator of usefulness of a blue-light-emitting device. In other words, a blue-light-emitting device with a large BI is suitable for providing a display apparatus having a wide color gamut and high efficiency.

TABLE 2

| | Chroma- | Chroma- | Increase rate of BI |
|---|---|---|---|
| | ticity x | ticity y | (%) |
| Light-emitting device 1B | 0.14 | 0.04 | 110% |
| Comparative device 1B | 0.14 | 0.04 | 100% |

The light-emitting device 1B was found to have favorable characteristics. For example, the light-emitting device 1B emitted blue light at high efficiency. In addition, the light-emitting device 1B was confirmed to have an effect of increasing the BI by 10% and reducing power consumption, while maintaining the chromaticity equivalent to a comparative device 1B having a structure described later in (Reference example).

### <<Structure of Light-Emitting Device 1G>>

A light-emitting device 1G, which was subjected to scientific calculation and is described in this example, has a structure similar to that of the light-emitting device 550G (see FIG. 22).

Table 3 shows a structure of the light-emitting device 1G.

TABLE 3

| | Reference | | Composition | Thickness/ |
|---|---|---|---|---|
| Structure | numeral | Material | ratio | nm |
| Layer | CAP | ITSO | | 70 |
| Electrode | 552G | Ag:Mg | 1:01 | 15 |
| Layer | 113G2 | ETM | | 39 |
| Layer | 111G2 | EMG | | 40 |
| Layer | 112G2 | HTM | | |
| Layer | 106G | CGM | | 97 |
| Layer | 113G | ETM | | |
| Layer | 111G | EMG | | 40 |
| Layer | 112G | HTM | | 47 |
| Electrode | 551G | ITSO | | 80 |
| Layer | LNG | SIOX | | 51 |
| Reflective film | REFG | Ag | | 100 |

The reflective film REFG contains Ag and has a thickness of 100 nm.

The layer LNG contains SIOX and has a thickness of 51 nm.

Note that the electrode 551G contains ITSO and has a thickness of 80 nm.

A layer 112G contains the material HTM having a hole-transport property and has a thickness of 47 nm.

A layer 111G contains the light-emitting material EMG and has a thickness of 40 nm. Note that an emission spectrum of the light-emitting material EMG has a peak at a wavelength of 527 nm (see FIG. 24). The refractive index n and the extinction coefficient k of the light-emitting material EMG are assumed to have the same wavelength dependence as the refractive index n and the extinction coefficient k of the organic material ORGM.

A layer 113G contains the electron-transport material ETM, the layer 106G contains the charge-generation material CGM, and a layer 112G2 contains the material HTM having a hole-transport property. The total thickness of the layer 113G, the layer 106G, and the layer 112G2 is 97 nm.

A layer 111G2 contains the light-emitting material EMG and has a thickness of 40 nm.

The layer 113G2 contains the electron-transport material ETM and has a thickness of 39 nm.

The electrode 552G contains Ag and Mg at Ag:Mg=1:0.1 (volume ratio) and has a thickness of 15 nm.

The layer CAP contains ITSO and has a thickness of 70 nm.

### <<Simulation of Operation Characteristics of the Light-Emitting Device 1G>>

Operation characteristics of the light-emitting device 1G were simulated using the above software. Note that the light-emitting device 1G emits light ELG1 from the layer 111G and light ELG2 from the layer 111G2 in accordance with the operation.

Table 4 shows calculated main characteristics of the light-emitting device 1G. Table 4 also shows the characteristics of a comparative device having a structure to be described later in (Reference example).

TABLE 4

| | | | Current efficiency |
|---|---|---|---|
| | Chroma- | Chroma- | increase rate |
| | ticity x | ticity y | (%) |
| Light-emitting device 1G | 0.23 | 0.74 | 106% |
| Comparative device 1G | 0.23 | 0.74 | 100% |

The light-emitting device 1G was found to have favorable characteristics. For example, the light-emitting device 1G emitted green light at high efficiency. In addition, the light-emitting device 1G was confirmed to have an effect of increasing current efficiency by 6% and reducing power consumption, while maintaining the chromaticity equivalent to a comparative device 1G having a structure described later in (Reference example). The same material and thickness as those of the layer LNB of the light-emitting device 1B were used for the layer LNG of the light-emitting device 1G, and the same material and thickness as those of the electrode 551B of the light-emitting device 1B were used for the electrode 551G of the light-emitting device 1G; even though the emission colors were different, the efficiency of the light-emitting device 1B and the light-emitting device 1G was improved from that of the comparative devices. Furthermore, the use of the same material and the same thickness can increase productivity.

### <<Structure of Light-Emitting Device 1R>>

A light-emitting device 1R, which was subjected to scientific calculation and is described in this example, has a structure similar to that of the light-emitting device 550R (see FIG. 22).

Table 5 shows the structure of the light-emitting device 1R.

TABLE 5

| | Reference | | Composition | Thickness/ |
|---|---|---|---|---|
| Structure | numeral | Material | ratio | nm |
| Layer | CAP | ITSO | | 70 |
| Electrode | 552R | Ag:Mg | 1:0.1 | 15 |
| Layer | 113R2 | ETM | | 55 |
| Layer | 111R2 | EMR | | 40 |
| Layer | 112R2 | HTM | | |
| Layer | 106R | CGM | | 139 |
| Layer | 113R | ETM | | |
| Layer | 111R | EMR | | 40 |
| Layer | 112R | HTM | | 74 |
| Electrode | 551R | ITSO | | 80 |
| Layer | LNR | SIOX | | 51 |
| Reflective film | REFR | Ag | | 100 |

The reflective film REFR contains Ag and has a thickness of 100 nm.

The layer LNR contains SIOX and has a thickness of 51 nm.

Note that the electrode 551R contains ITSO and has a thickness of 80 nm.

A layer 112R contains the material HTM having a hole-transport property and has a thickness of 74 nm.

A layer 111R contains the light-emitting material EMR and has a thickness of 40 nm. Note that an emission spectrum of the light-emitting material EMR has a peak at a wavelength of 627 nm (see FIG. 24). The refractive index n and the extinction coefficient k of the light-emitting material EMR are assumed to have the same wavelength dependence as the refractive index n and the extinction coefficient k of the organic material ORGM.

A layer 113R contains the electron-transport material ETM, the layer 106R contains the charge-generation material CGM, and a layer 112R2 contains the material HTM having a hole-transport property. The total thickness of the layer 113R, the layer 106R, and the layer 112R2 is 139 nm.

A layer 111R2 contains the light-emitting material EMR and has a thickness of 40 nm.

A layer 113R2 contains the electron-transport material ETM and has a thickness of 55 nm

The electrode 552R contains Ag and Mg at Ag:Mg=1:0.1 (volume ratio) and has a thickness of 15 nm.

The layer CAP contains ITSO and has a thickness of 70 nm.

### <<Simulation of Operation Characteristics of Light-Emitting Device 1R>>

Operation characteristics of the light-emitting device 1R were simulated using the above software. Note that the light-emitting device 1R emits light ELR1 from the layer 111R and light ELR2 from the layer 111R2 in accordance with the operation.

Table 6 shows calculated main characteristics of the light-emitting device 1R. Table 6 also shows the characteristics of a comparative device having a structure to be described later in (Reference example).

TABLE 6

| | | | Current efficiency |
|---|---|---|---|
| | Chroma- | Chroma- | increase rate |
| | ticity x | ticity y | (%) |
| Light-emitting device 1R | 0.66 | 0.34 | 105% |
| Comparative device 1R | 0.66 | 0.34 | 100% |

The light-emitting device 1R was found to have favorable characteristics. For example, the light-emitting device 1R emitted red light at high efficiency. In addition, the light-emitting device 1R was confirmed to have an effect of increasing current efficiency by 5% and reducing power consumption, while maintaining the chromaticity equivalent to a comparative device 1R having a structure described later in (Reference example). The same material and thickness as those of the layer LNB of the light-emitting device 1B were used for the layer LNG of the light-emitting device 1G and the layer LNR of the light-emitting device 1R, and the same material and thickness as those of the electrode 551B of the light-emitting device 1B were used for the electrode 551G of the light-emitting device 1G and the electrode 551R of the light-emitting device 1R; even though the emission colors were different, the efficiency of the light-emitting device 1B, the light-emitting device 1G, and the light-emitting device 1R was improved from that of the comparative devices. Furthermore, the use of the same material and the same thickness can increase productivity.

### Reference Example

In this reference example, a structure of the comparative apparatus 700ref is described with reference to FIG. 23.

<Comparative Apparatus 700ref>

The comparative apparatus 700ref described in this reference example includes a comparative device 550Bref, a comparative device 550Gref, and a comparative device 550Rref (see FIG. 23).

### <<Structure of Comparative Device 1B>>

The comparative device 1B, which was subjected to scientific calculation and is described in this reference example, has a structure similar to that of the comparative device 550Bref (see FIG. 23).

The comparative device 1B is different from the light-emitting device 1B in that the layer LNB is not included and the electrode 551B has a thickness of 110 nm instead of 80 nm. Here, the above description is referred to for portions having the same structure as the above.

### <<Simulation of Operation Characteristics of Comparative Device 1B>>

Operation characteristics of the comparative device 1B were simulated using the above software. Note that the comparative device 1B emits the light ELB1 from the layer 111B and the light ELB2 from the layer 111B2 in accordance with the operation. Table 2 shows calculated main characteristics of the comparative device 1B.

### <<Structure of Comparative Device 1G>>

The comparative device 1G, which was subjected to scientific calculation and is described in this reference example, has a structure similar to that of the comparative device 550Gref (see FIG. 23).

The comparative device 1G is different from the light-emitting device 1G in that the layer LNB is not included, the electrode 551G has a thickness of 110 nm instead of 80 nm, and the layer 112G has a thickness of 51 nm instead of 47 nm. Here, the above description is referred to for portions having the same structure as the above.

### <<Simulation of Operation Characteristics of Comparative Device 1G>>

Operation characteristics of the comparative device 1G were simulated using the above software. Note that the comparative device 1G emits the light ELG1 from the layer 111G and the light ELG2 from the layer 111G2 in accordance with the operation. Table 4 shows calculated main characteristics of the comparative device 1G.

### <<Structure of Comparative Device 1R>>

The comparative device 1R, which was subjected to scientific calculation and is described in this reference example, has a structure similar to that of the comparative device 550Rref (see FIG. 23).

The comparative device 1R is different from the light-emitting device 1R in that the layer LNR is not included, the electrode 551R has a thickness of 110 nm instead of 80 nm, and the layer 112R has a thickness of 81 nm instead of 74 nm. Here, the above description is referred to for portions having the same structure as the above.

### <<Simulation of Operation Characteristics of Comparative Device 1R>>

Operation characteristics of the comparative device 1R were simulated using the above software. Note that the comparative device 1R emits the light ELR1 from the layer 111R and the light ELR2 from the layer 111R2 in accordance with the operation. Table 6 shows calculated main characteristics of the comparative device 1R.

### Example 2

In this example, the display apparatus 700 of one embodiment of the present invention will be described with reference to FIG. 22 to FIG. 29.

### <Display Apparatus 700>

The display apparatus 700 includes the light-emitting device 550B, the light-emitting device 550G, and the light-emitting device 550R (see FIG. 22).

### <<Structure of Light-Emitting Device 2B>>

A light-emitting device 2B, which was subjected to scientific calculation and is described in this example, has a structure similar to that of the light-emitting device 550B (see FIG. 22).

Table 7 shows the structure of the light-emitting device 1B.

TABLE 7

| | Reference | | Composition | Thickness/ |
|---|---|---|---|---|
| Structure | numeral | Material | ratio | nm |
| Layer | CAP | ITSO | | 70 |
| Electrode | 552B | Ag:Mg | 1:0.1 | 15 |
| Layer | 113B2 | ETM | | 34 |
| Layer | 111B2 | EMB | | 25 |
| Layer | 112B2 | HTM | | |
| Layer | 106B | CGM | | 85 |
| Layer | 113B | ETM | | |
| Layer | 111B | EMB | | 25 |
| Layer | 112B | HTM | | 88 |
| Electrode | 551B | ITSO | | 10 |
| Layer | LNB | SiO2 | | 62 |
| Reflective film | REFB | Ag | | 100 |

The light-emitting device 2B is different from the light-emitting device 1B in that the layer LNB has a thickness of 62 nm instead of 51 nm, the electrode 551B has a thickness of 10 nm instead of 80 nm, the layer 112B has a thickness of 88 nm instead of 20 nm, and the stacked-layer structure of the layer 113B, the layer 106B, and the layer 112B2 has a thickness of 85 nm instead of 86 nm. Here, the above description is referred to for portions having the same structure as the above.

### <<Simulation of Operation Characteristics of Light-Emitting Device 2B>>

Operation characteristics of the light-emitting device 2B were simulated using the above software. Note that the light-emitting device 2B emits the light ELB1 from the layer 111B and the light ELB2 from the layer 111B2 in accordance with the operation.

Table 8 shows calculated main characteristics of the light-emitting device 2B. Table 8 also shows the characteristics of a comparative device having a structure to be described later in (Reference example).

TABLE 8

| | Chroma- | Chroma- | Increase rate of BI |
|---|---|---|---|
| | ticity x | ticity y | (%) |
| Light-emitting device 2B | 0.14 | 0.04 | 111% |
| Comparative device 2B | 0.14 | 0.04 | 100% |

The light-emitting device 2B was found to have favorable characteristics. For example, the light-emitting device 2B emitted blue light at high efficiency. In addition, the light-emitting device 2B was confirmed to have an effect of increasing the BI by 11% and reducing power consumption, while maintaining the chromaticity equivalent to a comparative device 2B having a structure described later in (Reference example).

### <<Structure of Light-Emitting Device 2G>>

A light-emitting device 2G, which was subjected to scientific calculation and is described in this example, has a structure similar to that of the light-emitting device 550G (see FIG. 22).

Table 9 shows the structure of the light-emitting device 2G.

TABLE 9

| | Reference | | Composition | Thickness/ |
|---|---|---|---|---|
| Structure | numeral | Material | ratio | nm |
| Layer | CAP | ITSO | | 70 |
| Electrode | 552G | Ag:Mg | 1:0.1 | 15 |
| Layer | 113G2 | ETM | | 39 |
| Layer | 111G2 | EMB | | 40 |
| Layer | 112G2 | HTM | | |
| Layer | 106G | CGM | | 97 |
| Layer | 113G | ETM | | |
| Layer | 111G | EMB | | 40 |
| Layer | 112G | HTM | | 115 |
| Electrode | 551G | ITSO | | 10 |
| Layer | LNG | SiO2 | | 62 |
| Reflective film | REFG | Ag | | 100 |

The light-emitting device 2G is different from the light-emitting device 1G in that the layer LNG has a thickness of 62 nm instead of 51 nm, the electrode 551G has a thickness of 10 nm instead of 80 nm, and the layer 112G has a thickness of 115 nm instead of 47 nm. Here, the above description is referred to for portions having the same structure as the above.

### <<Simulation of Operation Characteristics of Light-Emitting Device 2G>>

Operation characteristics of the light-emitting device 2G were simulated using the above software. Note that the light-emitting device 2G emits the light ELG1 from the layer 111G and the light ELG2 from the layer 111G2 in accordance with the operation.

Table 10 shows calculated main characteristics of the light-emitting device 2G. Table also shows the characteristics of a comparative device having a structure to be described later in (Reference example).

TABLE 10

| | | | Current efficiency |
|---|---|---|---|
| | Chroma- | Chroma- | increase rate |
| | ticity x | ticity y | (%) |
| Light-emitting device 2G | 0.25 | 0.74 | 107% |
| Comparative device 2G | 0.23 | 0.74 | 100% |

The light-emitting device 2G was found to have favorable characteristics. For example, the light-emitting device 2G emitted green light at high efficiency. In addition, the light-emitting device 2G was confirmed to have an effect of increasing current efficiency by 7% and reducing power consumption, while maintaining the chromaticity equivalent to a comparative device 2G having a structure described later in (Reference example). The same material and thickness as those of the layer LNB of the light-emitting device 1B were used for the layer LNG of the light-emitting device 1G, and the same material and thickness as those of the electrode 551B of the light-emitting device 1B were used for the electrode 551G of the light-emitting device 1G; even though the emission colors were different, the efficiency of the light-emitting device 1B and the light-emitting device 1G was improved from that of the comparative devices. Furthermore, the use of the same material and the same thickness can increase productivity.

### <<Structure of Light-Emitting Device 2R>>

A light-emitting device 2R, which was subjected to scientific calculation and is described in this example, has a structure similar to that of the light-emitting device 550R (see FIG. 22).

Table 11 shows the structure of the light-emitting device 2R.

TABLE 11

| | Reference | | Composition | Thickness/ |
|---|---|---|---|---|
| Structure | numeral | Material | ratio | nm |
| Layer | CAP | ITSO | | 70 |
| Electrode | 552R | Ag:Mg | 1:0.1 | 15 |
| Layer | 113R2 | ETM | | 55 |
| Layer | 111R2 | EMB | | 40 |
| Layer | 112R2 | HTM | | |
| Layer | 106R | CGM | | 140 |
| Layer | 113R | ETM | | |
| Layer | 111R | EMB | | 40 |
| Layer | 112R | HTM | | 143 |
| Electrode | 551R | ITSO | | 10 |
| Layer | LNR | SiO2 | | 62 |
| Reflective film | REFR | Ag | | 100 |

The light-emitting device 2R is different from the light-emitting device 1R in that the layer LNR has a thickness of 62 nm instead of 51 nm, the electrode 551R has a thickness of 10 nm instead of 80 nm, the layer 112R has a thickness of 143 nm instead of 74 nm, and the stacked-layer structure of the layer 113R, the layer 106R, and the layer 112R2 has a thickness of 140 nm instead of 139 nm. Here, the above description is referred to for portions having the same structure as the above.

### <<Simulation of Operation Characteristics of Light-Emitting Device 2R>>

Operation characteristics of the light-emitting device 2R were simulated using the above software. Note that the light-emitting device 2R emits the light ELR1 from the layer 111R and the light ELR2 from the layer 111R2 in accordance with the operation.

Table 12 shows calculated main characteristics of the light-emitting device 2R. Table 12 also shows the characteristics of a comparative device having a structure to be described later in (Reference example).

TABLE 12

| | | | Current efficiency |
|---|---|---|---|
| | Chroma- | Chroma- | increase rate |
| | ticity x | ticity y | (%) |
| Light-emitting device 2R | 0.60 | 0.34 | 105% |
| Comparative device 2R | 0.66 | 0.34 | 100% |

The light-emitting device 2R was found to have favorable characteristics. For example, the light-emitting device 2R emitted red light at high efficiency. In addition, the light-emitting device 2R was confirmed to have an effect of increasing current efficiency by 5% and reducing power consumption, while maintaining the chromaticity equivalent to a comparative device 2R having a structure described later in (Reference example). The same material and thickness as those of the layer LNB of the light-emitting device 1B were used for the layer LNG of the light-emitting device 1G and the layer LNR of the light-emitting device 1R, and the same material and thickness as those of the electrode 551B of the light-emitting device 1B were used for the electrode 551G of the light-emitting device 1G and the electrode 551R of the light-emitting device 1R; even though the emission colors were different, the efficiency of the light-emitting device 1B, the light-emitting device 1G, and the light-emitting device 1R was improved from that of the comparative devices. Furthermore, the use of the same material and the same thickness can increase productivity.

### Reference Example

In this reference example, the structure of the comparative apparatus 700ref is described with reference to FIG. 23.

<Comparative Apparatus 700ref>

The comparative apparatus 700ref described in this reference example includes the comparative device 550Bref, the comparative device 550Gref, and the comparative device 550Rref (see FIG. 23).

### <<Structure of Comparative Device 2B>>

The comparative device 2B, which was subjected to scientific calculation and is described in this reference example, has a structure similar to that of the comparative device 550Bref (see FIG. 23).

The comparative device 2B is different from the light-emitting device 2B in that the layer LNB is not included, the layer 112B has a thickness of 129 nm instead of 88 nm, and the layer 113B2 has a thickness of 33 nm instead of 34 nm. Here, the above description is referred to for portions having the same structure as the above.

### <<Simulation of Operation Characteristics of Comparative Device 2B>>

Operation characteristics of the comparative device 2B were simulated using the above software. Note that the comparative device 2B emits the light ELB1 from the layer 111B and the light ELB2 from the layer 111B2 in accordance with the operation. Table 8 shows calculated main characteristics of the comparative device 2B.

### <<Structure of Comparative Device 2G>>

The comparative device 2G, which was subjected to scientific calculation and is described in this reference example, has a structure similar to that of the comparative device 550Gref (see FIG. 23).

The comparative device 2G is different from the light-emitting device 2G in that the layer LNG is not provided, the layer 112G has a thickness of 161 nm instead of 115 nm, and the stacked-layer structure of the layer 113G, the layer 106G, and the layer 112G2 has a thickness of 96 nm instead of 97 nm. Here, the above description is referred to for portions having the same structure as the above.

### <<Simulation of Operation Characteristics of Comparative Device 2G>>

Operation characteristics of the comparative device 2G were simulated using the above software. Note that the comparative device 2G emits the light ELG1 from the layer 111G and the light ELG2 from the layer 111G2 in accordance with the operation. Table 10 shows calculated main characteristics of the comparative device 2G.

### <<Structure of Comparative Device 2R>>

The comparative device 2R, which was subjected to scientific calculation and is described in this reference example, has a structure similar to that of the comparative device 550Rref (see FIG. 23).

The comparative device 2R is different from the light-emitting device 2R in that the layer LNR is not included and the layer 112R has a thickness of 193 nm instead of 143 nm. Here, the above description is referred to for portions having the same structure as the above.

### <<Simulation of Operation Characteristics of Comparative Device 2R>>

Operation characteristics of the comparative device 2R were simulated using the above software. Note that the comparative device 2R emits the light ELR1 from the layer 111R and the light ELR2 from the layer 111R2 in accordance with the operation. Table 12 shows calculated main characteristics of the comparative device 2R.

### REFERENCE NUMERALS

ANO: conductive film, C21: capacitor, C22: capacitor, CAP: layer, GD: driver circuit, HNX: layer, HNXY: space, HNY: layer, HTM: material, LNB: layer, LNG: layer, LNR: layer, LNX: layer, LNY: layer, M21: transistor, N21: node, N22: node, nLX: ordinary refractive index, ORGM: organic material, REFB: reflective film, REFG: reflective film, REFR: reflective film, REFX: reflective film, REFY: reflective film, SD: driver circuit, SW21: switch, SW22: switch, SW23: switch, tLX: thickness, ELX: light, ELY: light, 14b: substrate, 16b: substrate, 17: substrate, 18: substrate, 37b: display portion, 61B: light-emitting device, 61G: light-emitting device, 61R: light-emitting device, 61W: light-emitting device, 63B: light-emitting device, 63G: light-emitting device, 63R: light-emitting device, 63W: light-emitting device, 71: substrate, 73: substrate, 83B: light, 83G: light, 83R: light, 100: display apparatus, 100A: display apparatus, 100B: display apparatus, 100C: display apparatus, 100D: display apparatus, 100E: display apparatus, 100F: display apparatus, 100G: display apparatus, 100H: display apparatus, 100I: display apparatus, 100J: display apparatus, 103X: unit, 103Y: unit, 104X: layer, 105X: layer, 105Y: layer, 105: layer, 106B: layer, 106G: layer, 106R: layer, 106X: intermediate layer, 106Y: intermediate layer, 106: intermediate layer, 107: display portion, 111B: layer, 111G: layer, 111R: layer, 111X: layer, 111Y: layer, 112B: layer, 112G: layer, 112R: layer, 112X: layer, 113B: layer, 113G: layer, 113R: layer, 113X: layer, 113Y: layer, 117: light-blocking layer, 120: substrate, 122: bonding layer, 140: connection portion, 142: bonding layer, 156: bonding layer, 162: insulating layer, 164: circuit, 165: wiring, 166: conductive layer, 168: conductive layer, 171: conductive layer, 172B: EL layer, 172G: EL layer, 172R: EL layer, 173: conductive layer, 176: IC, 177: FPC, 183B: coloring layer, 183G: coloring layer, 183R: coloring layer, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, region, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 270B: sacrificial layer, 270G: sacrificial layer, 270R: sacrificial layer, 271: protective layer, 272: insulating layer, 273: protective layer, 274a: conductive layer, 274b: conductive layer, 274: plug, 275: plug, 278: insulating layer, 280: display module, 290: FPC, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: bonding layer, 510: substrate, 519B: terminal, 520: functional layer, 521: insulating film, 529_1: film, 529_2: film, 529_3: film, 529_3X: opening portion, 529_3Y: opening portion, 530X: pixel circuit, 540: functional layer, 550B: light-emitting device, 550Bref: comparative device, 550G: light-emitting device, 550Gref: comparative device, 550R: light-emitting device, 550Rref: comparative device, 550X: light-emitting device, 550Y: light-emitting device, 551B: electrode, 551G: electrode, 551R: electrode, 551X: electrode, 551Y: electrode, 552B: electrode, 552G: electrode, 552R: electrode, 552X: electrode, 552Y: electrode, 552: conductive film, 591X: opening portion, 591Y: opening portion, 700ref: comparative apparatus, 700: display apparatus, 702X: pixel, 703: pixel, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 6700A: electronic device, 6700B: electronic device, 6721: housing, 6723: wearing portion, 6727: earphone portion, 6750: earphone, 6751: display panel, 6753: optical member, 6756: display region, 6757: frame, 6758: nose pad, 6800A: electronic device, 6800B: electronic device, 6820: display portion, 6821: housing, 6822: communication portion, 6823: wearing portion, 6824: control portion, 6825: image capturing portion, 6827: earphone portion, 6832: lens, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a first light-emitting device;
a first layer;
a first reflective film;
a second light-emitting device;
a second layer; and
a second reflective film,
wherein the first light-emitting device comprises a third layer, a first electrode, and a first unit,
wherein the first unit is between the first electrode and the third layer,
wherein the first unit comprises a first light-emitting material,
wherein the first light-emitting material has an emission spectrum having a peak at a first wavelength,
wherein the third layer has a light-transmitting property,
wherein the third layer comprises a second electrode,
wherein the first layer is between the third layer and the first reflective film,
wherein the first layer has a light-transmitting property,
wherein the first layer has an ordinary refractive index lower than that of the third layer at the first wavelength,
wherein the second light-emitting device comprises a fourth layer, a third electrode, and a second unit,
wherein the second unit is between the third electrode and the fourth layer,
wherein the second unit comprises a second light-emitting material,
wherein the second light-emitting material has an emission spectrum having a peak at a second wavelength,
wherein the fourth layer has a light-transmitting property,
wherein the fourth layer comprises a fourth electrode,
wherein a space is positioned between the fourth layer and the third layer,
wherein the second layer is between the fourth layer and the second reflective film,
wherein the second layer has a light-transmitting property, and
wherein the second layer has an ordinary refractive index lower than that of the fourth layer at the second wavelength.

2. A display apparatus comprising:
a first light-emitting device;
a first layer;
a first reflective film;
a second light-emitting device;
a second layer; and
a second reflective film,
wherein the first light-emitting device comprises a third layer, a first electrode, and a first unit,
wherein the first unit is between the first electrode and the third layer,
wherein the first unit comprises a first light-emitting material,
wherein the third layer has a light-transmitting property,
wherein the third layer comprises a second electrode,
wherein the third layer comprises an element with an atomic number of 21 to 83 at 5 atomic % or higher,
wherein the first layer is between the third layer and the first reflective film,
wherein the first layer has a light-transmitting property,
wherein the first layer comprises an element with an atomic number of 1 to 20 at 95 atomic % or higher,
wherein the second light-emitting device comprises a fourth layer, a third electrode, and a second unit,
wherein the second unit is between the third electrode and the fourth layer,
wherein the second unit comprises a second light-emitting material,
wherein the fourth layer has a light-transmitting property,
wherein the fourth layer comprises a fourth electrode,
wherein the fourth layer comprises an element with an atomic number of 21 to 83 at 5 atomic % or higher,
wherein a space is positioned between the fourth layer and the third layer,
wherein the second layer is between the fourth layer and the second reflective film,
wherein the second layer has a light-transmitting property, and
wherein the second layer comprises an element with an atomic number of 1 to 20 at 95 atomic % or higher.

3. The display apparatus according to claim 2,
wherein the third layer and the fourth layer each comprise a metal oxide, and
wherein the metal oxide comprises indium, tin, zinc, gallium, or titanium.

4. The display apparatus according to claim 2,
wherein the first layer and the second layer each comprise silicon oxide or aluminum oxide.

5. The display apparatus according to claim 1, wherein a difference in ordinary refractive index at the first wavelength between the third layer and the first layer is greater than or equal to 0.2 and less than or equal to 1.4.

6. The display apparatus according to claim 1,
wherein the first layer has an ordinary refractive index higher than or equal to 1.2 and lower than or equal to 1.7 at the first wavelength, and
wherein the first layer has an insulating property.

7. The display apparatus according to claim 1,
wherein the first layer has a thickness tLX,
wherein the first layer has an ordinary refractive index nLX at the first wavelength, and
wherein the thickness tLX and the ordinary refractive index nLX have a relation satisfying the following formula
$$0 < \frac{tLX \times nLX}{λ X} < 0.375 \qquad ( 1 )$$

8. The display apparatus according to claim 1,
wherein the second layer comprises the same material as the first layer, and
wherein the second layer has the same thickness as the first layer.

9. The display apparatus according to claim 1,
wherein the first light-emitting device comprises a first intermediate layer and a third unit,
wherein the third unit is between the first electrode and the first intermediate layer,
wherein the third unit comprises a third light-emitting material,
wherein the first intermediate layer is between the third unit and the first unit,
wherein the second light-emitting device comprises a second intermediate layer and a fourth unit,
wherein the fourth unit is between the third electrode and the second intermediate layer,
wherein the fourth unit comprises a fourth light-emitting material, and
wherein the second intermediate layer is between the fourth unit and the second unit.

10. The display apparatus according to claim 1, wherein the second light-emitting material is different from the first light-emitting material.

11. The display apparatus according to claim 1, comprising:
a first insulating film;
a conductive film; and
a second insulating film,
wherein the first reflective film is between the first insulating film and the first layer,
wherein the second reflective film is between the first insulating film and the second layer,
wherein the conductive film overlaps with the first insulating film,
wherein the conductive film comprises the first electrode and the third electrode,
wherein the second insulating film is between the conductive film and the first insulating film,
wherein the second insulating film fills the space,
wherein the second insulating film has an insulating property,
wherein the second insulating film comprises a first opening portion and a second opening portion,
wherein the first opening portion overlaps with the second electrode, and
wherein the second opening portion overlaps with the fourth electrode.

12. The display apparatus according to claim 1,
wherein the first reflective film is electrically connected to the second electrode, and
wherein the second reflective film is electrically connected to the fourth electrode.

13. A display module comprising:
the display apparatus according to claim 1; and
at least one of a connector and an integrated circuit.

14. An electronic device comprising:
the display apparatus according to claim 1; and
at least one of a battery, a camera, a speaker, and a microphone.

15. The display apparatus according to claim 2,
wherein the second layer comprises the same material as the first layer, and
wherein the second layer has the same thickness as the first layer.

16. The display apparatus according to claim 2,
wherein the first light-emitting device comprises a first intermediate layer and a third unit,
wherein the third unit is between the first electrode and the first intermediate layer,
wherein the third unit comprises a third light-emitting material,
wherein the first intermediate layer is between the third unit and the first unit,
wherein the second light-emitting device comprises a second intermediate layer and a fourth unit,
wherein the fourth unit is between the third electrode and the second intermediate layer,
wherein the fourth unit comprises a fourth light-emitting material, and
wherein the second intermediate layer is between the fourth unit and the second unit.

17. The display apparatus according to claim 2, wherein the second light-emitting material is different from the first light-emitting material.

18. The display apparatus according to claim 2, comprising:
a first insulating film;
a conductive film; and
a second insulating film,
wherein the first reflective film is between the first insulating film and the first layer,
wherein the second reflective film is between the first insulating film and the second layer,
wherein the conductive film overlaps with the first insulating film,
wherein the conductive film comprises the first electrode and the third electrode,
wherein the second insulating film is between the conductive film and the first insulating film,
wherein the second insulating film fills the space,
wherein the second insulating film has an insulating property,
wherein the second insulating film comprises a first opening portion and a second opening portion,
wherein the first opening portion overlaps with the second electrode, and
wherein the second opening portion overlaps with the fourth electrode.

19. The display apparatus according to claim 2,
wherein the first reflective film is electrically connected to the second electrode, and
wherein the second reflective film is electrically connected to the fourth electrode.

20. An electronic device comprising:
the display apparatus according to claim 2; and
at least one of a battery, a camera, a speaker, and a microphone.
